(19) United States
(12) Patent Application Publication
(10) Pub. No.: US 2016/0070174 A1
(43) Pub. Date: Mar. 10, 2016

(54) PATTERN FORMING METHOD, ACTIVE LIGHT SENSITIVE OR RADIATION SENSITIVE RESIN COMPOSITION, ACTIVE LIGHT SENSITIVE OR RADIATION SENSITIVE FILM, METHOD FOR MANUFACTURING ELECTRONIC DEVICE, AND ELECTRONIC DEVICE

(71) Applicant: FUJIFILM CORPORATION, Tokyo (JP)

(72) Inventors: Shuhei YAMAGUCHI, Shizuoka (JP); Kei YAMAMOTO, Shizuoka (JP); Shohei KATAOKA, Shizuoka (JP)

(73) Assignee: FUJIFILM CORPORATION, Tokyo (JP)

(21) Appl. No.: 14/938,061

(22) Filed: Nov. 11, 2015

Related U.S. Application Data
(63) Continuation of application No. PCT/JP2014/062758, filed on May 13, 2014.

(30) Foreign Application Priority Data
May 16, 2013 (JP) 2013-103860

(51) Int. Cl. G03F 7/32; G03F 7/20; G03F 7/038; G03F 7/16

(52) U.S. Cl. CPC G03F 7/325; G03F 7/16; G03F 7/20; G03F 7/038

(57) ABSTRACT

Disclosed is a pattern forming method including forming an active light sensitive or radiation sensitive film by coating a substrate with an active light sensitive or radiation sensitive resin composition; exposing the active light sensitive or radiation sensitive film; and forming a negative type pattern by developing the exposed active light sensitive or radiation sensitive film using a developer which includes an organic solvent, in which the active light sensitive or radiation sensitive resin composition contains a resin (A) which includes a repeating unit (a) which has an acidic group and a lactone structure and of which, due to a polarity thereof being increased by an action of an acid, a solubility decreases with respect to a developer which includes an organic solvent.

### CROSS-REFERENCE TO RELATED APPLICATIONS

This application is Continuation application of PCT Application No. PCT/JP2014/062758, filed May 13, 2014 and based upon and claiming the benefit of priority from Japanese Patent Application No. 2013-103860, filed May 16, 2013, the entire contents of all of which are incorporated herein by reference.

### BACKGROUND OF THE INVENTION

1. Field of the Invention

This application claims the benefit of priority of JP2013-103860, filed on May 16, 2013, and entire content of which is incorporated herein by reference.

The present invention relates to a pattern forming method, an active light sensitive or radiation sensitive resin composition, an active light sensitive or radiation sensitive film, a method for manufacturing an electronic device, and an electronic device which are favorably used for steps of manufacturing semiconductors such as IC, manufacturing circuit boards such as liquid crystals and thermal heads, and moreover, other photofabrication lithography steps. In particular, the present invention relates to a pattern forming method, an active light sensitive or radiation sensitive resin composition, an active light sensitive or radiation sensitive film, a method for manufacturing an electronic device, and an electronic device which are favorably used for exposure using ArF exposure apparatuses, ArF liquid immersion type projection exposure apparatuses, and EUV exposure apparatuses in which the light source uses far ultraviolet ray light with a wavelength of 300 nm or less.

2. Description of the Related Art

After a resist for a KrF excimer laser (248 nm), a pattern forming method in which chemical amplification is used is used in order to compensate for a reduction in sensitivity due to light absorption. For example, in a positive-type chemical amplification method, firstly, a photoacid generator which is included in an exposed section generates an acid due to being decomposed by light irradiation. Then, in a process of baking (Post Exposure Bake: PEB) or the like after the exposure, an alkali-insoluble group which is included in a photosensitive composition is changed to an alkali-soluble group by a catalytic effect of the generated acid. After that, for example, an alkali solution is used to perform development. Due to this, a desired pattern is obtained by removing the exposed section (for example, refer to JP3632410B, JP2009-269845A, and the like).

For the method described above, various types of alkali developers have been proposed. For example, a water-based alkali developer of a 2.38 mass % tetramethyl ammonium hydroxide (TMAH) aqueous solution is widely used as the alkali developer.

In order to refine semiconductor elements, the wavelength of the exposure light source is being shortened and the numerical aperture (high NA) of the projection lens is being increased and, currently, exposure devices in which an ArF excimer laser which has a wavelength of 193 nm is the light source are being developed. As a technique for further increasing resolving power, a method (that is, a liquid immersion method) has been proposed in which a liquid with a high refractive index (also referred to below as an “immersion liquid”) is filled between a projection lens and a sample. In addition, EUV lithography which performs exposure with ultraviolet light with an even shorter wavelength (13.5 nm) has also been proposed.

In recent years, pattern forming methods in which a developer which includes an organic solvent is used have also been developed (for example, refer to JP2008-281975A, JP2011-221513A, and the like).

### SUMMARY OF THE INVENTION

Finding an appropriate combination of a resist composition, a developer, a rinsing liquid, and the like which are necessary in order to form a pattern with comprehensively favorable performances is extremely difficult in practice and there is a demand for further improvements.

An object of the present invention is to provide a pattern forming method which is able to form a pattern which is excellent in terms of the roughness performance such as line width roughness (LWR), the exposure latitude (EL), and the pattern shape, an active light sensitive or radiation sensitive resin composition and an active light sensitive or radiation sensitive film which are favorably used therein, a method for manufacturing an electronic device, and an electronic device.

The present invention is, for example, the configuration which will be described below and, due to this, the object of the present invention described above is achieved.

[1] A pattern forming method including a step of forming an active light sensitive or radiation sensitive film by coating a substrate with an active light sensitive or radiation sensitive resin composition, a step of exposing the active light sensitive or radiation sensitive film, and a step of forming a negative-type pattern by developing the exposed active light sensitive or radiation sensitive film using a developer including an organic solvent, in which the active light sensitive or radiation sensitive resin composition contains a resin (A) which includes a repeating unit (a) having an acidic group and a lactone structure and of which a polarity is increased by an action of an acid and thus, a solubility with respect to a developer including an organic solvent is decreased.

[2] The pattern forming method according to [1], in which the repeating unit (a) having an acidic group and a lactone structure includes a structure represented by General Formula (I-1) or (I-2) below.

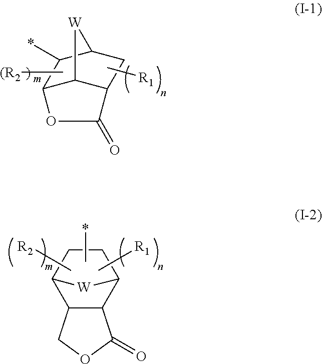

In General Formulas (I-1) and (I-2),

R₁ represents an acidic group and may be the same or may be different from each other in a case where a plurality thereof are present.

R₂ represents a monovalent organic group and may be the same or may be different from each other in a case where a plurality thereof are present.

n represents an integer of 1 or more and m represents an integer of 0 or more.

W represents a methylene group, an ethylene group, or an oxygen atom.

* represents a linking site with a remainder of the repeating unit (a).

[3] The pattern forming method according to [1] or [2], in which the acidic group of the repeating unit (a) is a carboxyl group.

[4] The pattern forming method according to any one of [1] to [3], in which the resin (A) further contains a repeating unit (b) having an acid-decomposable group which is decomposed by an action of an acid.

[5] The pattern forming method according to [4], in which a content ratio of the repeating unit (b) is 55 mol % or more with respect to all of the repeating units included in the resin (A).

[6] The pattern forming method according to [4] or [5], in which the acid-decomposable group of at least one type of the repeating unit (b) is a group which is decomposed by an action of an acid and generates an alcoholic hydroxy group.

[7] The pattern forming method according to any one of [4] to [6], in which the acid-decomposable group of at least one type of the repeating unit (b) includes a structure represented by General Formula (II) below.

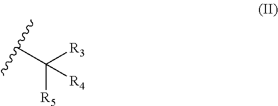

In the formula, R₃, R₄, and R₅ each independently represents an alkyl group, provided that one or more CH₂s in the alkyl group may be replaced by an ether bond.

[8] An active light sensitive or radiation sensitive resin composition including a resin (A) which includes a repeating unit (a) having an acidic group and a lactone structure and a repeating unit (b) having an acid-decomposable group which is decomposed by an action of an acid and of which a polarity is increased by an action of an acid and a solubility with respect to a developer which includes an organic solvent is decreased, in which the repeating unit (a) includes a structure represented by General Formula (I-1) or (I-2) below, and a content ratio of the repeating unit (b) is 55 mol % or more with respect to all of the repeating units included in the resin (A).

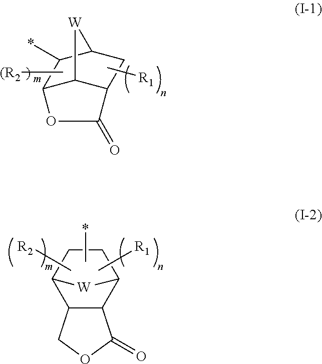

In General Formulas (I-1) and (I-2),

R₁ represents an acidic group and may be the same or may be different from each other in a case where a plurality thereof are present.

R₂ represents a monovalent organic group and may be the same or may be different from each other in a case where a plurality thereof are present.

n represents an integer of 1 or more and m represents an integer of 0 or more.

W represents a methylene group, an ethylene group, or an oxygen atom.

* represents a linking site with a remainder of the repeating unit (a).

[9] The active light sensitive or radiation sensitive resin composition according to [8], in which at least one R₁ in General Formulas (I-1) and (I-2) is a carboxyl group.

[10] The active light sensitive or radiation sensitive resin composition according to [8] or [9], in which the acid-decomposable group of at least one type of the repeating unit (b) is a group which is decomposed by an action of an acid and generates an alcoholic hydroxy group.

[11] The active light sensitive or radiation sensitive resin composition according to any one of [8] to [10], in which the acid-decomposable group of at least one type of the repeating unit (b) includes a structure represented by General Formula (II) below.

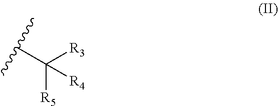

In the formula, R₃, R₄, and R₅ each independently represents an alkyl group, provided that one or more CH₂s in the alkyl group may be replaced by an ether bond.

[12] An active light sensitive or radiation sensitive film which is formed using the active light sensitive or radiation sensitive resin composition according to any one of [8] to [11].

[13] A method for manufacturing an electronic device including the pattern forming method according to any one of [1] to [7].

[14] An electronic device which is manufactured by the method for manufacturing an electronic device according to [13].

According to the present invention, it is possible to provide a pattern forming method which is able to form a pattern which is excellent in terms of the roughness performance such as line width roughness, the exposure latitude, and the pattern shape, an active light sensitive or radiation sensitive resin composition and an active light sensitive or radiation sensitive film which are favorably used therein, a method for manufacturing an electronic device, and an electronic device.

### DESCRIPTION OF THE PREFERRED EMBODIMENTS

Detailed description will be given below of embodiments of the present invention.

In the notation of the groups (atomic groups) in the present specification, notation which does not indicate whether a group is substituted or unsubstituted encompasses having a substituent group as well as not having a substituent group. For example, an “alkyl group” encompasses not only an alkyl group which does not have a substituent group (an unsubstituted alkyl group), but also an alkyl group which has a substituent group (a substituted alkyl group).

The “active light” or “radiation” in the present specification has the meaning of, for example, the bright line spectrum of a mercury lamp, far ultraviolet rays which are represented by an excimer laser, extreme ultraviolet (EUV light) rays, X-rays, electron beams (EB), and the like. In addition, light in the present invention has the meaning of active lights or radiation.

In addition, unless otherwise stated, “exposure” in the present specification includes not only exposure using a mercury lamp, far ultraviolet rays which are represented by an excimer laser, extreme ultraviolet rays, X-rays, and the like, but also drawing using particle beams such as electron beams and ion beams.

The pattern forming method of the present invention includes a step of forming an active light sensitive or radiation sensitive film by coating an active light sensitive or radiation sensitive resin composition on a substrate, a step of exposing the active light sensitive or radiation sensitive film, and a step of forming a negative-type pattern by developing the exposed active light sensitive or radiation sensitive film using a developer which includes an organic solvent, and uses an active light sensitive or radiation sensitive resin composition which contains a resin (also referred to below as “resin (A)” or an “acid-decomposable resin”) which includes a repeating unit (a) having an acidic group and a lactone structure and of which, due to a polarity thereof being increased by an action of an acid, a solubility decreases with respect to a developer which includes an organic solvent, as the active light sensitive or radiation sensitive resin composition described above.

The present inventors and the like discovered that, in a pattern forming method which includes forming a negative-type pattern using a developer which includes an organic solvent (also referred to below as an “organic solvent-based developer”), it is possible to obtain a pattern which is excellent in terms of the roughness performance such as line width roughness (LWR), the exposure latitude (EL), and the pattern shape by using an active light sensitive or radiation sensitive resin composition which contains the resin (A) described above. The reasons why it is possible to obtain a pattern which is excellent in all of the roughness performance, the exposure latitude (EL), and the pattern shape in this manner are not certain, but are thought to be as follows.

In the system which forms a negative-type pattern using an organic solvent-based developer, LWR and EL easily deteriorate since the dissolution contrast before and after being decomposed by an acid is low; however, it is possible to improve the LWR and EL to a certain extent by increasing the ratio of acid-decomposable groups in a resin or using acid-decomposable groups with high solubility in developer. However, when the developer solubility is excessively high throughout the entire resin, the pattern in the exposed section is also easily dissolved and the LWR and the pattern shape deteriorate. With respect to this, it is considered that, by using a resin which includes a repeating unit which has an acidic group and a lactone structure as a repeating unit with appropriately low developer solubility, the developer solubility of the pattern in the exposed section is suppressed and it is possible to obtain a pattern which is excellent in all of LWR, EL and pattern shape.

Firstly, description will be given of an active light sensitive or radiation sensitive resin composition which is used in the pattern forming method according to the present invention and, subsequently, description will be given of a pattern forming method in which this composition is used.

<Active Light Sensitive or Radiation Sensitive Resin Composition>

The active light sensitive or radiation sensitive resin composition according to the present invention is used for negative-type development (development in which the solubility decreases with respect to a developer when exposed and exposed sections remain as a pattern and unexposed sections are removed). That is, it is possible for the active light sensitive or radiation sensitive resin composition according to the present invention to be an active light sensitive or radiation sensitive resin composition for organic solvent development which is used for development in which a developer which includes an organic solvent is used. Here, for organic solvent development has the meaning of usage in a developing step using a developer which includes an organic solvent.

The active light sensitive or radiation sensitive resin composition of the present invention is typically a resist composition and preferably a negative-type resist composition (that is, a resist composition for organic solvent development) from the point of view that it is possible to obtain particularly high effects. In addition, the composition according to the present invention is typically a chemical amplification resist composition.

The active light sensitive or radiation sensitive resin composition according to the present invention contains a resin (also referred to below as “resin (A)” and the like) which has a repeating unit which has an acidic group and a lactone structure and of which, due to the polarity thereof being increased by the action of an acid, a solubility decreases with respect to a developer which includes an organic solvent; however, it is preferable to also contain a compound which generates an acid when irradiated with active rays or radiation.

In addition, the active light sensitive or radiation sensitive resin composition may further include at least one of a solvent, a hydrophobic resin, a basic compound, a surfactant, and other additive agents. Description will be given below of each of the components in order.

<Resin (A) of which, Due to a Polarity Thereof being Increased by an Action of an Acid, a Solubility Decreases with Respect to a Developer which Includes an Organic Solvent>

The resin (A) contains a repeating unit (a) which has an acidic group and a lactone structure.

Examples of the acidic group of the repeating unit (a) include carboxylic acid, sulfonic acid, a sulfonamide structure, and the like and the repeating unit (a) may include two or more acidic groups. In an aspect of the present invention, at least one acidic group is preferably carboxylic acid.

The lactone structure of the repeating unit (a) is preferably, for example, a 5 to 7 membered ring lactone structure and more preferably a 5 to 7 membered ring lactone structure on which another ring structure is condensed in a form which forms a bicyclo structure and a spiro structure. In detail, examples thereof include a lactone structure which is represented by any of General Formulas (LC1-1) to (LC1-21) which will be described below.

In an aspect of the present invention, an aspect in which an acidic group is bonded to a lactone structure is preferable. In this case, the acidic group may be directly bonded to the lactone structure and may be bonded to the lactone structure via a linking group. In addition, the lactone structure may further have a substituent group other than the acidic group.

The repeating unit (a) preferably includes a structure which is represented by General Formula (I-1) or (I-2) below.

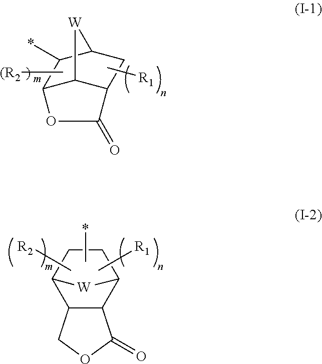

In General Formulas (I-1) and (I-2),

R₁ represents an acidic group and may be the same or may be different from each other in a case where a plurality thereof are present.

R₂ represents a monovalent organic group and may be the same or may be different from each other in a case where a plurality thereof are present.

n represents an integer of 1 or more and m represents an integer of 0 or more.

W represents a methylene group, an ethylene group, or an oxygen atom.

* represents a linking site with a remainder of the repeating unit (a).

Examples of an acidic group as R₁ include a carboxyl group, a sulfonic acid group (—SO₃H), a sulfonamide group (—SO₂NH₂), and the like and a group which has a linking group between the acidic group and a lactone structure is also included. Examples of the linking group include an alkylene group (preferably, with 1 to 3 carbon atoms), —O—, —S—, —CO—, —SO₂—, or a group which combines two or more thereof, and the like.

In an aspect of the present invention, the acidic group as R₁ is preferably a carboxyl group.

Examples of an organic group as R₂ include an alkyl group, a cycloalkyl group, an alkoxy group, an alkoxycarbonyl group, a halogen atom, a hydroxy group, and a cyano group.

An alkyl group as R₂ is preferably an alkyl group with 1 to 8 carbon atoms and examples thereof include a methyl group, an ethyl group, a propyl group, an n-butyl group, a sec-butyl group, a hexyl group, an octyl group, and the like.

A cycloalkyl group as R₂ may be a monocyclic type or may be a polycyclic type. A cycloalkyl group with 3 to 8 carbon atoms is preferable as the monocyclic type and examples thereof include a cyclopropyl group, a cyclobutyl group, a cyclopentyl group, a cyclohexyl group, a cyclooctyl group, and the like. A cycloalkyl group with 6 to 20 carbon atoms is preferable as the polycyclic type and examples thereof include an adamantyl group, a norbornyl group, an isoboronyl group, a camphanyl group, a dicyclopentyl group, an α-pinel group, a tricyclodecanyl group, a tetracyclododecyl group, an androstanyl group, and the like. Here, at least one carbon atom in the cycloalkyl group may be substituted with a hetero atom such as an oxygen atom.

An alkyl site in the alkoxy group and an alkyl site in the alkoxycarbonyl group is preferably, for example, an alkyl group with 1 to 8 carbon atoms.

n represents an integer of 1 or more and is preferably an integer of 1 to 3.

m represents an integer of 0 or more and is preferably an integer of 0 to 2.

An aspect of the repeating unit (a) may be an aspect in which a lactone structure which has an acidic group is bonded to the main chain of a resin via a linking group or may be an aspect in which the lactone structure is directly bonded to the main chain of a resin.

Specific examples of the repeating unit (a) which has an acidic group and a lactone structure will be shown below; however, the content of the present invention is not limited thereto. In the formulas below, RXa represents a methyl group, a trifluoromethyl group, or a hydrogen atom.

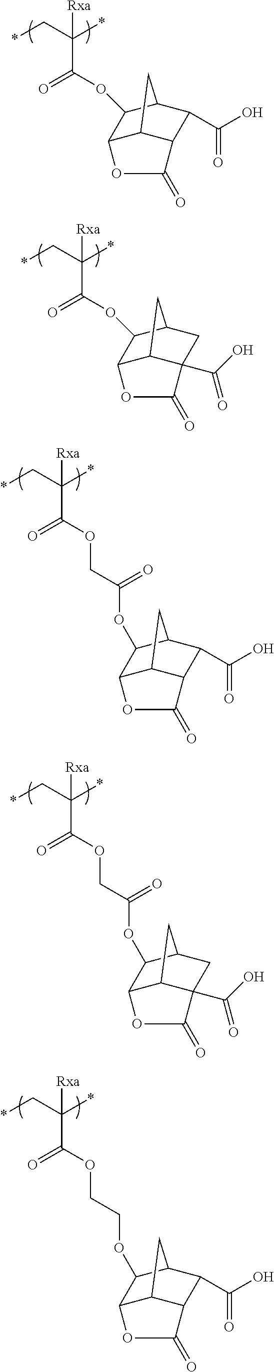

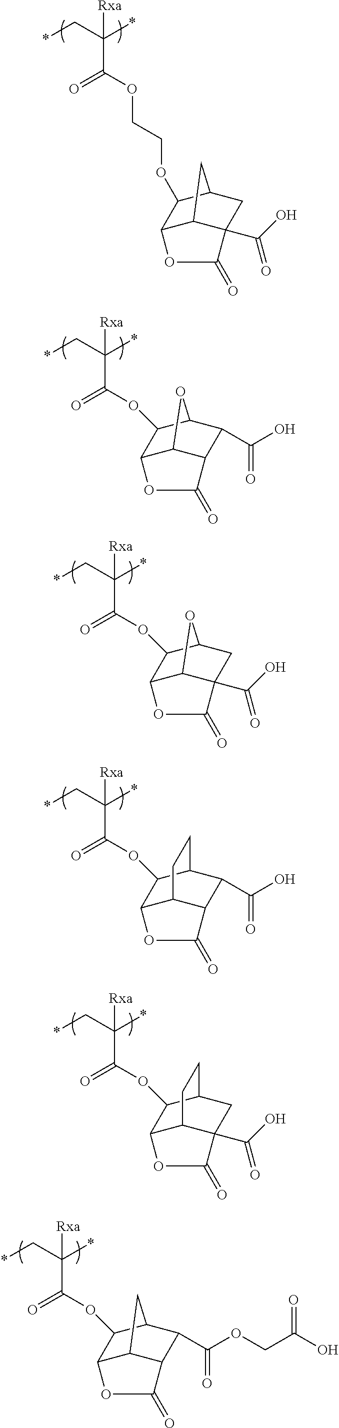

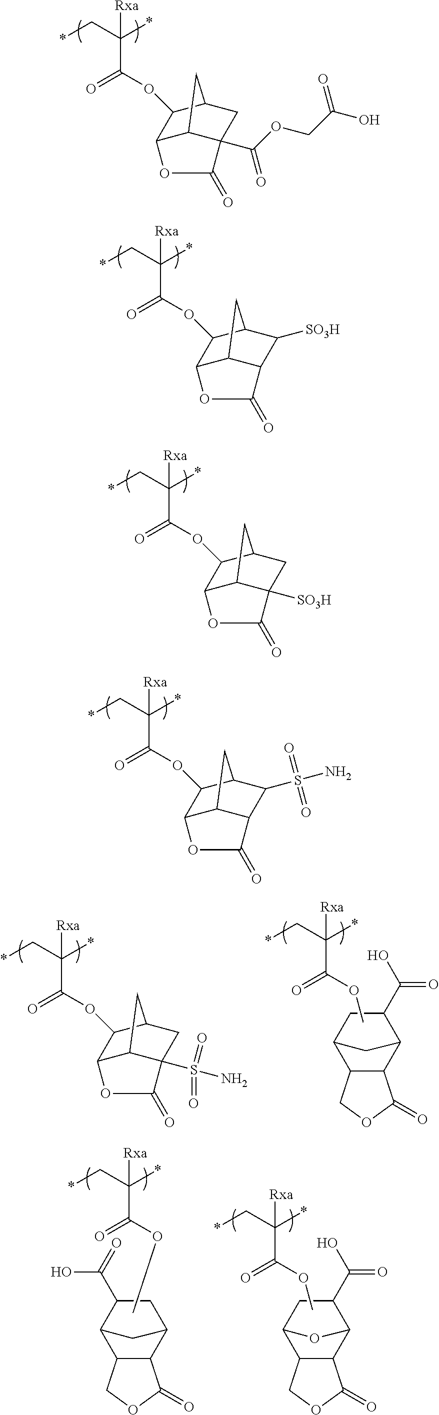

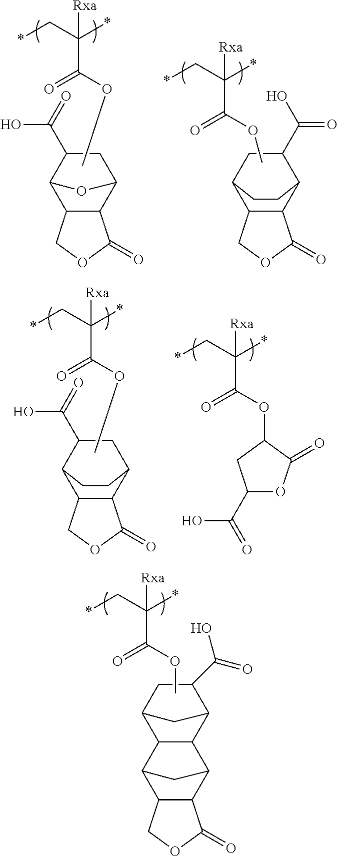

The content ratio of the repeating unit (a) which has an acidic group and a lactone structure is preferably 3 mol % to 60 mol % with respect to all of the repeating units which configure the resin (A), more preferably 5 mol % to 55 mol %, and even more preferably 10 mol % to 50 mol %.

The resin (A) preferably further contains an acid-decomposable group which is decomposed by the action of an acid and preferably contains a repeating unit which has an acid-decomposable group.

The acid-decomposable group preferably has a structure in which a polar group is protected by a group which is decomposed and desorbs a polar group by the action of an acid.

The polar group is not particularly limited as long as the polar group is sparingly soluble or insoluble in a developer which includes an organic solvent; however, examples thereof include acidic groups (groups which dissociate in a 2.38 mass % tetramethyl ammonium hydroxide aqueous solution which is used as a resist developer in the related art) such as a phenolic hydroxy group, a carboxyl group, a fluorinated alcohol group (preferably, a hexafluoroisopropanol group), a sulfonic acid group, a sulfonamide group, a sulfonylimide group, an (alkylsulfonyl) (alkylcarbonyl)methylene group, an (alkylsulfonyl) (alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, and a tris(alkylsulfonyl)methylene group, or an alcoholic hydroxy group, or the like.

Here, an alcoholic hydroxy group is a hydroxy group which is bonded to a hydrocarbon group and refers to a hydroxy group other than a hydroxy group (a phenolic hydroxy group) which is directly bonded on an aromatic ring, and aliphatic alcohol groups (for example, fluorinated alcohol groups (a hexafluoroisopropanol group and the like)) in which the α-position is substituted with an electron-withdrawing group such as a fluorine atom as an acidic group are excluded.

The pKa of the alcoholic hydroxy group which may be generated due to the acid-decomposable group which generates the alcoholic hydroxy group being decomposed by the action of an acid is, for example, 12 or more and typically 12 to 20. When the pKa is excessively small, the stability of the composition which includes an acid-decomposable resin decreases and there are cases where changes in the resist performance over time increase. Here, “pKa” is a value which is calculated using “ACD/pKaDB” manufactured by Fujitsu Corp., based on the uncustomized default settings.

Examples of preferable polar groups include a carboxyl group, a fluorinated alcohol group (preferably, a hexafluoroisopropanol group), a sulfonic acid group, and an alcoholic hydroxy group.

A group which is preferable as an acid-decomposable group is a group in which the hydrogen atoms of these groups are substituted with groups which are desorbed by an acid.

Examples thereof include —C(R₃₆)(R₃₇)(R₃₈), —C(R₃₆)(R₃₇)(OR₃₉), —C(R₀₁)(R₀₂)(OR₃₉), and the like.

In the formula, R₃₆ to R₃₉ each independently represents an alkyl group, a cycloalkyl group, an aryl group, an aralkyl group, or an alkenyl group. R₃₆ and R₃₇ may form a ring by bonding with each other.

R₀₁ and R₀₂ each independently represents a hydrogen atom, an alkyl group, a cycloalkyl group, an aryl group, an aralkyl group, or an alkenyl group.

The alkyl group of R₃₆ to R₃₉, R₀₁, and R₀₂ is preferably an alkyl group with 1 to 8 carbon atoms and examples thereof include a methyl group, an ethyl group, a propyl group, an n-butyl group, a sec-butyl group, a hexyl group, an octyl group, and the like.

The cycloalkyl group of R₃₆ to R₃₉, R₀₁, and R₀₂ may be a monocyclic type or may be a polycyclic type. A cycloalkyl group with 3 to 8 carbon atoms is preferable as the monocyclic type and examples thereof include a cyclopropyl group, a cyclobutyl group, a cyclopentyl group, a cyclohexyl group, a cyclooctyl group, and the like. A cycloalkyl group with 6 to 20 carbon atoms is preferable as the polycyclic type and examples thereof include an adamantyl group, a norbornyl group, an isoboronyl group, a camphanyl group, a dicyclopentyl group, an α-pinel group, a tricyclodecanyl group, a tetracyclododecyl group, an androstanyl group, and the like. Here, at least one carbon atom in the cycloalkyl group may be substituted with a hetero atom such as an oxygen atom.

The aryl group of R₃₆ to R₃₉, R₀₁, and R₀₂ is preferably an aryl group with 6 to 10 carbon atoms and examples thereof include a phenyl group, a naphthyl group, an anthryl group, and the like.

The aralkyl group of R₃₆ to R₃₉, R₀₁, and R₀₂ is preferably an aralkyl group with 7 to 12 carbon atoms and examples thereof include a benzyl group, a phenethyl group, a naphthylmethyl group, and the like.

The alkenyl group of R₃₆ to R₃₉, R₀₁, and R₀₂ is preferably an alkenyl group with 2 to 8 carbon atoms and examples thereof include a vinyl group, an allyl group, a butenyl group, a cyclohexenyl group, and the like.

A ring which is formed by R₃₆ and R₃₇ being bonded to each other is preferably a cycloalkyl group (monocyclic or polycyclic). The cycloalkyl groups are preferably monocyclic cycloalkyl groups such as a cyclopentyl group and a cyclohexyl group, or polycyclic cycloalkyl groups such as a norbornyl group, a tetracyclodecanyl group, a tetracyclododecanyl group, and an adamantyl group. A monocyclic cycloalkyl group with 5 or 6 carbon atoms is more preferable and a monocyclic cycloalkyl group with 5 carbon atoms is particularly preferable.

In an aspect of the present invention, an acid-decomposable group is preferably a cumyl ester group, an enol ester group, an acetal ester group, a tertiary alkyl ester group, and the like. The tertiary alkyl ester group is more preferable.

The acid-decomposable group preferably includes, for example, a structure which is represented by General Formula (II) below.

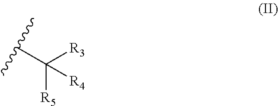

In the formula, R₃, R₄, and R₅ each independently represents an alkyl group, provided that one or more CH₂s in the alkyl group may be replaced by an ether bond.

Examples of an alkyl group which is represented by R₃, R₄, and R₅ include a methyl group, an ethyl group, a propyl group, an n-butyl group, a sec-butyl group, a tert-butyl group, and the like.

In another aspect of the present invention, the resin (A) preferably contains a group which generates an alcoholic hydroxy group due to being decomposed by the action of an acid as an acid-decomposable group and the group preferably includes at least any one of the structures which are represented by General Formulas (OR-1) to (OR-9) below. Out of these, the groups which are represented by General Formulas (OR-1) to (OR-4) are groups which generate one alcoholic hydroxy group due to being decomposed by the action of an acid and General Formulas (OR-5) to (OR-9) are groups which generate two or three alcoholic hydroxy groups due to being decomposed by the action of an acid.

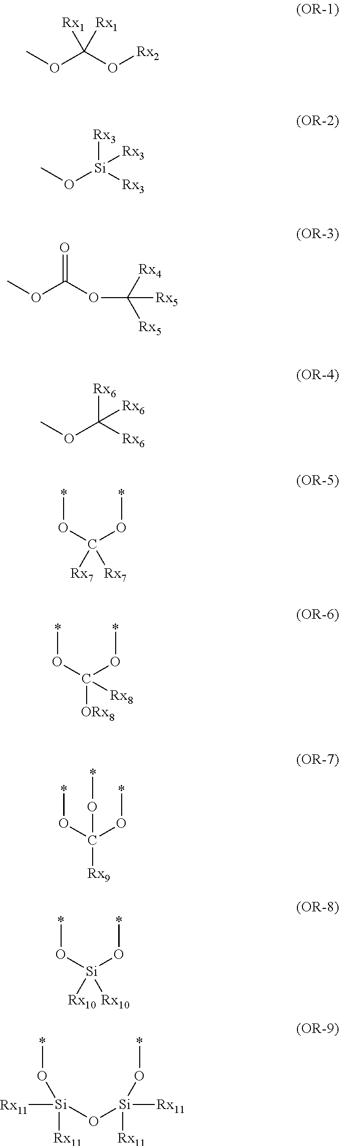

In General Formula (OR-1) described above,

Rx₁ each independently represents a hydrogen atom or a monovalent organic group. Rx₁ may form a ring by bonding with each other.

Rx₂ represents a monovalent organic group. Rx₁ and Rx₂ may form a ring by bonding with each other.

At least one of the carbon atoms (carbon atoms which contribute to the ring forming) which configure a ring formed by Rx₁ bonding with each other or a ring formed by one Rx₁ and Rx₂ bonding with each other may be substituted with an oxygen atom or a sulfinyl group.

In General Formula (OR-2) described above,

Rx₃ each independently represents a monovalent organic group. Rx₃ may form a ring by bonding with each other.

In General Formula (OR-3) described above,

Rx₄ represents a hydrogen atom or a monovalent organic group.

Rx₅ each independently represents a monovalent organic group. Rx₅ may form a ring by bonding with each other. Rx₄ and Rx₅ may form a ring by bonding with each other.

In General Formula (OR-4) described above,

Rx₆ each independently represents a hydrogen atom, an alkyl group, a cycloalkyl group, an aryl group, an alkenyl group, or an alkynyl group. Two Rx₆ may form a ring by bonding with each other. However, in a case where one or two out of the three Rx₆ are hydrogen atoms, at least one out of the remaining Rx₆ represents an aryl group, an alkenyl group, or an alkynyl group.

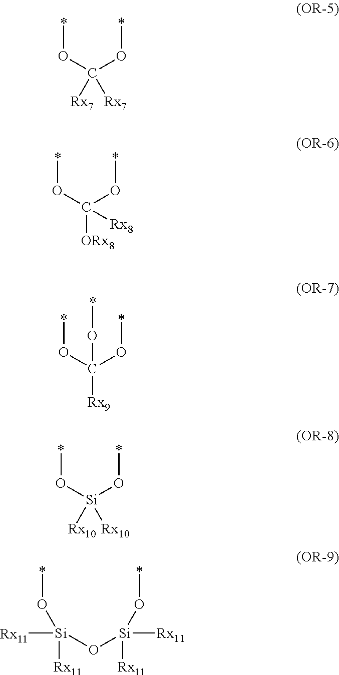

In General Formula (OR-5) described above,

Rx₇ each independently represents a hydrogen atom or a monovalent organic group. Rx₇ may form a ring by bonding with each other.

In General Formula (OR-6) described above,

Rx₈ each independently represents a hydrogen atom or a monovalent organic group. Rx₈ may form a ring by bonding with each other.

In General Formula (OR-7) above,

Rx₉ represents a monovalent organic group.

In General Formula (OR-8) described above,

Rx₁₀ each independently represents a monovalent organic group. Rx₁₀ may form a ring by bonding with each other.

In General Formula (OR-9) described above,

Rx₁₁ each independently represents a monovalent organic group. Rx₁₁ may form a ring by bonding with each other.

In General Formulas (OR-5) to (OR-9) described above, * represents an atomic bond which is linked with the main chain or a side chain of a resin.

A group which generates an alcoholic hydroxy group due to being decomposed by the action of an acid is more preferably represented by at least one selected from General Formulas (OR-1) to (OR-3), even more preferably represented by General Formula (OR-1) or (OR-3), and particularly preferably represented by General Formula (OR-1). The reason why the structure of (OR-1) is preferable is because the film Tg is high for a resin which has an alcoholic hydroxyl protective group in addition to the heat stability of an acid-unstable group being high.

Rx₁ and Rx₄ each independently represents a hydrogen atom or a monovalent organic group as described above. Rx₁ and Rx₄ are preferably a hydrogen atom, an alkyl group, or a cycloalkyl group and more preferably a hydrogen atom or an alkyl group.

The alkyl group of Rx₁ and Rx₄ may be a straight-chain form or a branched chain form. The number of carbon atoms of an alkyl group of Rx₁ and Rx₄ is preferably 1 to 10 and more preferably 1 to 3.

The cycloalkyl group of Rx₁ and Rx₄ may be monocyclic or may be polycyclic. The number of carbon atoms of the cycloalkyl group of Rx₁ and Rx₄ is preferably 3 to 10 and more preferably 4 to 8.

In addition, in General Formula (OR-1), at least one Rx₁ is preferably a monovalent organic group. It is possible to achieve particularly high sensitivity by adopting this configuration.

Rx₁ and Rx₄ may have a substituent group and examples of the substituent group include an alkyl group (with 1 to 4 carbon atoms), a cycloalkyl group (with 3 to 10 carbon atoms), a halogen atom, a hydroxy group, an alkoxy group (with 1 to 4 carbon atoms), a carboxyl group, an alkoxycarbonyl group (with 2 to 6 carbon atoms), an aryl group (with 6 to 10 carbon atoms), and the like and the number of carbon atoms is preferably 8 or less.

Rx₂ and Rx₅ represent a monovalent organic group as described above. Rx₂ and Rx₅ are preferably an alkyl group or a cycloalkyl group and more preferably an alkyl group. The alkyl group and the cycloalkyl group may further have a substituent group and examples of the substituent group include the same groups described with regard to the substituent groups which Rx₁ and Rx₄ described above may have.

The alkyl groups of Rx₂ and Rx₅ preferably do not have a substituent group or have one or more aryl groups and/or one or more silyl groups as a substituent group. The number of carbon atoms of an unsubstituted alkyl group is preferably 1 to 20. The number of carbon atoms in the alkyl group portion in the alkyl group which is substituted with one or more aryl groups is preferably 1 to 25.

Specific examples of the alkyl groups of Rx₂ and Rx₅ include the same groups described as the specific examples of the alkyl groups of Rx₁ and Rx₄. In addition, an aryl group in an alkyl group which is substituted with one or more aryl groups is preferably an aryl group with 6 to 10 carbon atoms and specific examples thereof include a phenyl group and a naphthyl group.

The number of carbon atoms in an alkyl group portion in an alkyl group which is substituted with one or more silyl groups is preferably 1 to 30. In addition, in a case where the cycloalkyl group of Rx₂ and Rx₅ does not have a substituent group, the number of carbon atoms is preferably 3 to 20.

Specific examples of the cycloalkyl group of Rx₂ and Rx₅ include the same examples described as the specific examples of the cycloalkyl group of Rx₁ and Rx₄.

Rx₃ is each independently preferably an alkyl group, a cycloalkyl group, or an aryl group, more preferably an alkyl group or a cycloalkyl group, and even more preferably an alkyl group.

Specific examples and preferable examples of an alkyl group and a cycloalkyl group with regard to Rx₃ include the same examples as the alkyl groups and the cycloalkyl groups described above with regard to Rx₁ and Rx₄.

Examples of the aryl group of Rx₃ include an aryl group with 6 to 10 carbon atoms such as a phenyl group and a naphthyl group.

The alkyl group, the cycloalkyl group, and the aryl group may further have a substituent group and examples of the substituent group include the same examples as the groups described with regard to the substituent groups which Rx₁ and Rx₄ may have.

Rx₆ represents a hydrogen atom, an alkyl group, a cycloalkyl group, an aryl group, an alkenyl group, or an alkynyl group. However, in a case where one or two out of three Rx₆ are hydrogen atoms, at least one out of the remaining Rx₆ represents an aryl group, an alkenyl group, or an alkynyl group. Rx₆ is preferably a hydrogen atom or an alkyl group. An alkyl group, a cycloalkyl group, an aryl group, an alkenyl group, and an alkynyl group as Rx₆ may further have a substituent group and examples of the substituent group include the same examples described above as the substituent groups which Rx₁ and Rx₄ may have.

Examples of an alkyl group and a cycloalkyl group as Rx₆ include the same examples as described with regard to the alkyl group and the cycloalkyl group of Rx₁ and Rx₄. In particular, in a case where the alkyl group does not have a substituent group, the number of carbon atoms is preferably 1 to 6 and more preferably 1 to 3.

Examples of the aryl group of Rx₆ include the same examples as the aryl groups described with regard to the aryl group of Rx₃.

Examples of the alkenyl group of Rx₆ include alkenyl groups with 2 to 5 carbon atoms such as a vinyl group, a propenyl group, and an allyl group.

Examples of an alkynyl group as Rx₆ include an alkynyl group with 2 to 5 carbon atoms such as an ethynyl group, a propynyl group, and a butynyl group.

Rx₇ represents a hydrogen atom or a monovalent organic group as described above. Rx₇ is preferably a hydrogen atom, an alkyl group, or a cycloalkyl group, more preferably a hydrogen atom or an alkyl group, and even more preferably a hydrogen atom or an alkyl group which does not have a substituent group. Rx₇ is preferably a hydrogen atom or an alkyl group with 1 to 10 carbon atoms and more preferably a hydrogen atom or an alkyl group with 1 to 10 carbon atoms which does not have a substituent group.

An alkyl group and a cycloalkyl group as Rx₇ may further have a substituent group and examples of the substituent group include the same examples described above of the substituent group which Rx₁ and Rx₄ may have.

Specific examples of the alkyl group and the cycloalkyl group of Rx₇ include the same examples as described as the specific examples of the alkyl group and the cycloalkyl group of Rx₁ and Rx₄.

Rx₈ each independently represents a hydrogen atom or a monovalent organic group as described above. Rx₈ are each independently preferably a hydrogen atom, an alkyl group, or a cycloalkyl group and more preferably a hydrogen atom or an alkyl group.

Examples of the alkyl group and the cycloalkyl group of Rx₈ include the same examples as described with regard to the alkyl group and the cycloalkyl group of Rx₁ and Rx₄.

Rx₉, Rx₁₀, and Rx₁₁ each independently represents a monovalent organic group as described above. Rx₉, Rx₁₀, and Rx₁₁ are each independently preferably an alkyl group or a cycloalkyl group and more preferably an alkyl group.

Examples of an alkyl group and a cycloalkyl group of Rx₉, Rx₁₀, and Rx₁₁ include the same examples as described with regard to the alkyl group and cycloalkyl group of Rx₁ and Rx₄.

Specific examples of a group which generates an alcoholic hydroxy group due to being decomposed by the action of an acid will be shown below.

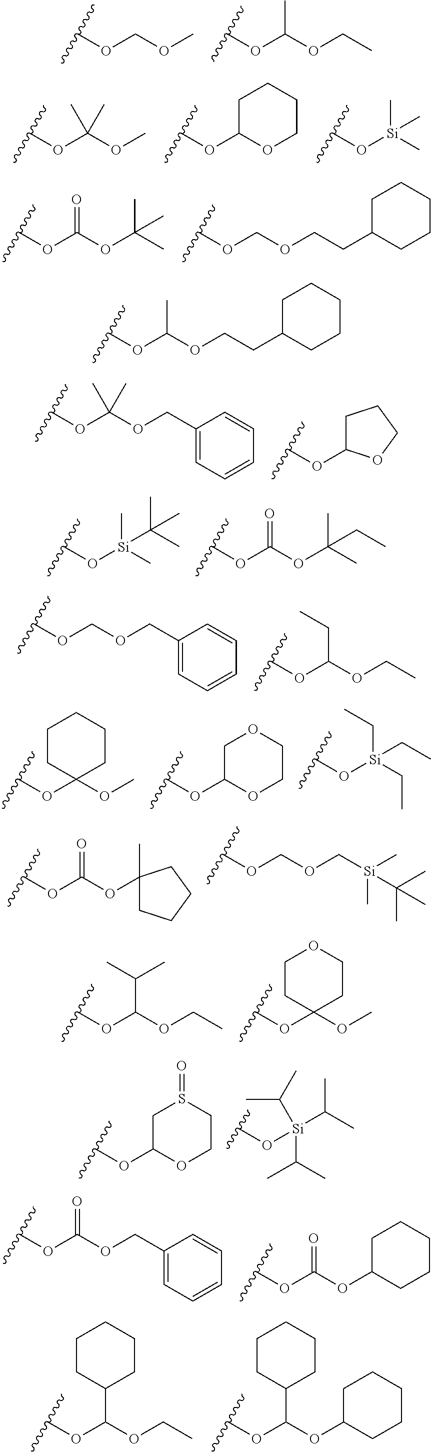

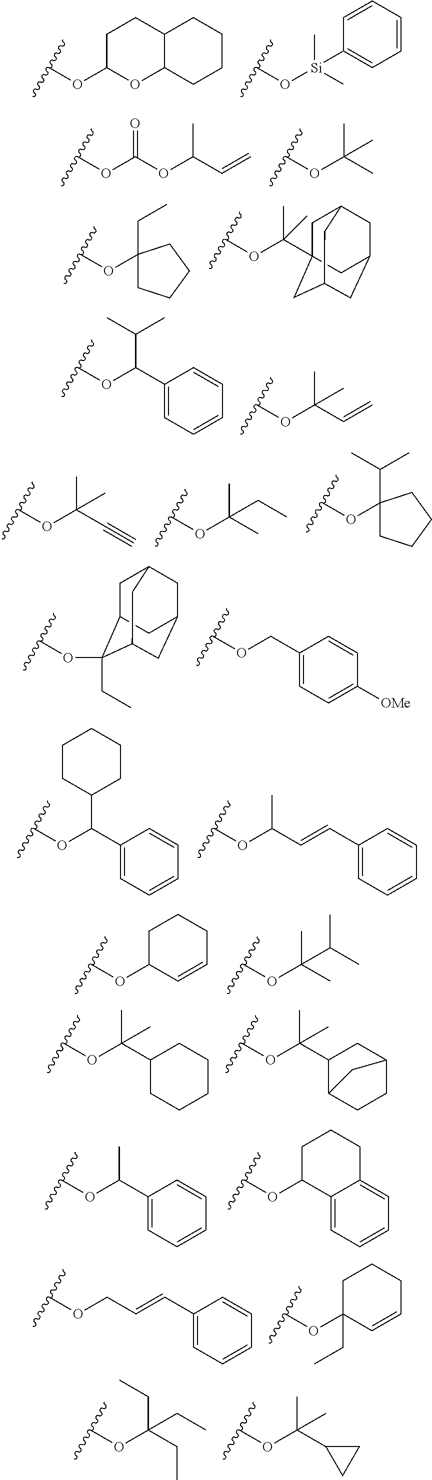

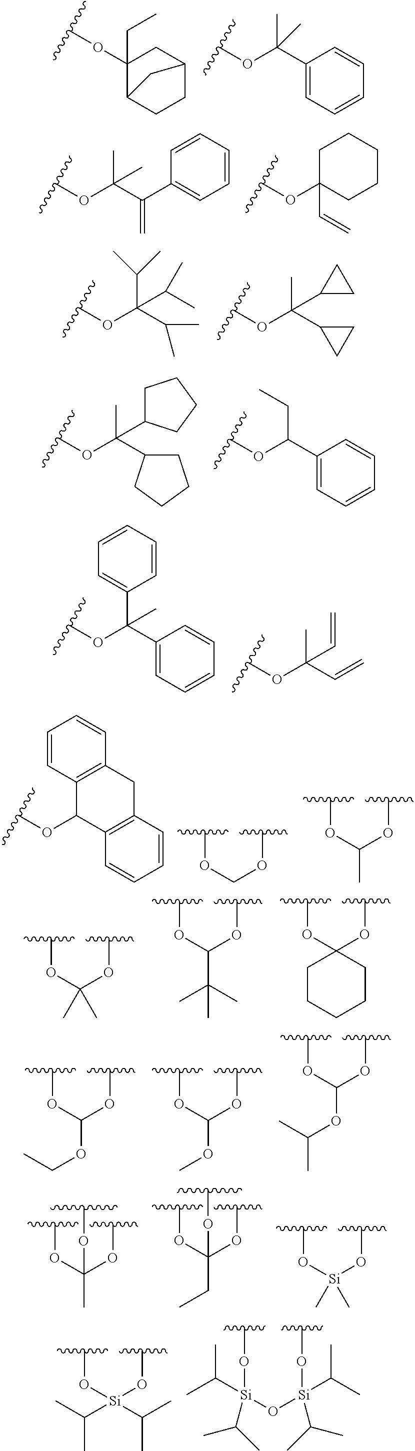

In an aspect of the present invention, a repeating unit which has a group which generates an alcoholic hydroxy group due to being decomposed by the action of an acid may have a polycyclic alicyclic hydrocarbon group.

The repeating unit which has a group which generates an alcoholic hydroxy group due to being decomposed by the action of an acid is preferably represented by at least one selected from a group formed of General Formulas (b-1) to (b-8) below. The repeating unit is more preferably represented by at least one selected from a group formed of General Formulas (b-1) to (b-3) below and even more preferably represented by General Formula (b-1) below.

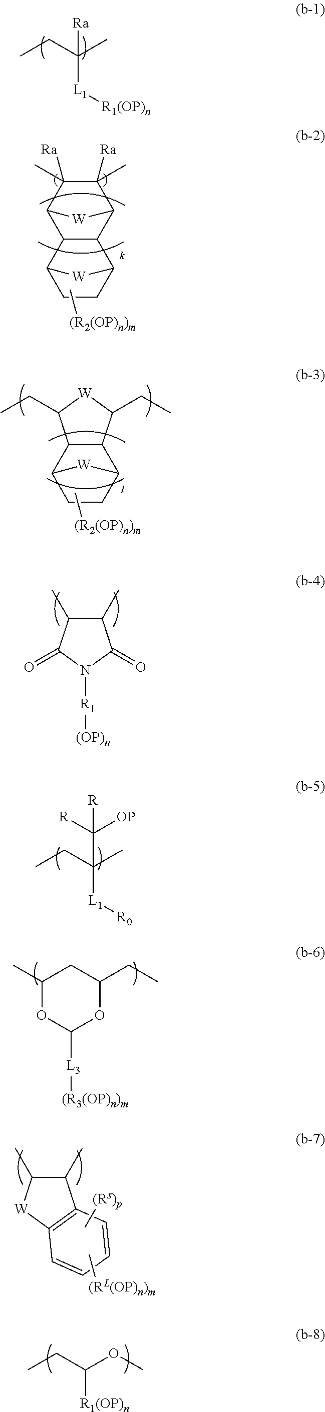

In the formulas described above,

Ra each independently represents a hydrogen atom, an alkyl group, or a group which is represented by —CH₂—O—Ra₂. Here, Ra₂ represents a hydrogen atom, an alkyl group, or an acyl group.

R₁, R₂, and R₃ each independently represents a single bond or an (n+1)valent organic group. In a case where a plurality of R₂ are present, the plurality of R₂ may be the same or may be different. In a case where a plurality of R₃ are present, the plurality of R₃ may be the same or may be different.

OP each independently represents the acid-decomposable group which generates an alcoholic hydroxy group due to being decomposed by the action of an acid. In a case where n≧2 and/or m≧2, two or more OP may form a ring by bonding with each other.

W represents a methylene group, an oxygen atom, or a sulfur atom.

n and m represent an integer of 1 or more. Here, in a case where R₂ represents a single bond in General Formula (b-2) or (b-3), n is 1. In addition, in a case where R₃ represents a single bond in General Formula (b-6), n is 1.

k represents an integer of 0 or more.

l represents an integer of 1 or more.

L₁ represents a linking group which is represented by —COO—, —OCO—, —CONH—, —O—, —Ar—, —SO₃—, or —SO₂NH—. Here, Ar represents a divalent aromatic ring group.

R each independently represents a hydrogen atom or an alkyl group.

R₀ represents a polycyclic alicyclic hydrocarbon group.

L₃ represents an (m+2)valent linking group.

R^{L} represents an (n+1)valent polycyclic alicyclic hydrocarbon group. In a case where a plurality of R^{L} are present, the plurality of R^{L} may be the same or may be different.

R^{S} represents a substituent group and, in a case where a plurality of R^{S} are present, the plurality of R^{S} may be the same or may be different and may form a ring by bonding with each other.

p represents an integer of 0 to 3.

Ra represents a group which is represented by a hydrogen atom, an alkyl group, or a group which is represented by —CH₂—O—Ra₂ as described above.

The number of carbon atoms of an alkyl group of Ra is preferably 6 or less and the number of carbon atoms of an alkyl group and an acyl group of Ra₂ is preferably 5 or less. An alkyl group of Ra and an alkyl group and an acyl group of Ra₂ may have a substituent group.

Ra is preferably a hydrogen atom, an alkyl group with 1 to 10 carbon atoms, or an alkoxyalkyl group with 1 to 10 carbon atoms and more preferably a hydrogen atom or a methyl group.

W represents a methylene group, an oxygen atom, or a sulfur atom. W is preferably a methylene group or an oxygen atom.

R₁, R₂, and R₃ represent a single bond or an (n+1)valent organic group as described above.

In an aspect of the present invention, R₁, R₂, and R₃ are preferably a single bond or a non-aromatic hydrocarbon group. In this case, R₁, R₂, and R₃ may be a chain hydrocarbon group or an alicyclic hydrocarbon group.

In a case where R₁, R₂, and R₃ are a chain hydrocarbon group, the chain hydrocarbon group may be a straight-chain form or a branched chain form. In addition, the number of carbon atoms of the chain hydrocarbon group is preferably 1 to 8. For example, in a case where R₁, R₂, and R₃ are an alkylene group, R₁, R₂, and R₃ are preferably a methylene group, an ethylene group, an n-propylene group, an isopropylene group, an n-butylene group, an isobutylene group, or a sec-butylene group.

In a case where R₁, R₂, and R₃ are an alicyclic hydrocarbon group, the alicyclic hydrocarbon group may be monocyclic or may be polycyclic. The alicyclic hydrocarbon group is provided with, for example, a monocyclo, bicyclo, tricyclo, or tetracyclo structure. The number of carbon atoms of the alicyclic hydrocarbon group is generally 5 or more, preferably 6 to 30, and more preferably 7 to 25.

Examples of an alicyclic hydrocarbon group with regard to R₁, R₂, and R₃ include an alicyclic hydrocarbon group which is provided with the partial structures which will be exemplified below. In addition, examples of an (n+1)valent polycyclic alicyclic hydrocarbon group with regard to R₁ and R₃ include an alicyclic hydrocarbon group which is provided with a partial structure which has two or more rings out of the partial structures which will be exemplified below. Each of the partial structures may have a substituent group. In addition, in each of the partial structures, a methylene group (—CH₂—) may be substituted with an oxygen atom (—O—), a sulfur atom (—S—), a carbonyl group [—C(═O)—], a sulfonyl group [—S(═O)₂—], a sulfinyl group [—S(═O)—], or an imino group [—N—(R—)—] (R is a hydrogen atom or an alkyl group).

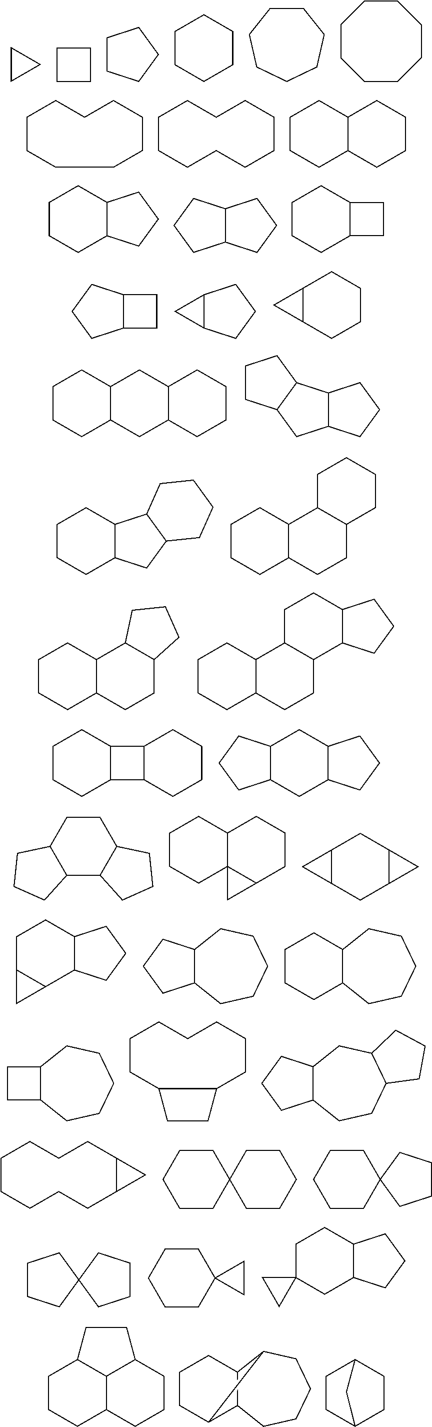

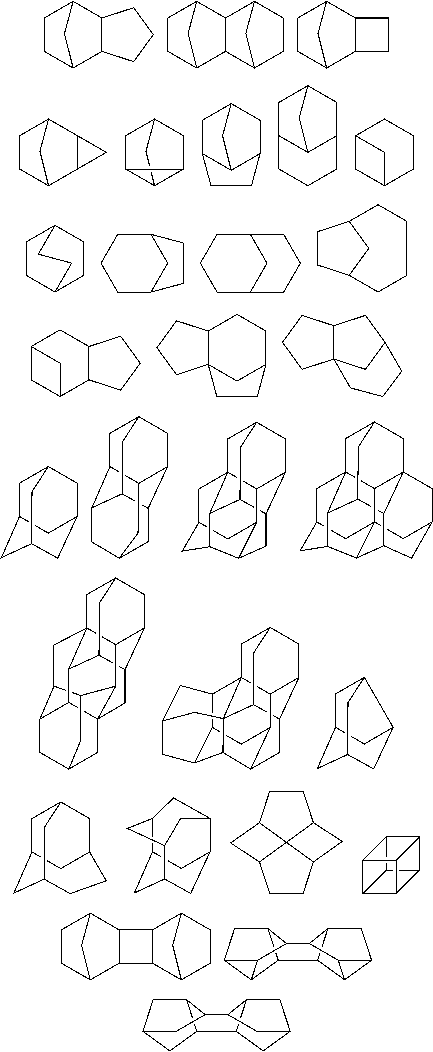

In addition, in another aspect of the present invention, R₁, R₂, and R₃ are preferably an (n+1)valent polycyclic alicyclic hydrocarbon atom.

The (n+1)valent polycyclic alicyclic hydrocarbon group with regard to R₁, R₂, and R₃ is more preferably an adamantylene group, a norbornylene group, a tetracyclododecanylene group, or a tricyclodecanylene group.

The (n+1)valent polycyclic alicyclic hydrocarbon group and a non-aromatic hydrocarbon group with regard to R₁, R₂, and R₃ may have a substituent group. Examples of the substituent group include an alkyl group with 1 to 4 carbon atoms, a halogen atom, a hydroxy group, an alkoxy group with 1 to 4 carbon atoms, a carboxy group, and an alkoxycarbonyl group with 2 to 6 carbon atoms. The alkyl group, the alkoxy group, and the alkoxy carbonyl group described above may further have a substituent group. Examples of the substituent group include a hydroxy group, a halogen atom, and an alkoxy group.

L₁ represents a linking group which is represented by —COO—, —OCO—, —CONH—, —O—, —Ar—, —SO₃—, or —SO₂NH— (“—” on the left side in the linking groups has the meaning of being connected with the main chain of a resin). Here, Ar represents a divalent aromatic ring group and is preferably, for example, a divalent aromatic ring group with 6 to 10 carbon atoms such as a phenylene group or a naphthylene group. L₁ is preferably a linking group which is represented by —COO—, —CONH—, or —Ar— and more preferably a linking group which is represented by —COO— and —CONH—.

R represents a hydrogen atom or an alkyl group. The alkyl group may be a straight-chain form or may be a branched chain form. The number of carbon atoms of the alkyl group is preferably 1 to 6 and more preferably 1 to 3. R is preferably a hydrogen atom or a methyl group and more preferably a hydrogen atom.

R₀ represents a polycyclic cycloalkyl group. Examples of the polycyclic cycloalkyl group include an adamantyl group, a noradamantyl group, a decahydronaphthyl group, a tricyclodecanyl group, a tetracyclododecanyl group, a norbornyl group, and the like.

L₃ represents an (m+2)valent linking group. That is, L₃ represents a trivalent or higher linking group.

L₃ is preferably a non-aromatic hydrocarbon group and may be a chain hydrocarbon group or may be an alicyclic hydrocarbon group. Specific examples of the chain hydrocarbon group include a group in which m arbitrary hydrogen atoms are removed from the groups described above which were exemplified as the alkylene group with regard to R₁, R₂, and R₃ and specific examples of the alicyclic hydrocarbon group include a group in which m arbitrary hydrogen atoms are removed from the groups described above which were exemplified as the alicyclic hydrocarbon group with regard to R₁, R₂, and R₃.

R^{L} represents an (n+1)valent polycyclic alicyclic hydrocarbon group. That is, R^{L} represents a divalent or higher polycyclic alicyclic hydrocarbon group. Examples of the polycyclic alicyclic hydrocarbon group include the same examples as for the polycyclic alicyclic hydrocarbon group described as an (n+1)valent polycyclic alicyclic hydrocarbon group with regard to R₁, R₂, and R₃. R^{L} may form a ring structure by bonding with each other or bonding with R^{S} which will be described below.

R^{S} represents a substituent group. Examples of the substituent group include an alkyl group, an alkenyl group, an alkynyl group, an aryl group, an alkoxy group, an acyloxy group, an alkoxycarbonyl group, and a halogen atom.

n is an integer of 1 or more. n is preferably an integer of 1 to 3 and more preferably 1 or 2. In addition, when n is 2 or more, it is possible to further improve the dissolution contrast with respect to a developer which includes an organic solvent. Due to this, it is possible to further improve the limit resolving power and roughness characteristics.

m is an integer of 1 or more. m is preferably an integer of 1 to 3 and more preferably 1 or 2.

k is an integer of 0 or more. k is preferably 0 or 1.

l is an integer of 1 or more. l is preferably 1 or 2 and more preferably 1.

p is an integer of 0 to 3.

Specific examples of a repeating unit which has an acid-decomposable group which generates an alcoholic hydroxy group will be shown below. Here, in the specific examples, Ra and OP are each the same as in General Formulas (b-1) to (b-3). In addition, in a case where a plurality of OP form a ring by bonding with each other, the corresponding ring structure is denoted as “O—P—O” for convenience.

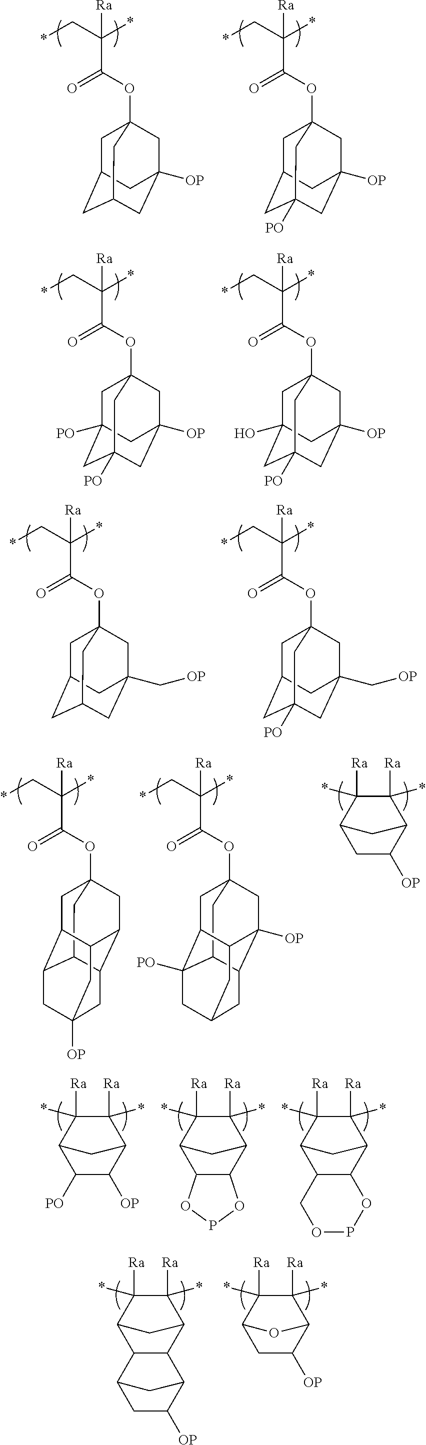

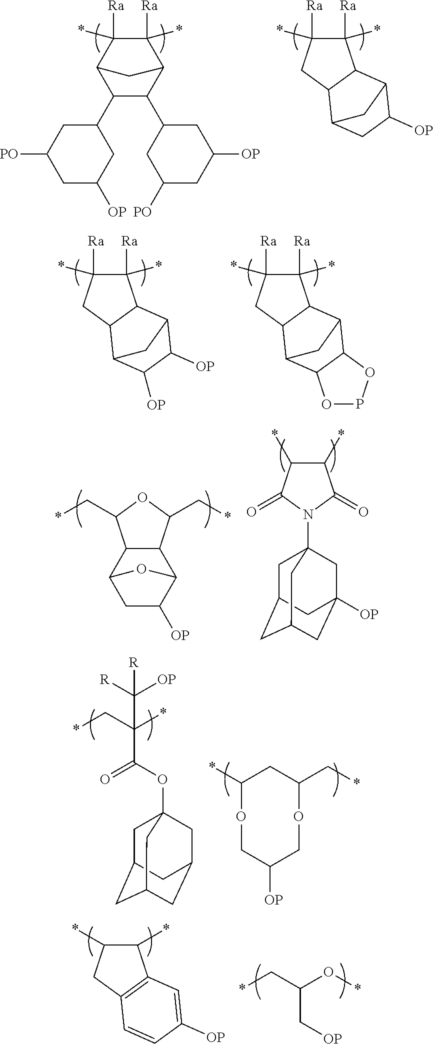

As described above, the repeating unit which has an acid-decomposable group which generates an alcoholic hydroxy group due to being decomposed by the action of an acid is particularly preferably represented by General Formula (b-1) described above. In addition, a group which generates an alcoholic hydroxy group due to being decomposed by the action of an acid is more preferably represented by General Formula (OR-1) or (OR-3) described above and particularly preferably represented by General Formula (OR-1) described above.

In an aspect of the present invention, the repeating unit which has an acid-decomposable group which generates an alcoholic hydroxy group due to being decomposed by the action of an acid is particularly preferably represented by General Formula (IV-1) or (IV-2) below.

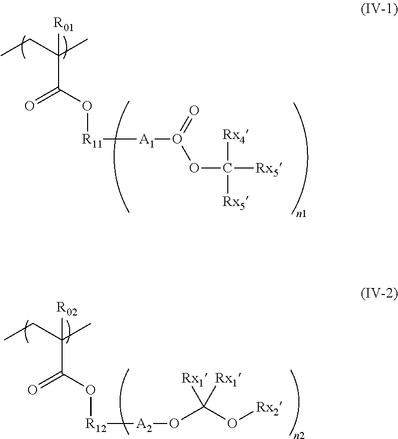

In General Formulas (IV-1) and (IV-2) described above,

R₀₁ and R₀₂ each independently represents a hydrogen atom or a methyl group.

R₁₁ represents an (n1+l)valent polycyclic alicyclic hydrocarbon group.

R₁₂ represents an (n2+l)valent polycyclic alicyclic hydrocarbon group.

A₁ and A₂ each independently represents a single bond or an alkylene group.

Rx₄′ represents a hydrogen atom, an alkyl group, or a cycloalkyl group.

Rx₅′ each independently represents an alkyl group or a cycloalkyl group. Rx₅′ may form a ring by bonding with each other. In addition, Rx₄′ and Rx₅′ may form a ring by bonding with each other.

Rx₁′ each independently represents a hydrogen atom, an alkyl group, or a cycloalkyl group. Rx₁′ may form a ring by bonding with each other.

Rx₂′ each independently represents an alkyl group or a cycloalkyl group. Rx₁′ and Rx₂′ may form a ring by bonding with each other.

n1 and n2 each independently represents an integer of 1 to 3.

When n1 is 2 or 3, a plurality of A₁, a plurality of Rx₄′, and a plurality of Rx₅′ may each independently be the same or may be different from each other.

When n2 is 2 or 3, a plurality of A₂, a plurality of Rx₁′, and a plurality of Rx₂′ may each independently be the same or may be different from each other.

Examples of an (n1+l)valent polycyclic alicyclic hydrocarbon group with regard to R₁₁ and an (n2+l)valent polycyclic alicyclic hydrocarbon group with regard to R₁₂ include a norbornane ring group, a tetracyclodecane ring group, a tetracyclododecane ring group, an adamantane ring group, a diamantane ring group, and the like and a polycyclic alicyclic hydrocarbon group with 7 to 20 carbon atoms is preferable, a polycyclic alicyclic hydrocarbon group with 7 to 15 carbon atoms is more preferable, and a polycyclic alicyclic hydrocarbon group with 10 to 15 carbon atoms is particularly preferable.

Examples of an alkylene group with regard to A₁ and A₂ include straight-chain or branched alkylene groups (for example, —CH₂—, —C(CH₃)₂—, —(CH₂)₂—, —(CH₂)₃—, —(CH₂)₄—, —(CH₂)₁₀—, and the like) and an alkylene group with 1 to 8 carbon atoms is preferable, an alkylene group with 1 to 4 carbon atoms is more preferable, and an alkylene group with 1 or 2 carbon atoms is particularly preferable.

A₁ and A₂ are most preferably a single bond or an alkylene group with 1 or 2 carbon atoms.

Specific examples and preferable examples of an alkyl group and a cycloalkyl group with regard to Rx₁′, Rx₂′, Rx₄′, and Rx₅′ include the same examples as the specific examples and preferable examples described above as the alkyl groups and the cycloalkyl groups with regard to Rx₁ and Rx₄.

At least one of carbon atoms (carbon atoms which contribute to the ring forming) which configure the ring formed by Rx₁′ bonding with each other or the ring formed by Rx₁′ and Rx₂′ bonding with each other may be substituted with an oxygen atom or a sulfinyl group.

Preferable specific examples of a repeating unit which has an acid-decomposable group which generates an alcoholic hydroxy group due to being decomposed by the action of an acid include the following; however, the present invention is not limited thereto. In the specific examples below, Xa₁ represents a hydrogen atom, CH₃, CF₃, or CH₂OH.

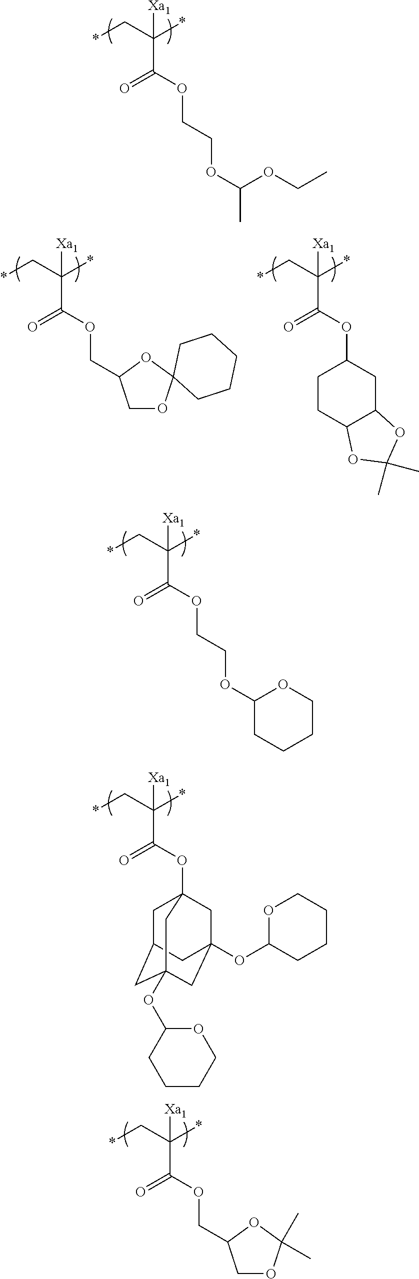

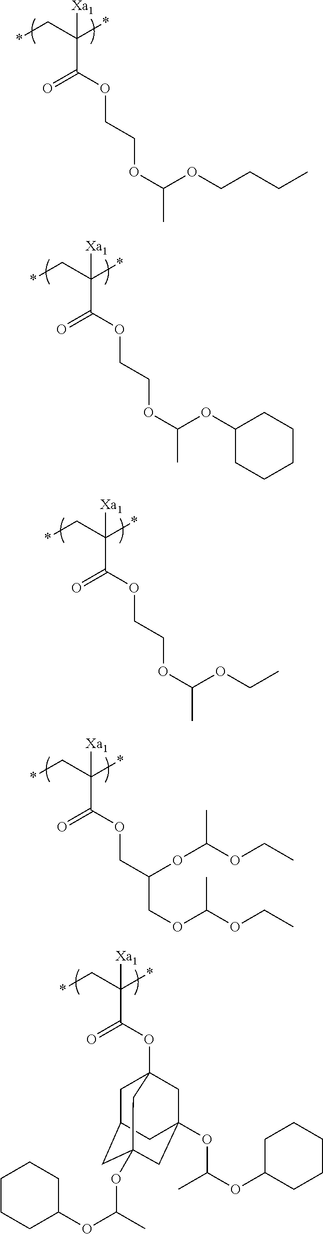

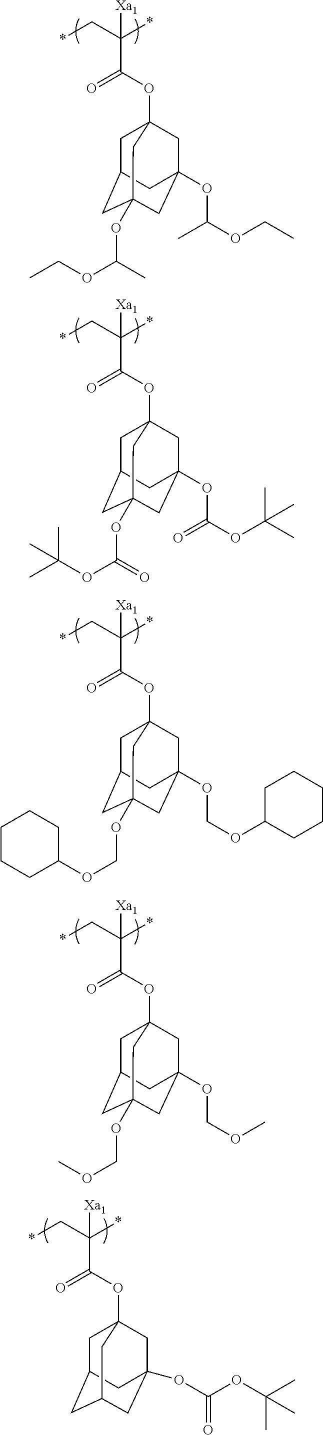

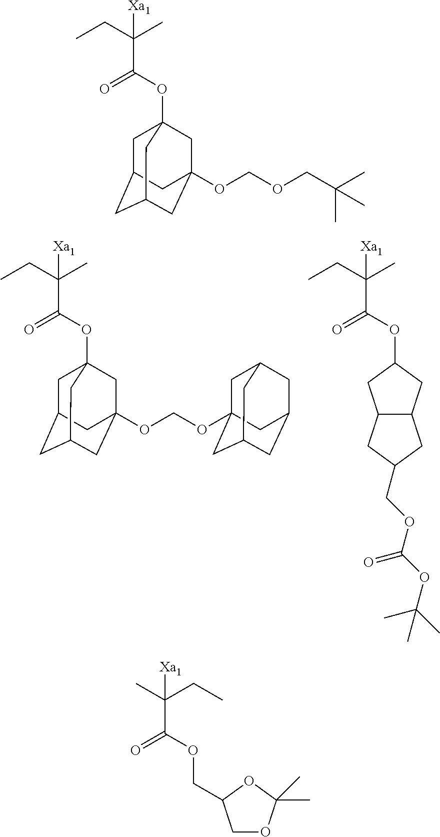

In addition, the resin (A) preferably has a repeating unit which is represented by General Formula (AI) below as a repeating unit which has an acid-decomposable group.

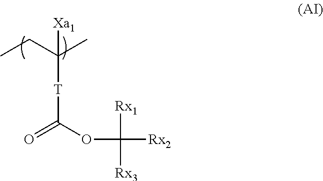

In General Formula (AI),

Xa₁ represents a hydrogen atom, an alkyl group, a cyano group, or a halogen atom.

T represents a single bond or a divalent linking group.

Rx₁ to Rx₃ each independently represents an alkyl group or a cycloalkyl group.

Two of Rx₁ to Rx₃ may form a ring structure by bonding with each other.

Examples of a divalent linking group of T include an alkylene group, a —COO-Rt- group, a —O-Rt- group, a phenylene group, and the like. In the formulas, Rt represents an alkylene group or a cycloalkylene group.

T is preferably a single bond or a —COO-Rt- group. Rt is preferably an alkylene group with 1 to 5 carbon atoms and more preferably a —CH₂— group, a —(CH₂)₂— group, or —(CH₂)₃— group. T is more preferably a single bond.

The alkyl group of Xa₁ may have a substituent group and examples of the substituent group include a hydroxy group and a halogen atom (preferably a fluorine atom).

The alkyl group of Xa₁ preferably has 1 to 4 carbon atoms and examples thereof include a methyl group, an ethyl group, a propyl group, a hydroxymethyl group, a trifluoromethyl group, and the like; however, a methyl group is preferable.

Xa₁ is preferably a hydrogen atom or a methyl group.

The alkyl groups of Rx₁, Rx₂, and Rx₃ may be a straight-chain form or a branched form and preferably have 1 to 4 carbon atoms, such as a methyl group, an ethyl group, an n-propyl group, an isopropyl group, an n-butyl group, an isobutyl group, and a t-butyl group.

The cycloalkyl groups of Rx₁, Rx₂, and Rx₃ are preferably monocyclic cycloalkyl groups such as a cyclopentyl group and a cyclohexyl group, or polycyclic cycloalkyl groups such as a norbornyl group, a tetracyclodecanyl group, a tetracyclododecanyl group, and an adamantyl group.

The ring structure formed by two of Rx₁, Rx₂, and Rx₃ bonding with each other is preferably a monocyclic cycloalkane ring such as a cyclopentyl ring and a cyclohexyl ring, or a polycyclic cycloalkyl group such as a norbornane ring, a tetracyclodecane ring, a tetracyclododecane ring, and an adamantane ring. A monocyclic cycloalkane ring with 5 or 6 carbon atoms is particularly preferable.

Rx₁, Rx₂, and Rx₃ are preferably each independently an alkyl group and more preferably a straight-chain or branched alkyl group with 1 to 4 carbon atoms.

Each of the groups described above may have a substituent group and examples of the substituent group include an alkyl group (with 1 to 4 carbon atoms), a cycloalkyl group (with 3 to 8 carbon atoms), a halogen atom, an alkoxy group (with 1 to 4 carbon atoms), a carboxyl group, an alkoxycarbonyl group (with 2 to 6 carbon atoms), and the like, and the number of carbon atoms is preferably 8 or less. Among these, from the point of view of improving the dissolution contrast with respect to a developer which contains an organic solvent more before and after being decomposed by an acid, a substituent group which does not have a hetero atom such as an oxygen atom, a nitrogen atom, and a sulfur atom is more preferable (for example, a substituent group which is not an alkyl group or the like which is substituted with a hydroxy group is more preferable), a group which is only formed of hydrogen atoms and carbon atoms is even more preferable, and a straight-chain or branched alkyl group and a cycloalkyl group are particularly preferable.

Specific examples of a repeating unit which is represented by General Formula (AI) will be given below; however, the present invention is not limited to the specific examples.

In the specific examples, Rx represents a hydrogen atom, CH₃, CF₃, or CH₂OH. Rxa and Rxb each represent an alkyl group with 1 to 4 carbon atoms. Xa₁ represents a hydrogen atom, CH₃, CF₃, or CH₂OH. Z represents a substituent group and a plurality of Z may be the same or different from each other in a case where a plurality are present. p represents 0 or a positive integer. Specific examples and preferable examples of Z are the same as the specific examples and preferable examples of the substituent group which each group such as Rx₁ to Rx₃ may have.

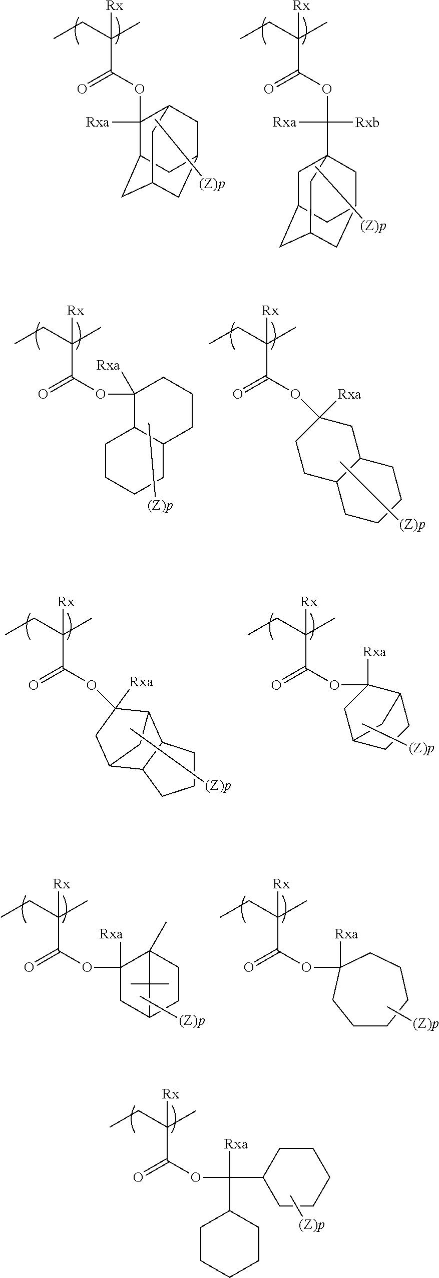

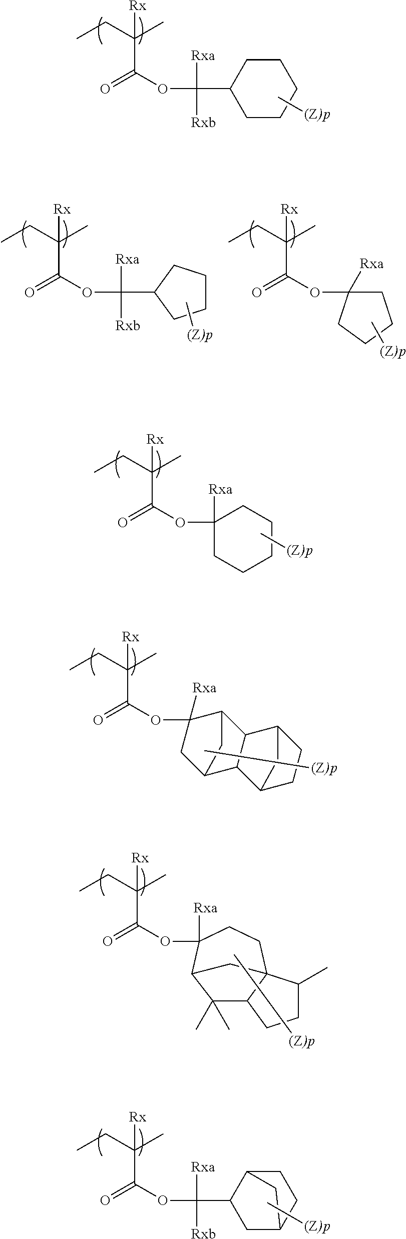

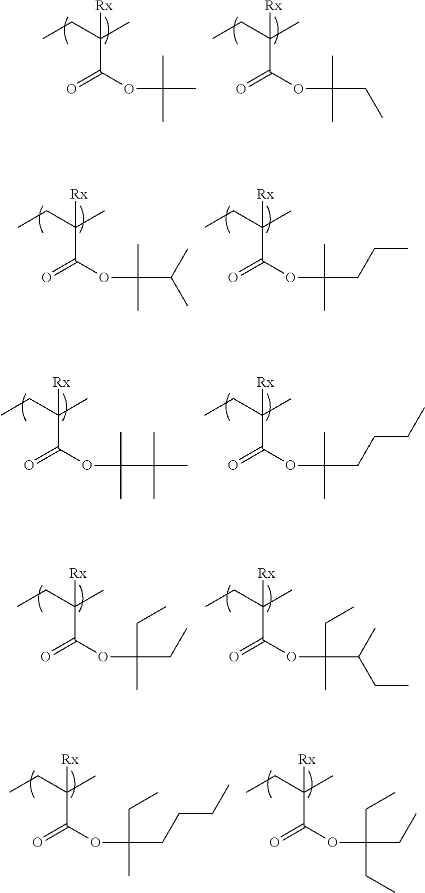

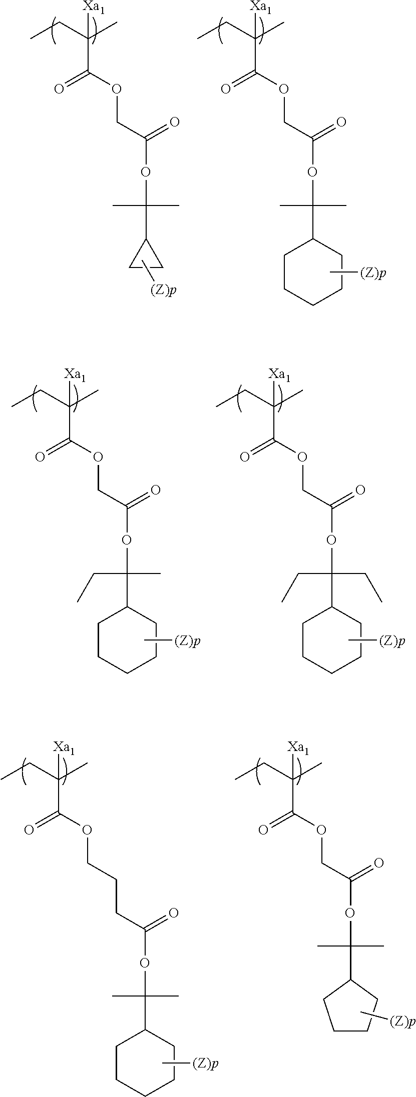

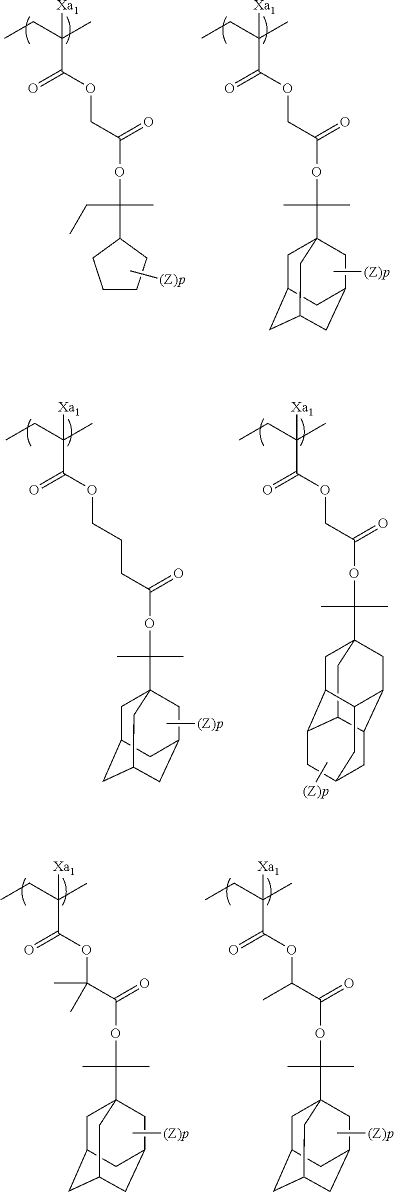

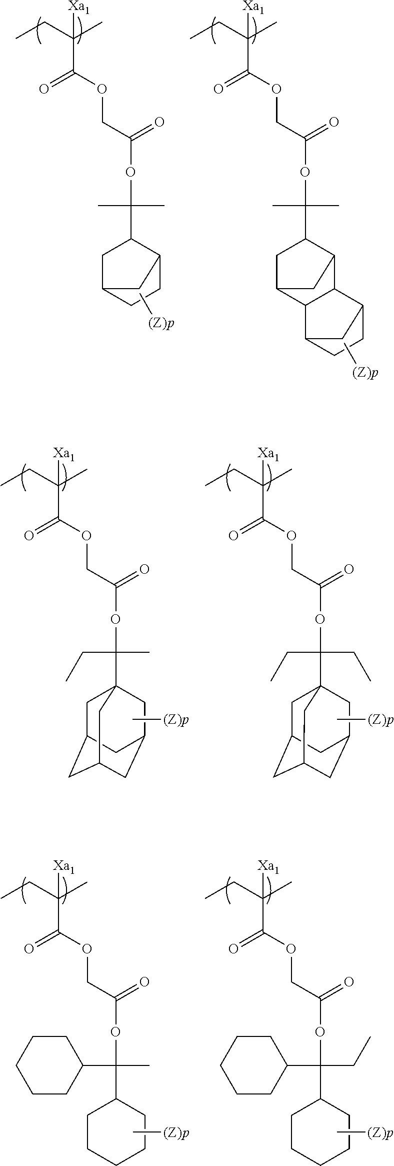

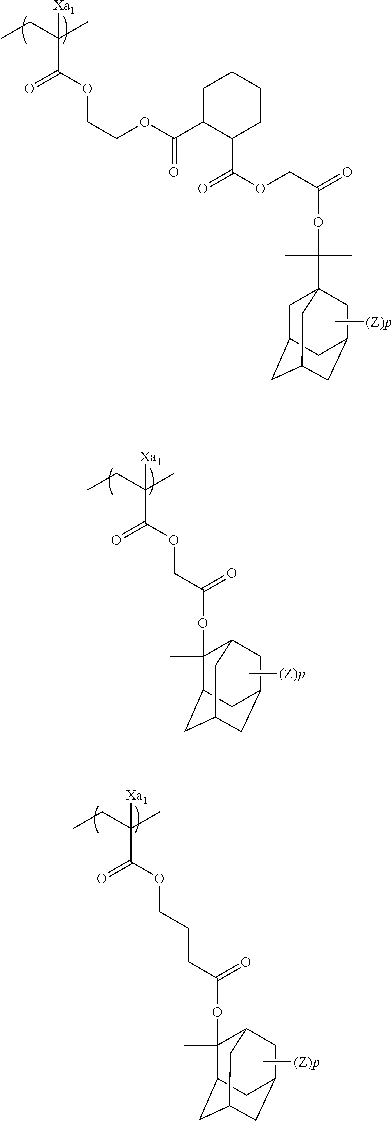

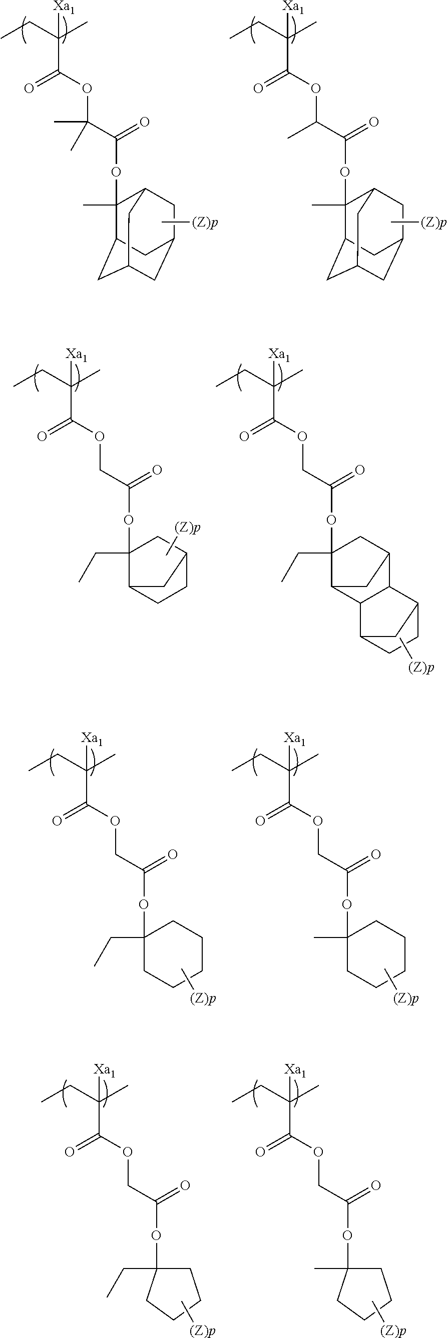

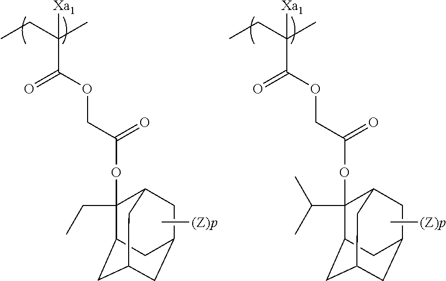

In the specific examples below, Xa represents a hydrogen atom, an alkyl group, a cyano group, or a halogen atom.

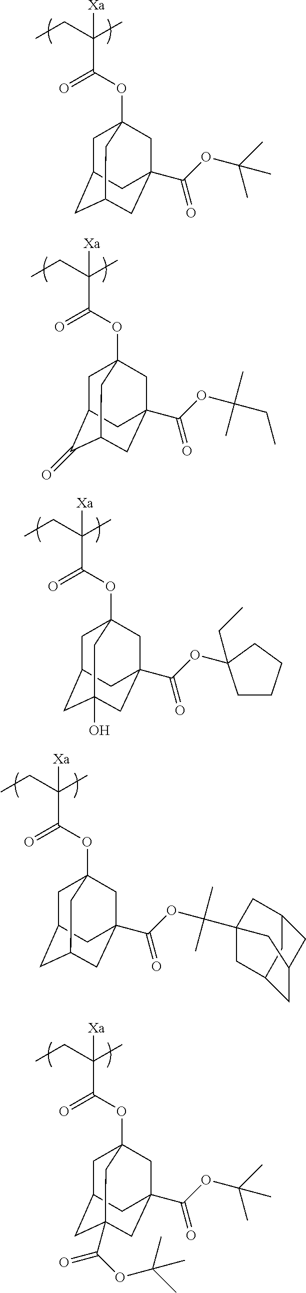

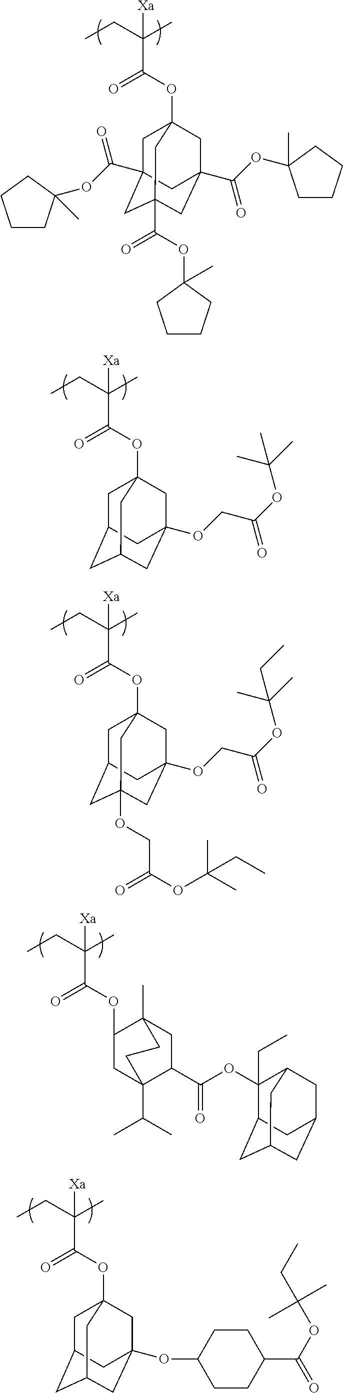

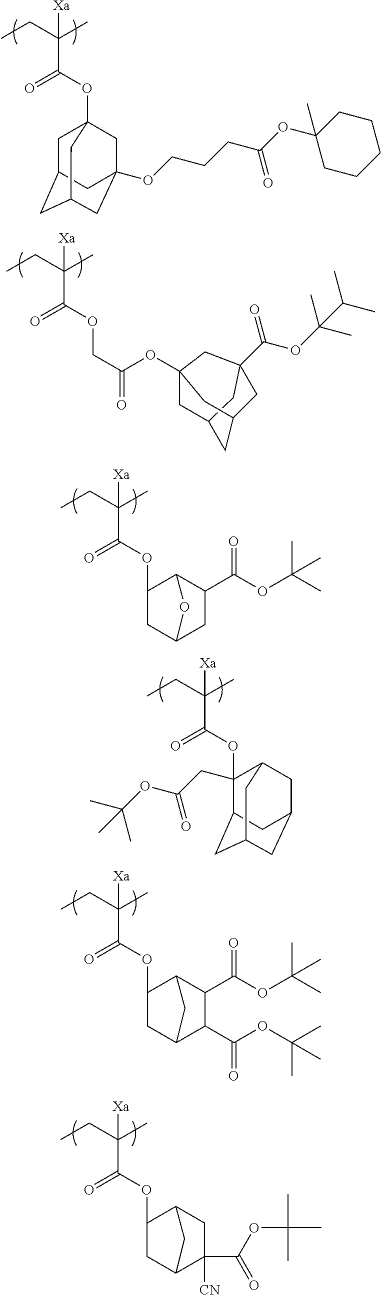

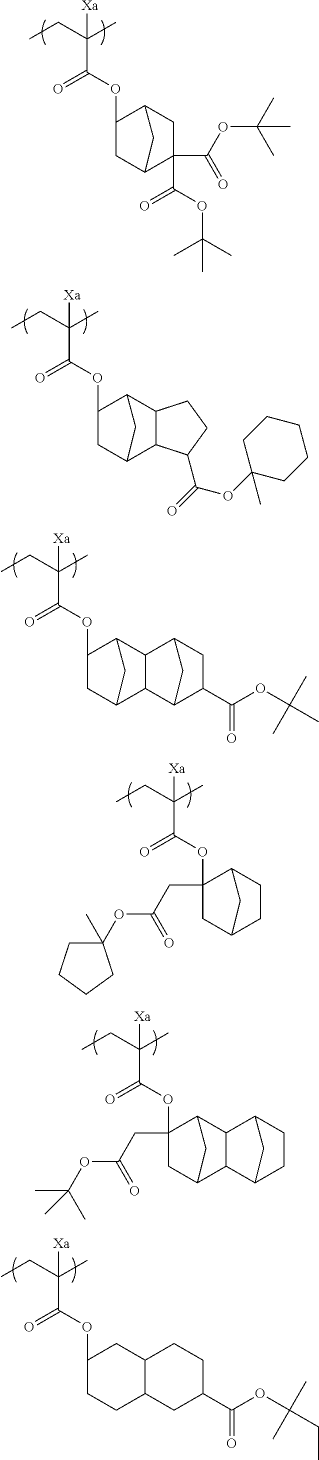

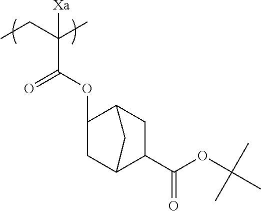

A repeating unit which has an acid-decomposable group may be one type or two or more types may be used together. Examples of specific combinations in a case of using two or more types together are not particularly limited but include the following.

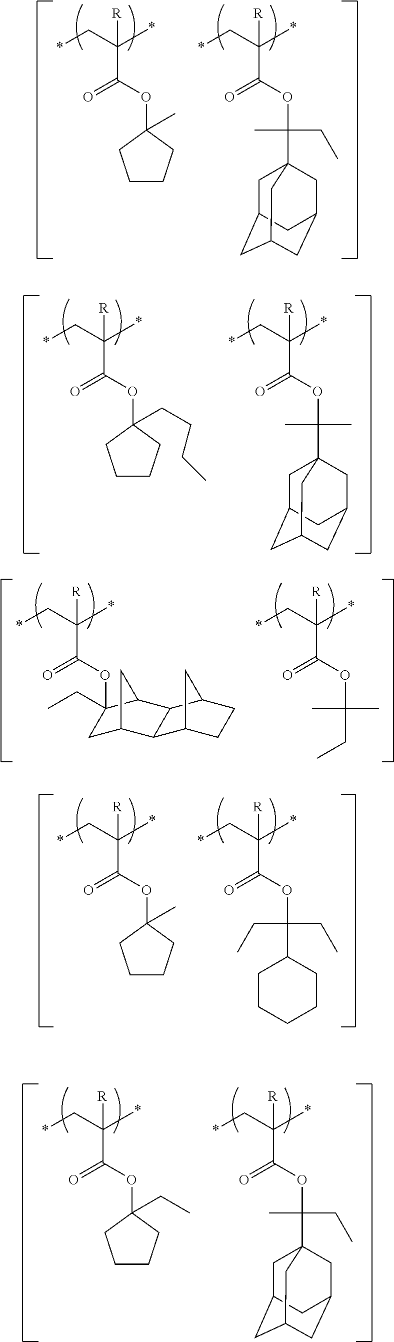

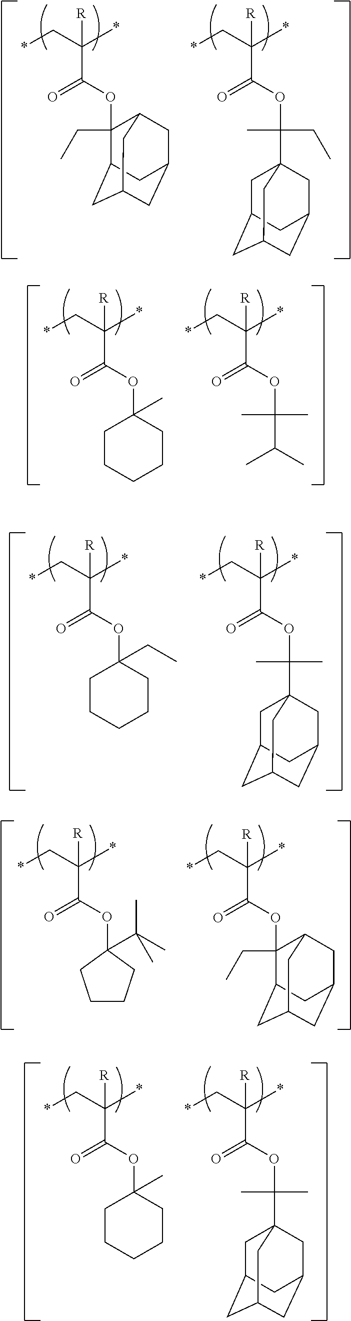

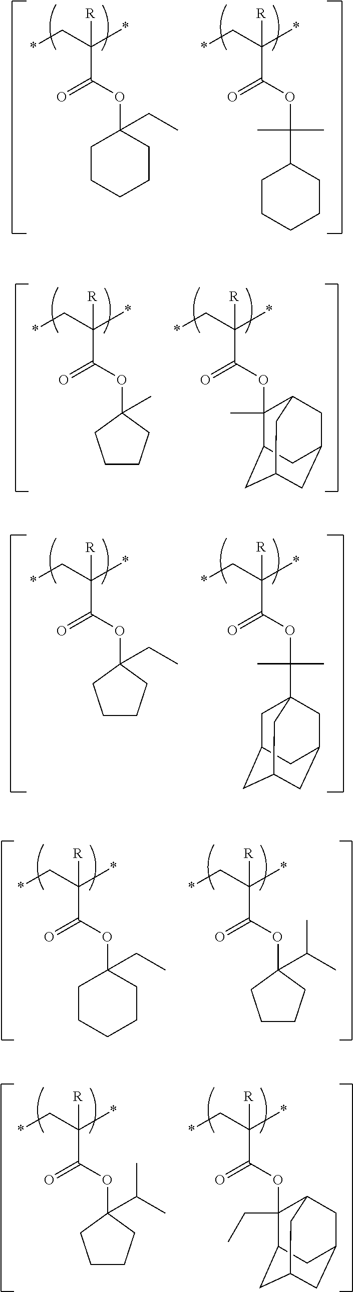

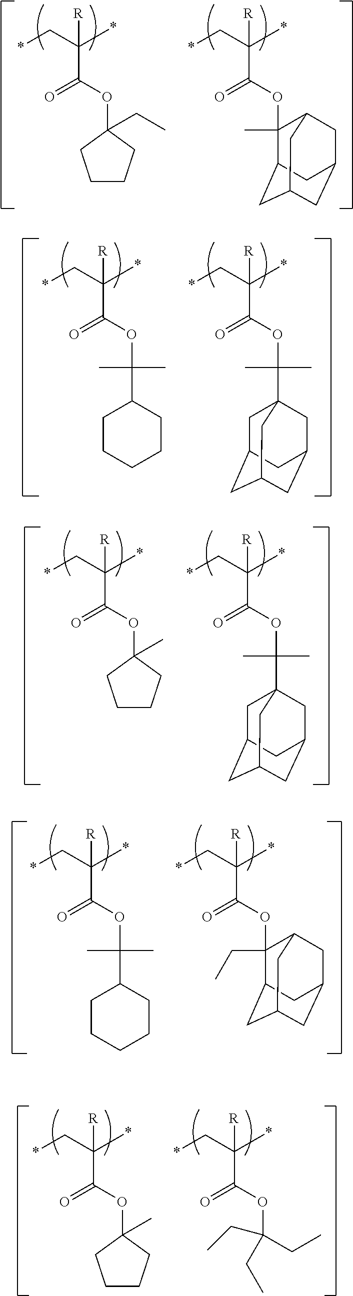

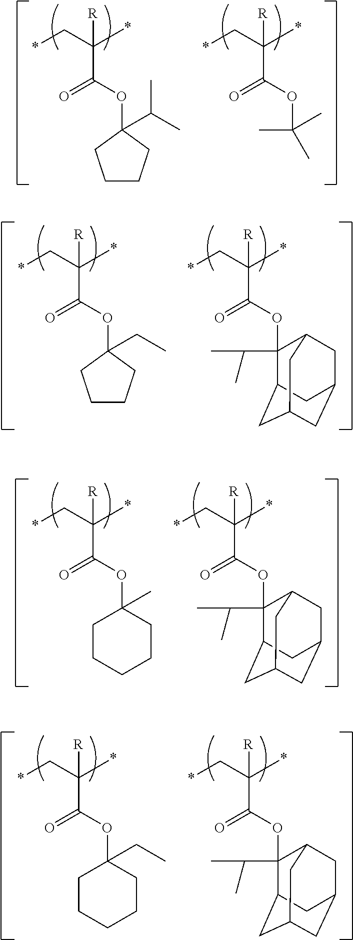

The content ratio of a repeating unit which has an acid-decomposable group which is included in the resin (A) (the total thereof in a case where a plurality of the repeating units which have an acid-decomposable group are present) is preferably 30 mol % or more with respect to all of the repeating units of the resin (A), more preferably 40 mol % or more, even more preferably 50 mol % or more, and particularly preferably 55 mol % or more. Among these, in addition to the resin (A) having the repeating unit which is represented by General Formula (AI) described above, the content of the repeating unit which is represented by General Formula (AI) with respect to all of the repeating units of the resin (A) is preferably 40 mol % or more.

In addition, the content of the repeating unit which has an acid-decomposable group is preferably 80 mol % or less with respect to all of the repeating units of the resin (A), preferably 75 mol % or less, and more preferably 70 mol % or less.

The resin (A) may further contain a repeating unit which has a different lactone structure from the repeating unit (a) described above or a repeating unit which has a sultone structure.

As a lactone structure or a sultone structure, it is possible to use any structure which has a lactone structure or a sultone structure; however, a 5 to 7 membered ring lactone structure or a 5 to 7 membered ring sultone structure is preferable and a 5 to 7 membered ring lactone structure on which another ring structure is condensed in a form which forms a bicyclo structure, and a spiro structure or a 5 to 7 membered ring sultone structure on which another ring structure is condensed in a form which forms a bicyclo structure and a spiro structure are more preferable. It is more preferable to have a repeating unit which has a lactone structure which is represented by any of General Formulas (LC1-1) to (LC1-21) below or a sultone structure which is represented by any of General Formulas (SL1-1) to (SL1-3) below. In addition, a lactone structure or a sultone structure may be directly bonded to the main chain. Preferable lactone structures are (LC1-1), (LC1-4), (LC1-5), (LC1-6), (LC1-13), (LC1-14), and (LC1-17) and a particularly preferable lactone structure is (LC1-4). By using the specific lactone structure, the LER and developing defects become favorable.

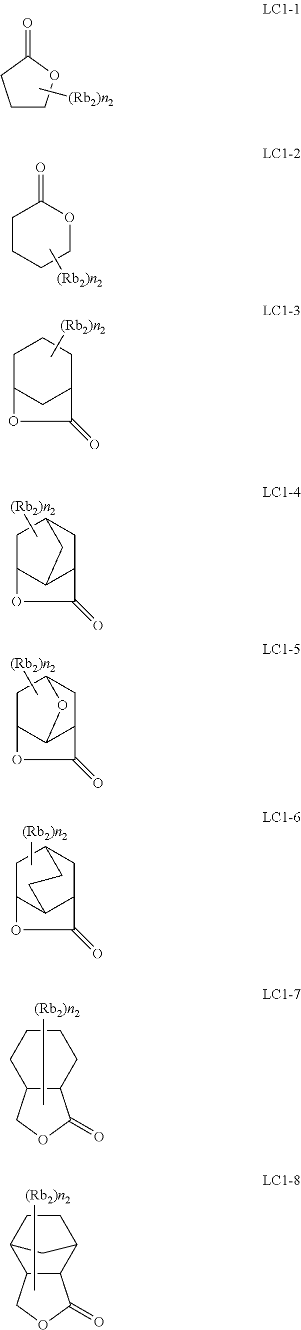

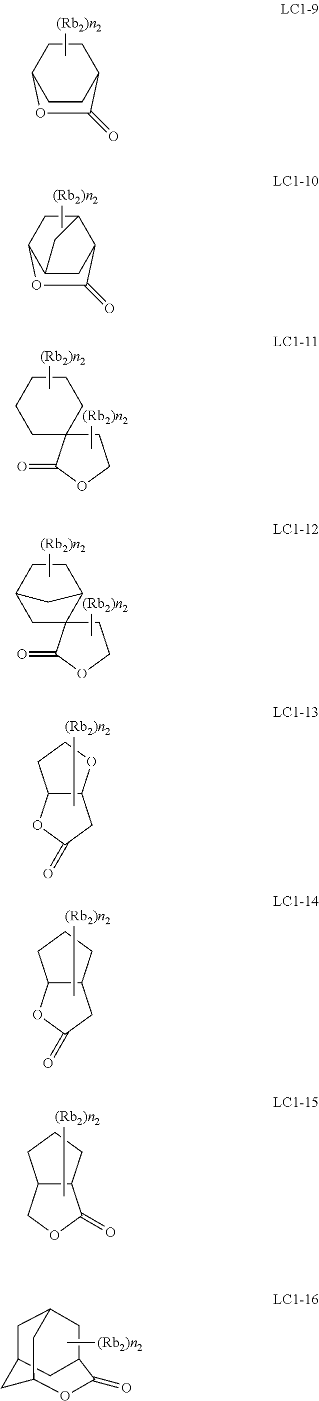

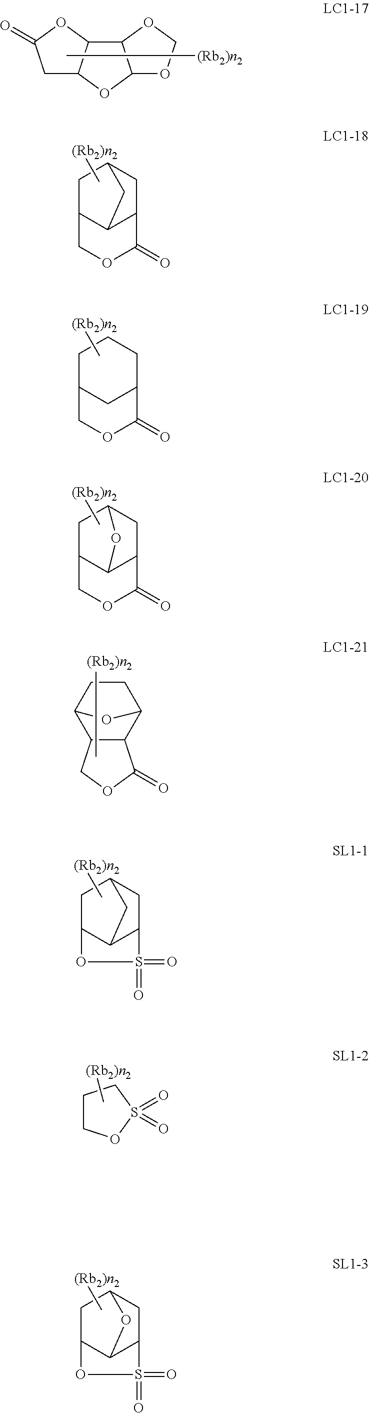

The lactone structure portion or the sultone structure portion may or may not have a substituent group (Rb₂). Examples of a preferable substituent group (Rb₂) include an alkyl group with 1 to 8 carbon atoms, a cycloalkyl group with 4 to 7 carbon atoms, an alkoxy group with 1 to 8 carbon atoms, an alkoxycarbonyl group with 2 to 8 carbon atoms, a halogen atom, a hydroxy group, a cyano group, an acid-decomposable group, and the like. An alkyl group with 1 to 4 carbon atoms, a cyano group, and an acid-decomposable group are more preferable. n₂ represents an integer of 0 to 4. When n₂ is 2 or more, a plurality of substituent groups (Rb₂) may the same or may be different. In addition, the plurality of substituent groups (Rb₂) may form a ring by bonding with each other.

In a repeating unit which has a lactone structure or a sultone structure, an optical isomer is generally present; however, any optical isomer may be used. In addition, one type of optical isomer may be used individually or a plurality of optical isomers may be used in a mixture. In a case of mainly using one type of optical isomer, the optical purity (ee) thereof is preferably 90% or more and more preferably 95% or more.

A repeating unit which has a lactone structure or a sultone structure is preferably a repeating unit which is represented by General Formula (III) below.

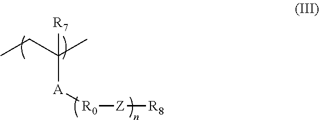

In General Formula (III) described above,

A represents an ester bond (a group which is represented by —COO—) or an amide bond (a group which is represented by —CONH—).

In a case where there are a plurality of R₀, the R₀ each independently represents an alkylene group, a cycloalkylene group, or a combination thereof.

In a case where there are a plurality of Z, the Z each independently represents a single bond, an ether bond, an ester bond, an amide bond, a urethane bond

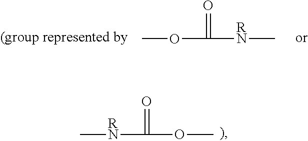

or a urea bond.

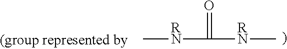

Here, R each independently represents a hydrogen atom, an alkyl group, a cycloalkyl group, or an aryl group.

R₈ represents a monovalent organic group which has a lactone structure or a sultone structure.

n is the number of repetitions of a structure which is represented by —R₀—Z—, represents an integer of 0 to 5, and is preferably an integer of 0 or 1 and more preferably 0. In a case where n is 0, —R₀—Z— is not present. Namely, there is a single bond between A and R₈.

R₇ represents a hydrogen atom, a halogen atom, or an alkyl group.

The alkylene group and the cycloalkylene group of R₀ may have a substituent group.

Z is preferably an ether bond or an ester bond and particularly preferably an ester bond.

The alkyl group of R₇ is preferably an alkyl group with 1 to 4 carbon atoms, more preferably a methyl group and an ethyl group, and particularly preferably a methyl group.

The alkylene group and the cycloalkylene group of R₀ and the alkyl group in R₇ may each be substituted and examples of substituent groups include a halogen atom such as a fluorine atom, a mercapto group, a hydroxy group, an alkoxy group, and an acyloxy group.

R₇ is preferably a hydrogen atom, a methyl group, a trifluoromethyl group, or a hydroxymethyl group.

A preferable chain alkylene group in R₀ is preferably a chain alkylene group with 1 to 10 carbon atoms and examples thereof include a methylene group, an ethylene group, a propylene group, and the like. A preferable cycloalkylene group is a cycloalkylene group with 3 to 20 carbon atoms and examples thereof include a cyclohexylene group, a cyclopentylene group, a norbornylene group, an adamantylene group, and the like. In order to exhibit the effects of the present invention, a chain alkylene group is more preferable and a methylene group is particularly preferable.

A monovalent organic group which has a lactone structure or a sultone structure which is represented by R₈ is not limited as long as the structure has a lactone structure or a sultone structure and specific examples thereof include a lactone structure or a sultone structure which is represented by any of General Formulas (LC1-1) to (LC1-21) and (SL1-1) to (SL1-3) and, among these, a structure which is represented by (LC1-4) is particularly preferable. In addition, n₂ in (LC1-1) to (LC1-21) is more preferably 2 or less.

In addition, R₈ is preferably a monovalent organic group which has an unsubstituted lactone structure or sultone structure or a monovalent organic group which has a lactone structure or a sultone structure which has a methyl group, a cyano group, or an alkoxycarbonyl group as a substituent group, and a monovalent organic group which has a lactone structure (cyanolactone) which has a cyano group as a substituent group is more preferable.

Specific examples of a repeating unit which has a group which has a lactone structure or a sultone structure will be shown below; however, the present invention is not limited thereto.

(In the formula, Rₓ represents H, CH₃, CH₂OH, or CF₃)

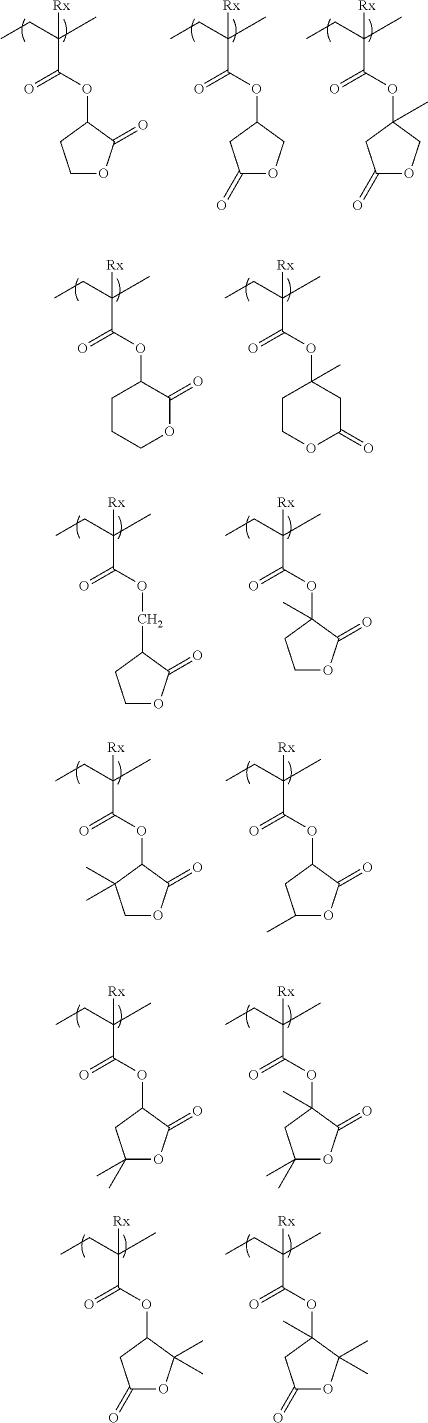

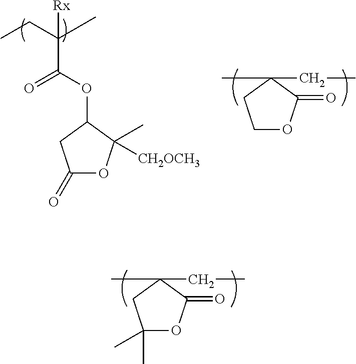

(In the formula, Rₓ represents H, CH₃, CH₂OH, or CF₃)

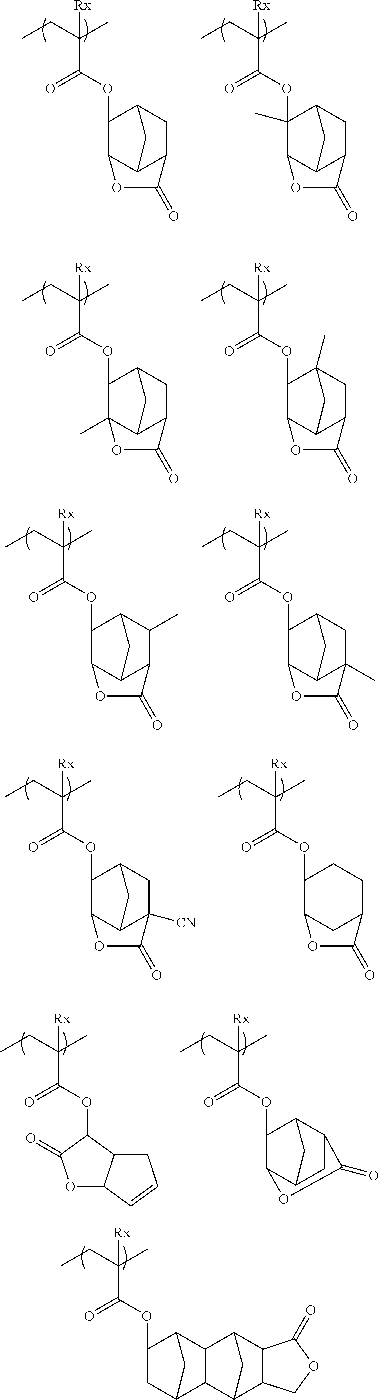

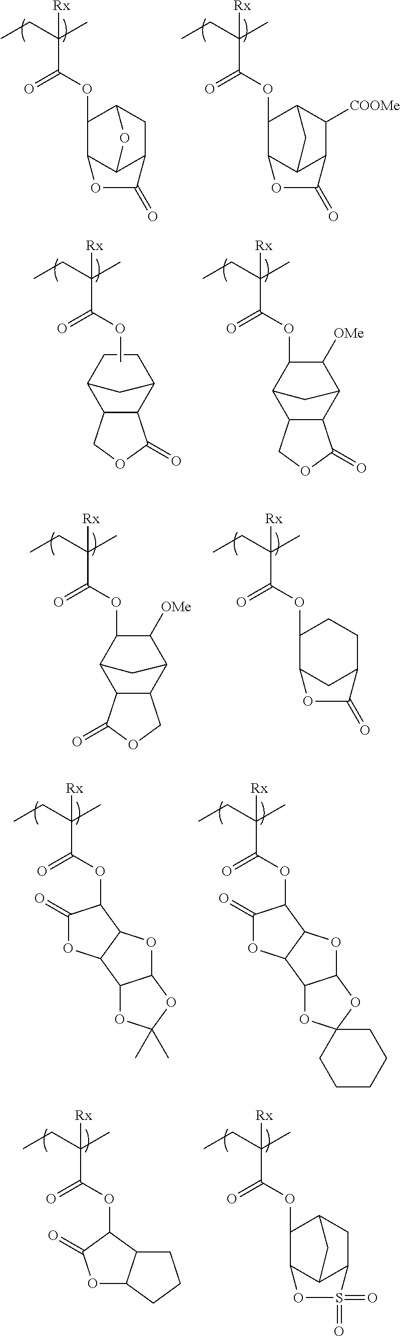

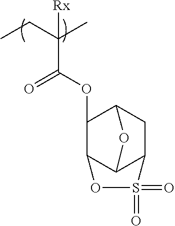

(In the formula, Rₓ represents H, CH₃, CH₂OH, or CF₃)

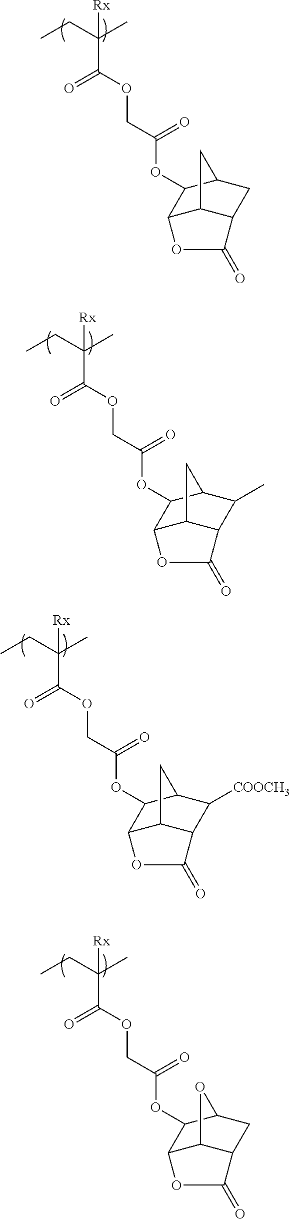

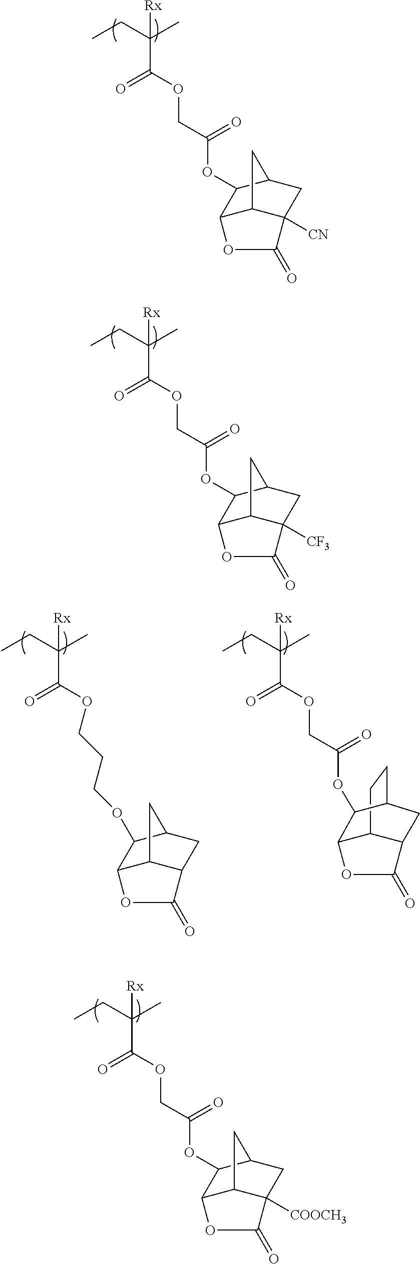

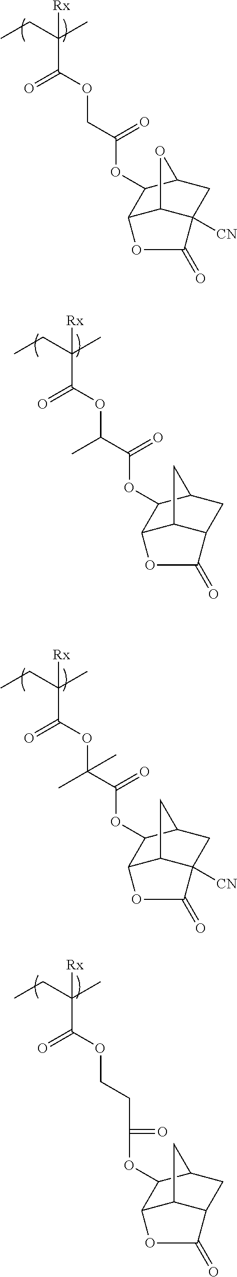

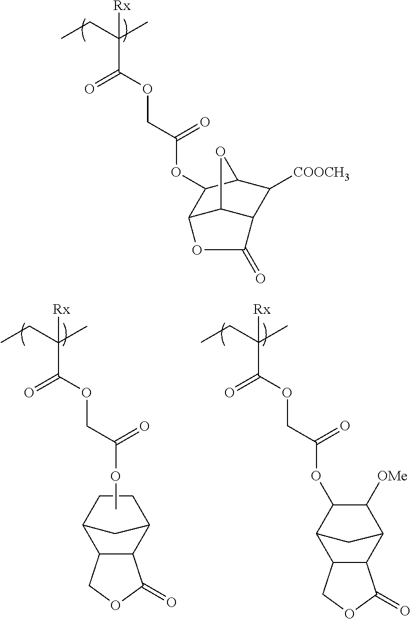

In order to increase the effect of the present invention, it is also possible to use two or more types of repeating units which have a lactone structure or a sultone structure together.

In a case where the resin (A) contains a repeating unit (excluding the repeating unit (a)) which has a lactone structure or a sultone structure, the content of the repeating unit which has a lactone structure or a sultone structure is preferably 5 mol % to 60 mol % with respect to all of the repeating units in the resin (A), more preferably 5 mol % to 55 mol %, and even more preferably 10 mol % to 50 mol %.

In addition, the resin (A) may have a repeating unit which has a cyclic carbonic ester structure.

The repeating unit which has a cyclic carbonic ester structure is preferably a repeating unit which is represented by General Formula (A-1) below.

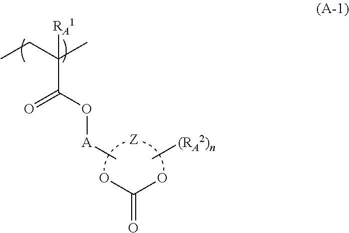

In General Formula (A-1), R_{A}¹ represents a hydrogen atom or an alkyl group.

R_{A}² each independently represents a substituent group in a case where n is 2 or more.

A represents a single bond or a divalent linking group.

Z represents an atomic group which forms a monocyclic or polycyclic structure with a group which is represented by —O—C(═O)—O— in the formula.

n represents an integer of 0 or more.

Detailed description will be given of General Formula (A-1).

An alkyl group which is represented by R_{A}¹ may have a substituent group such as a fluorine atom. R_{A}¹ preferably represents a hydrogen atom, a methyl group, or a trifluoromethyl group and more preferably represents a methyl group.

A substituent group which is represented by R_{A}² is, for example, an alkyl group, a cycloalkyl group, a hydroxyl group, an alkoxy group, an amino group, and an alkoxycarbonylamino group.

n represents the number of substituent groups and is an integer of 0 or more. n is, for example, preferably 0 to 4 and more preferably 0.

Examples of a divalent linking group which is represented by A include an alkylene group, a cycloalkylene group, an ester bond, an amide bond, an ether bond, a urethane bond, a urea bond, or a combination thereof, and the like. The alkylene group is preferably an alkylene group with 1 to 10 carbon atoms and examples thereof include a methylene group, an ethylene group, a propylene group, and the like.

In an aspect of the present invention, A is preferably a single bond or an alkylene group.

Examples of a single ring which includes —O—C(═O)—O— which is represented by Z include a 5 to 7 membered ring where n_{A}=2 to 4 in a cyclic carbonic ester which is represented by General Formula (a) below and a 5 membered ring or a 6 membered ring (n_{A}=2 or 3) is preferable and a 5 membered ring (n_{A}=2) is more preferable.

Examples of a polycyclic ring which includes —O—C(═O)—O— which is represented by Z include a structure in which a cyclic carbonic ester which is represented by General Formula (a) below forms a condensed ring with one or two or more of other ring structures, or a structure which forms a spiro ring. “Other ring structures” which may form a condensed ring or a spiro ring may be an alicyclic hydrocarbon group, may be an aromatic hydrocarbon group, or may be a hetero ring.

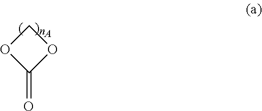

In the resin (A), one type out of the repeating units which are represented by General Formula (A-1) may be included individually, or two or more types may be included.

In the resin (A), the content ratio of a repeating unit which has a cyclic carbonic ester structure (preferably a repeating unit which is represented by General Formula (A-1)) is preferably 3 mol % to 80 mol % with respect to all of the repeating units which configure the resin (A), more preferably 3 mol % to 60 mol %, particularly preferably 3 mol % to 30 mol %, and most preferably 10 mol % to 15 mol %. By setting such a content ratio, it is possible to improve the developing property, lower the defects, lower the LWR, lower the PEB temperature dependency, improve the profile, and the like as a resist.

Specific examples of the repeating units which are represented by General Formula (A-1) (repeating units (A-1a) to (A-1w)) will be given below; however, the present invention is not limited thereto.

Here, R_{A}′ in the specific examples below are the same as R_{A}′ in General Formula (A-1).

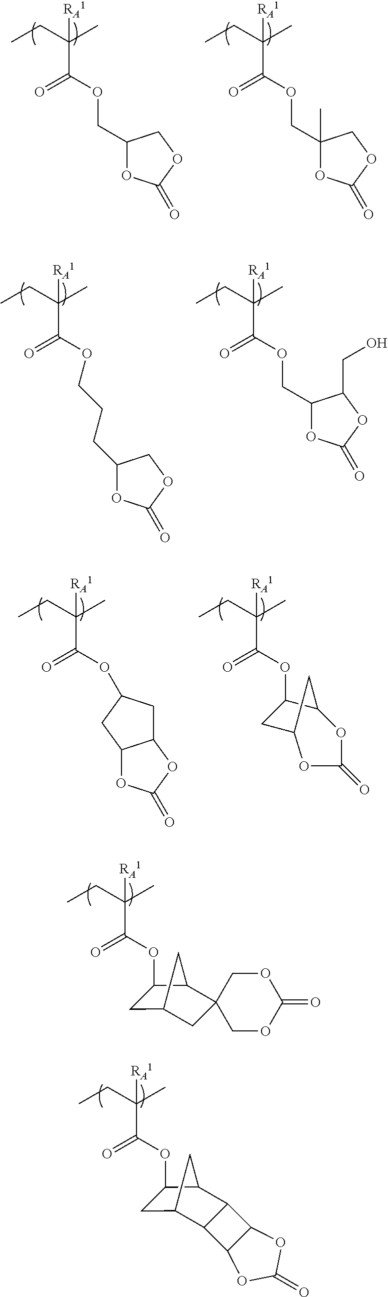

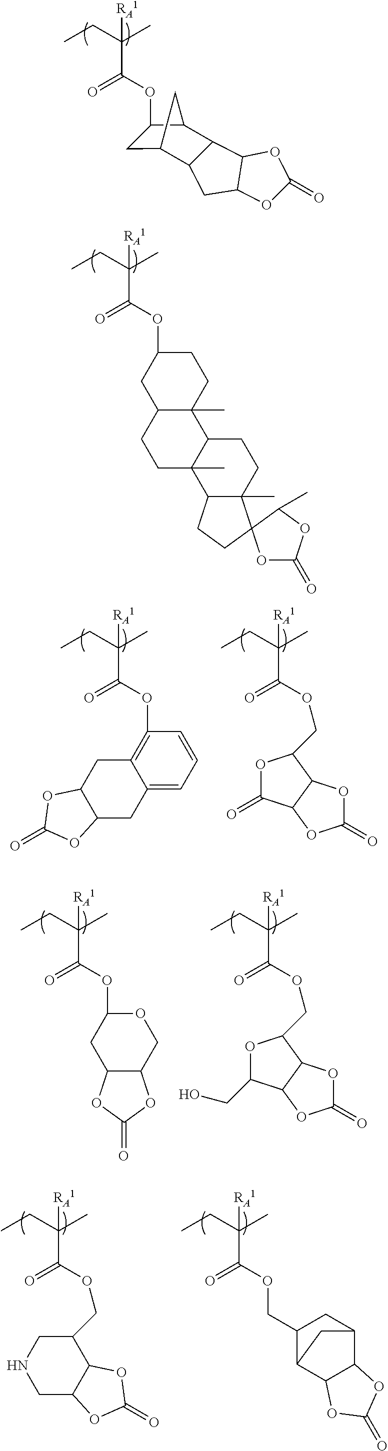

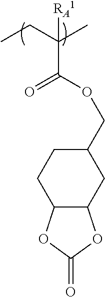

The resin (A) may have a repeating unit which has a hydroxy group or a cyano group. Due to this, the substrate adhesiveness and developer compatibility are improved. The repeating unit which has a hydroxy group or a cyano group is preferably a repeating unit which has an alicyclic hydrocarbon structure which is substituted with a hydroxy group or a cyano group and preferably does not have an acid-decomposable group.

In addition, the repeating unit which has an alicyclic hydrocarbon structure which is substituted with a hydroxy group or a cyano group is preferably different from a repeating unit which has an acid-decomposable group (that is, is preferably a repeating unit which is stable with respect to an acid).

The alicyclic hydrocarbon structure in the alicyclic hydrocarbon structure which is substituted with a hydroxy group or a cyano group is preferably an adamantyl group, diamantyl group, and a norbornane group.

More preferable examples thereof include the repeating units which are represented by any of General Formulas (AIIa) to (AIIc) below.

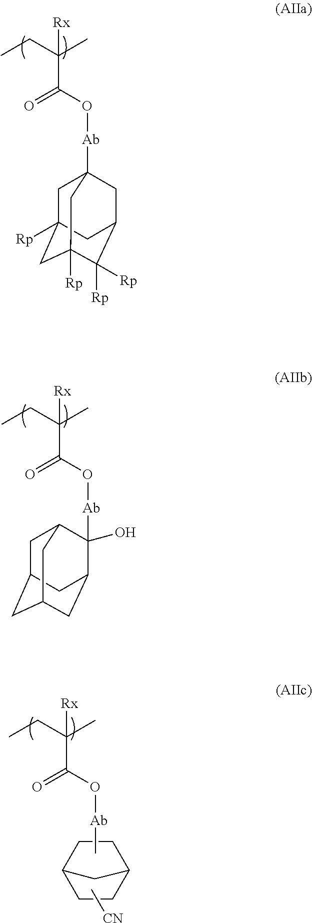

In the formulas, R_{X} represents a hydrogen atom, a methyl group, a hydroxymethyl group, or a trifluoromethyl group.

Ab represents a single bond or a divalent linking group.

Examples of the divalent linking group which is represented by Ab include an alkylene group, a cycloalkylene group, an ester bond, an amide bond, an ether bond, a urethane bond, a urea bond, or a combination thereof, and the like. The alkylene group is preferably an alkylene group with 1 to 10 carbon atoms and more preferably an alkylene group with 1 to 5 carbon atoms and examples thereof include a methylene group, an ethylene group, a propylene group, and the like.

In an aspect of the present invention, Ab is preferably a single bond or an alkylene group.

Rp represents a hydrogen atom, a hydroxyl group, or a hydroxyalkyl group. A plurality of Rp may be the same or may be different; however, at least one out of the plurality of Rp represents a hydroxyl group or a hydroxyalkyl group.

The resin (A) may contain or may not contain a repeating unit which has a hydroxy group or a cyano group; however, in a case where the resin (A) contains a repeating unit which has a hydroxy group or a cyano group, the content of the repeating unit which has a hydroxy group or a cyano group is preferably 1 mol % to 40 mol % with respect to all of the repeating units in the resin (A), more preferably 3 mol % to 30 mol %, and even more preferably 5 mol % to 25 mol %.

Specific examples of the repeating unit which has a hydroxy group or a cyano group will be given below; however, the present invention is not limited thereto.

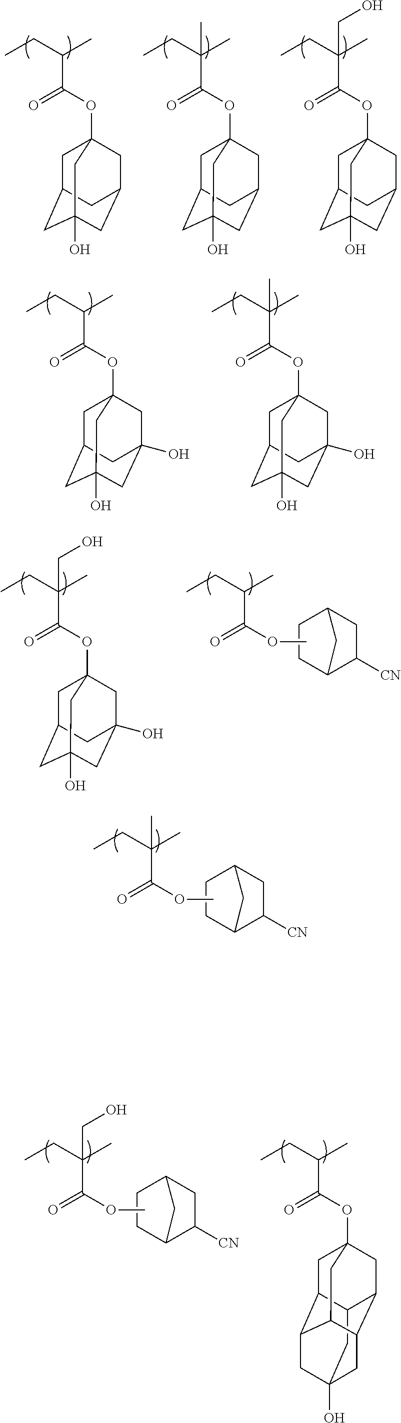

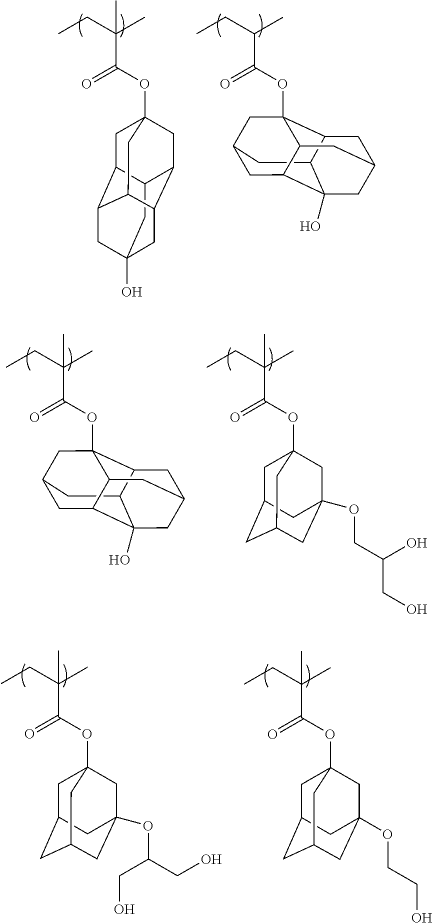

Other than these, it is also possible to appropriately use the monomers described in paragraph “0011” and beyond in WO2011/122336A, repeating units corresponding thereto, and the like.

The resin (A) may have a repeating unit which has an acidic group (excluding the repeating unit (a)). Examples of the acidic group include a carboxyl group, a sulfonamide group, a sulfonylimide group, a bissulfonylimide group, a naphthol structure, and an aliphatic alcohol group in which the α-position is substituted with an electron-withdrawing group (for example, a hexafluoroisopropanol group) and it is more preferable to have a repeating unit which has a carboxyl group. By containing a repeating unit which has an acidic group, the resolution for contact hole usage increases. As the repeating unit which has an acidic group, any of a repeating unit in which an acidic group is directly bonded to the main chain of a resin such as a repeating unit using acrylic acid or methacrylic acid, or a repeating unit in which an acidic group is bonded to the main chain of a resin via a linking group, and moreover, introduction to the end of a polymer chain using a polymerization initiator or a chain transfer agent which has an acidic group during the polymerization is preferable and the linking group may have a monocyclic or polycyclic cyclic hydrocarbon structure. A repeating unit using acrylic acid or methacrylic acid is particularly preferable.

The resin (A) may or may not contain a repeating unit which has an acidic group; however, when contained, the content of the repeating unit which has an acidic group is preferably 25 mol % or less with respect to all of the repeating units in the resin (A) and more preferably 20 mol % or less. In a case where the resin (A) contains a repeating unit which has an acidic group, the content of the repeating unit which has an acidic group in the resin (A) is generally 1 mol % or more.

Specific examples of the repeating unit which has an acidic group will be shown below; however, the present invention is not limited thereto. In the specific examples, Rx represents H, CH₃, CH₂OH, or CF₃.

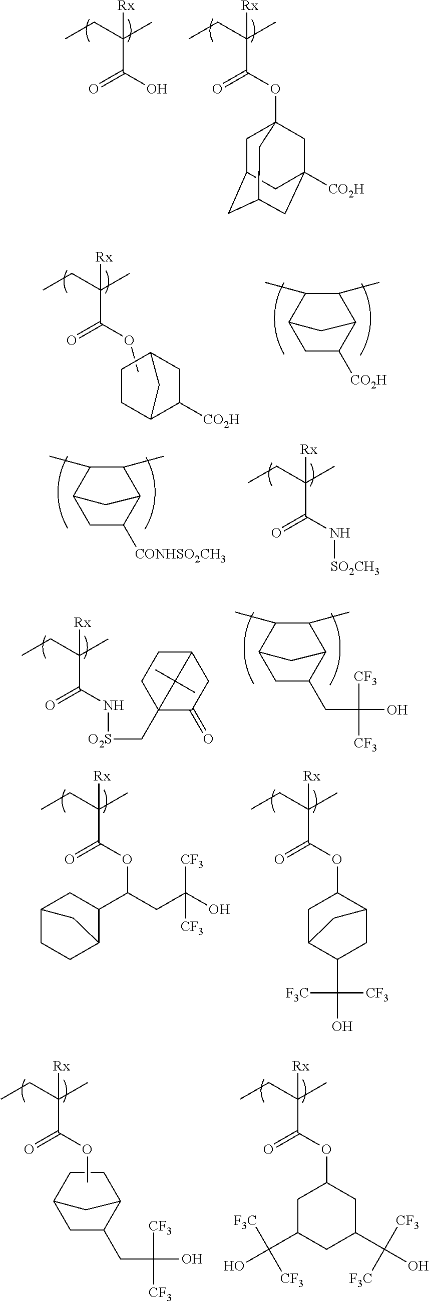

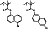

The resin (A) in the present invention is able to further have a repeating unit which has an alicyclic hydrocarbon structure which does not have a polar group (for example, the acidic group, the hydroxyl group, or the cyano group) and which does not exhibit acid decomposability. Due to this, in addition to it being possible to reduce the elution of low molecular components from a resist film into the immersion liquid during liquid immersion exposure, it is possible to appropriately adjust the solubility of a resin during development which uses a developer which includes an organic solvent. Examples of such a repeating unit include the repeating unit which is represented by General Formula (IV).

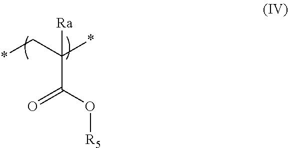

In General Formula (IV), R₅ represents a hydrocarbon group which has least one ring structure and does not have a polar group.

Ra represents a hydrogen atom, an alkyl group, or a —CH₂—O—Ra_{z} group. In the formula, Ra₂ represents a hydrogen atom, an alkyl group or an acyl group. Ra is preferably a hydrogen atom, a methyl group, a hydroxymethyl group, or a trifluoromethyl group and is particularly preferably a hydrogen atom or a methyl group.

The ring structure of R₅ includes monocyclic hydrocarbon groups and polycyclic hydrocarbon groups. Examples of the monocyclic hydrocarbon group include cycloalkyl groups with 3 to 12 carbon atoms such as a cyclopentyl group, a cyclohexyl group, a cycloheptyl group, and a cyclooctyl group and cycloalkenyl groups with 3 to 12 carbon atoms such as a cyclohexenyl group. A preferable monocyclic hydrocarbon group is a monocyclic hydrocarbon group with 3 to 7 carbon atoms and more preferable examples thereof include a cyclopentyl group and a cyclohexyl group.

A ring-aggregated hydrocarbon group and a cross-linked cyclic hydrocarbon group are included in the polycyclic hydrocarbon group and examples of the ring-aggregated hydrocarbon group include a bicyclohexyl group, a perhydronaphthalenyl group, and the like. Examples of a cross-linked cyclic hydrocarbon ring include a 2-ring type hydrocarbon ring such as pinane, bornane, norpinane, norbornane, or a bicyclooctane ring (a bicyclo[2.2.2]octane ring, a bicyclo[3.2.1]octane ring, and the like), a 3-ring type hydrocarbon ring such as homobledane, adamantane, tricyclo[5.2.1.0^{2,6}]decane, or a tricyclo[4.3.1.1^{2,5}]undecane ring, and a 4-ring type hydrocarbon ring such as tetracyclo[4.4.0.1^{2,5}0.1^{7,10}]dodecane or a perhydro-1,4-methano-5,8-methanonaphthalene ring. In addition, a condensed cyclic hydrocarbon ring, for example, a condensed ring where a plurality of 5 to 8 membered cycloalkane rings are condensed such as perhydronaphthalene (decaline), perhydroanthracene, perhydrophenanthrene, perhydroacenaphthene, perhydrofluorene, perhydroindene, and perhydrophenalene rings are also included in the cross-linked cyclic hydrocarbon ring.

Preferable examples of a cross-linked cyclic hydrocarbon ring include a norbornyl group, an adamantyl group, a bicyclooctanyl group, a tricyclo[5,2,1,0^{2,6}]decanyl group, and the like. More preferable examples of a cross-linked cyclic hydrocarbon ring include a norbonyl group and an adamantyl group.

These alicyclic hydrocarbon groups may have a substituent group and preferable examples of substituent groups include a halogen atom, an alkyl group, a hydroxyl group in which a hydrogen atom is substituted, an amino group in which a hydrogen atom is substituted, and the like.

The resin (A) may or may not contain a repeating unit which has an alicyclic hydrocarbon structure which does not have a polar group and does not exhibit acid decomposability; however, when contained, the content of the repeating unit is preferably 1 mol % to 50 mol % with respect to all of the repeating units in the resin (A), more preferably 5 mol % to 50 mol %, and even more preferably 5 mol % to 25 mol %.

Specific examples of a repeating unit which has an alicyclic hydrocarbon structure which does not have a polar group and does not exhibit acid decomposability will be given below; however, the present invention is not limited thereto. In the formulas, Ra represents H, CH₃, CH₂OH, or CF₃.

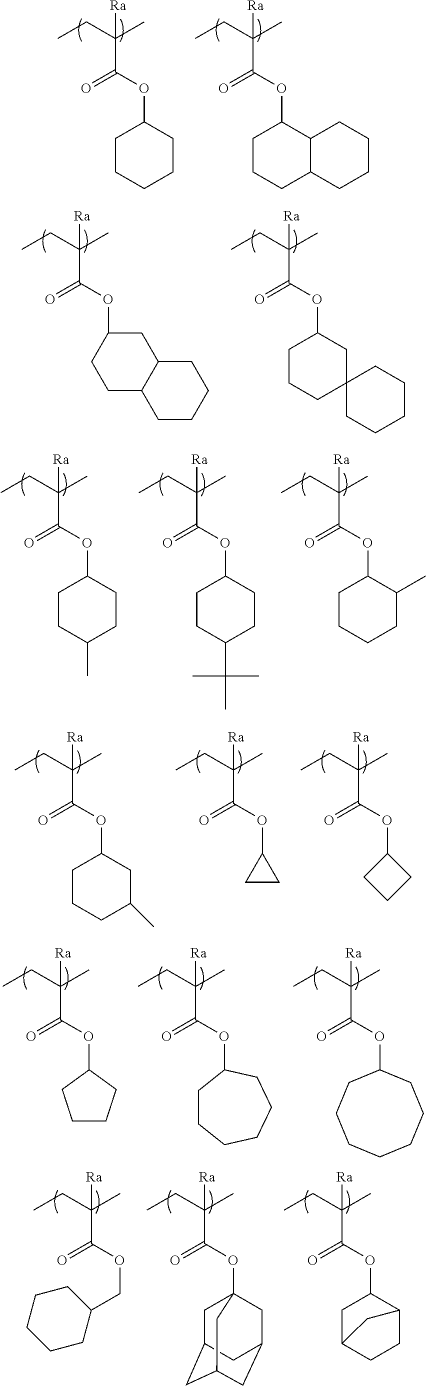

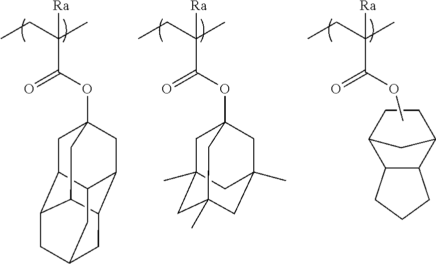

The resin (A) which is used for the composition of the present invention is able to have various types of repeating structure units other than the repeating structure units described above for the purpose of adjusting the dry etching resistance or standard developing solution aptitude, the substrate adhesiveness, and the resist profile, and, moreover, resolving power, heat resistance, sensitivity, and the like which are typical necessary characteristics for active light sensitive or radiation sensitive resin compositions.

Examples of such repeating structure units include repeating structure units which are equivalent to the monomers described below; however, the present invention is not limited thereto.

Due to this, it is possible to carry out fine adjustment of the properties which are demanded for the resins which are used for the compositions according to the present invention, in particular,

(1) solubility with respect to a coating solvent,

(2) film-forming property (glass transition temperature),

(3) alkali developing characteristics,

(4) film loss (hydrophilic-hydrophobic properties and alkali-soluble group selection),

(5) adhesiveness of an unexposed section of a substrate,

(6) dry etching resistance, and the like.

Examples of the monomers include compounds or the like which have one addition polymerizable unsaturated bond which is selected from, for example, acrylic acid esters, methacrylic acid esters, acrylamides, methacrylamides, allyl compounds, vinylethers, vinylesters, and the like.

Apart from the above, copolymerizing may be carried out with an addition polymerizable unsaturated compound which is able to be copolymerized with monomers which are equivalent to the various types of repeating structure units described above.

In the resin (A) which is used for the composition of the present invention, the content molar ratio of each repeating structure unit is appropriately set in order to adjust the dry etching resistance or standard developing solution aptitude, the substrate adhesiveness, and the resist profile of active light sensitive or radiation sensitive resin compositions, and moreover, the resolving power, heat resistance, sensitivity, and the like which are typical necessary characteristics for active light sensitive or radiation sensitive resin compositions.

When the composition of the present invention is used for ArF exposure, the resin (A) which is used for the composition of the present invention preferably substantially does not have an aromatic ring from the point of view of transparency to ArF light (in detail, the ratio of the repeating units which have an aromatic group in the resin is preferably 5 mol % or less, more preferably 3 mol % or less, and ideally 0 mol %, that is, the resin (A) does not have an aromatic group) and the resin (A) preferably has a monocyclic or polycyclic alicyclic hydrocarbon structure.

The form of the resin (A) in the present invention may be any of a random type, a block type, a comb type, and a star type. It is possible to synthesize the resin (A), for example, by radical, cation, or anion polymerization of unsaturated monomers which correspond to each structure. In addition, it is also possible to obtain a target resin by performing a polymer reaction after carrying out polymerizing using unsaturated monomers which are equivalent to the precursor bodies of each structure.

When the composition of the present invention is used for ArF exposure, the resin (A) which is used for the composition of the present invention preferably substantially does not have an aromatic ring from the point of view of transparency to ArF light (in detail, the ratio of the repeating units which have an aromatic group in the resin is preferably 5 mol % or less, more preferably 3 mol % or less, and ideally 0 mol %, that is, the resin (A) does not have an aromatic group) and the resin (A) preferably has a monocyclic or polycyclic alicyclic hydrocarbon structure.

In a case where the composition of the present invention includes a resin (D) which will be described below, the resin (A) preferably does not contain a fluorine atom or a silicon atom from the point of view of mutual solubility with the resin (D).

The resin (A) which is used for the composition of the present invention is preferably a resin where all of the repeating units are configured by (meth)acrylate-based repeating units. In this case, it is possible to use any of a resin where all of the repeating units are methacrylate-based repeating units, a resin where all of the repeating units are acrylate-based repeating units, and a resin where all of the repeating units are formed by methacrylate-based repeating units and acrylate-based repeating units; however, the acrylate-based repeating units are preferably 50 mol % or less of all of the repeating units.

In a case of irradiating the composition of the present invention with KrF excimer laser light, electron beams, X-rays, or high energy rays with a wavelength of 50 nm or less (EUV and the like), the resin (A) preferably also has hydroxystyrene-based repeating units. It is more preferable to have a hydroxystyrene-based repeating unit and an acid-decomposable repeating unit such as a hydroxystyrene-based repeating unit which is protected by an acid-decomposable group, or a (meth)acrylic acid tertiary alkylester.

Examples of the repeating unit which has a preferable hydroxystyrene-based acid-decomposable group include repeating units or the like using t-butoxycarbonyloxystyrene, 1-alkoxyethoxystyrene, and (meth)acrylic acid tertiary alkylester, and repeating units using 2-alkyl-2-adamantyl(meth)acrylate and dialkyl (1-adamantyl)methyl(meth)acrylate are more preferable.

It is possible to synthesize the resin (A) in the present invention by normal methods (for example, radical polymerization). Examples of typical synthesizing methods include a collective polymerization method in which polymerization is performed by dissolving a monomer type and an initiator in a solvent and heating, a dripping polymerization method in which a solution of a monomer type and an initiator is dripped and added to a heating solvent over 1 to 10 hours, and the like, and the dripping polymerization method is preferable. Examples of reaction solvents include ethers such as tetrahydrofuran, 1,4-dioxane, and diisopropylether, ketones such as methylethyl ketone and methylisobutyl ketone, ester solvents such as ethyl acetate, and amide solvents such as dimethylformamide and dimethylacetamide, and moreover, solvents which dissolve the composition of the present invention which will be described below such as propylene glycol monomethyl ether acetate, propylene glycol monomethyl ether, and cyclohexanone. It is more preferable to carry out the polymerization using the same solvent as the solvent which is used for the photosensitive composition of the present invention. Due to this, it is possible to suppress the generation of particles during the storage.

The polymerization reaction is preferably performed in an inert gas atmosphere such as nitrogen or argon. Polymerization is initiated using a commercially available radical initiator (an azo-based initiator, peroxide, or the like) as the polymerization initiator. The radical initiator is preferably an azo-based initiator and preferably an azo-based initiator which has an ester group, a cyano group, and a carboxyl group. Examples of preferable initiators include azobisisobutyronitrile, azobisdimethylvaleronitrile, dimethyl 2,2′-azobis(2-methylpropionate), and the like. As desired, an initiator is added or divided and added and, after the reaction ends, a desired polymer is recovered by a method such as powder or solid collection by placing the resultant in a solvent. The concentration of the reaction solution is 5 mass % to 50 mass % and preferably 10 mass % to 30 mass %. The reaction temperature is generally 10° C. to 150° C., preferably 30° C. to 120° C., and more preferably 60° C. to 100° C.

After the reaction ends, the resultant is cooled to room temperature and purified. With regard to the purification, it is possible to apply general methods such as a liquid extraction method which removes residual monomers or oligomer components by washing with water or combining appropriate solvents, a solution state purifying method such as ultrafiltration which only extracts and removes substances with a specific molecular weight or less, a re-precipitation method which removes residual monomers or the like by solidifying the resin in a weak solvent by dripping a resin solution into the weak solvent, or a solid-state purifying method such as cleaning filtered and separated a resin slurry using a weak solvent.

For example, the resin is educted as solid matter by the resin described above being brought in contact with a sparingly soluble or insoluble solvent (a weak solvent) with a volume amount of 10 times or less that of the reaction solution, preferably a volume amount of 10 to 5 times.

It is sufficient if the solvent (the precipitation or re-precipitation solvent) which is used during a precipitation or re-precipitation operation from a polymer solution is a weak solvent for the polymer and it is possible to use a solvent appropriately selected from hydrocarbons, halogenated hydrocarbons, nitro compounds, ethers, ketones, esters, carbonates, alcohols, carboxylic acids, water, mixed solvents which include these solvents, and the like according to the type of the polymer. Among these, a solvent which includes at least alcohol (particularly methanol and the like) or water is preferable as the precipitation or re-precipitation solvent.

It is possible to appropriately select the usage amount of the precipitation or re-precipitation solvent in consideration of the efficiency, yield, and the like; however, the usage amount is generally 100 parts by mass to 10000 parts by mass with respect to 100 parts by mass of the polymer solution, preferably 200 parts by mass to 2000 parts by mass, and even more preferably 300 parts by mass to 1000 parts by mass.

It is possible to appropriately select the temperature during precipitation or re-precipitation in consideration of the efficiency or operability; however, the temperature is generally approximately 0° C. to 50° C. and preferably approximately room temperature (for example, approximately 20° C. to 35° C.). It is possible to perform the precipitation or re-precipitation operation using methods known in the art such as a batch type operation or a continuous type operation using a common mixture container such as a stirring tank.

Generally, the precipitated or re-precipitated polymer is provided for use by being filtered, subjected to common solid-liquid separation such as centrifugal separation, and dried. Filtration is preferably performed under pressure using a filter material with solvent resistance. Drying is performed under normal pressure or reduced pressure (preferably under reduced pressure), at the temperature of approximately 30° C. to 100° C., and preferably 30° C. to 50° C.

Here, after educting and separating the resin once, the resin may be brought into contact with a sparingly soluble or insoluble solvent by dissolving in a solvent again. That is, the method may be a method which includes bringing the polymer into contact with a sparingly soluble or insoluble solvent after the radical polymerization reaction ends and educting a resin (step a), separating the resin from the solution (step b), dissolving the resin in a solvent again and preparing a resin solution A (step c), and then educting resin solid matter in the resin solution A by bringing the resin into contact with a sparingly soluble or insoluble solvent with a volume amount of less than 10 times that of the resin solution A (preferably a volume amount of 5 times or less) (step d), and separating the educted resin (step e).

In addition, in order to suppress the resin from aggregating after the preparation of the composition, for example, as described in JP2009-037108A, a step may be added in which the synthesized resins are dissolved in a solvent to make a solution and the solution is heated at approximately 30° C. to 90° C. for approximately 30 minutes to 4 hours.

As a polystyrene converted value using a GPC method, the weight average molecular weight of the resin (A) in the present invention is 7,000 or more as described above, preferably 7,000 to 200,000, more preferably 7,000 to 50,000, even more preferably 7,000 to 40,000, and particularly preferably 7,000 to 30,000. When the weight average molecular weight is smaller than 7000, the solubility with respect to an organic-based developer is excessively high and there is a concern that it will not be possible to form a precise pattern.

The resin of which the dispersity (molecular weight distribution) is normally in the range of 1.0 to 3.0, preferably 1.0 to 2.6, more preferably 1.0 to 2.0, and particularly preferably 1.4 to 2.0 is used. As the molecular weight distribution is smaller, the resolution and the resist shape are superior and the side wall of a resist pattern is smoother and has superior roughness.

In the active light sensitive or radiation sensitive resin composition of the present invention, the mixing ratio of the resin (A) in the entire composition is preferably 30 mass % to 99 mass % of the entirety of the solid content and more preferably 60 mass % to 95 mass %.

In addition, in the present invention, the resin (A) may be used as one type or a plurality thereof may be used together. In addition, the resin (A) and a resin which is not the resin (A) and of which, due to a polarity thereof being increased by the action of an acid, a solubility decreases with respect to a developer which includes an organic solvent may be used together.

Examples of the resin (A) which is preferably used in the present invention include the resins P-1 to P-7 in Examples 1 to 14 which will be described below; however, other examples thereof include the resins as follows. A favorable performance is expected to be exhibited even when these resins are used instead of the resins P-1 to P-7 which are used in Examples 1 to 14 which will be described below.

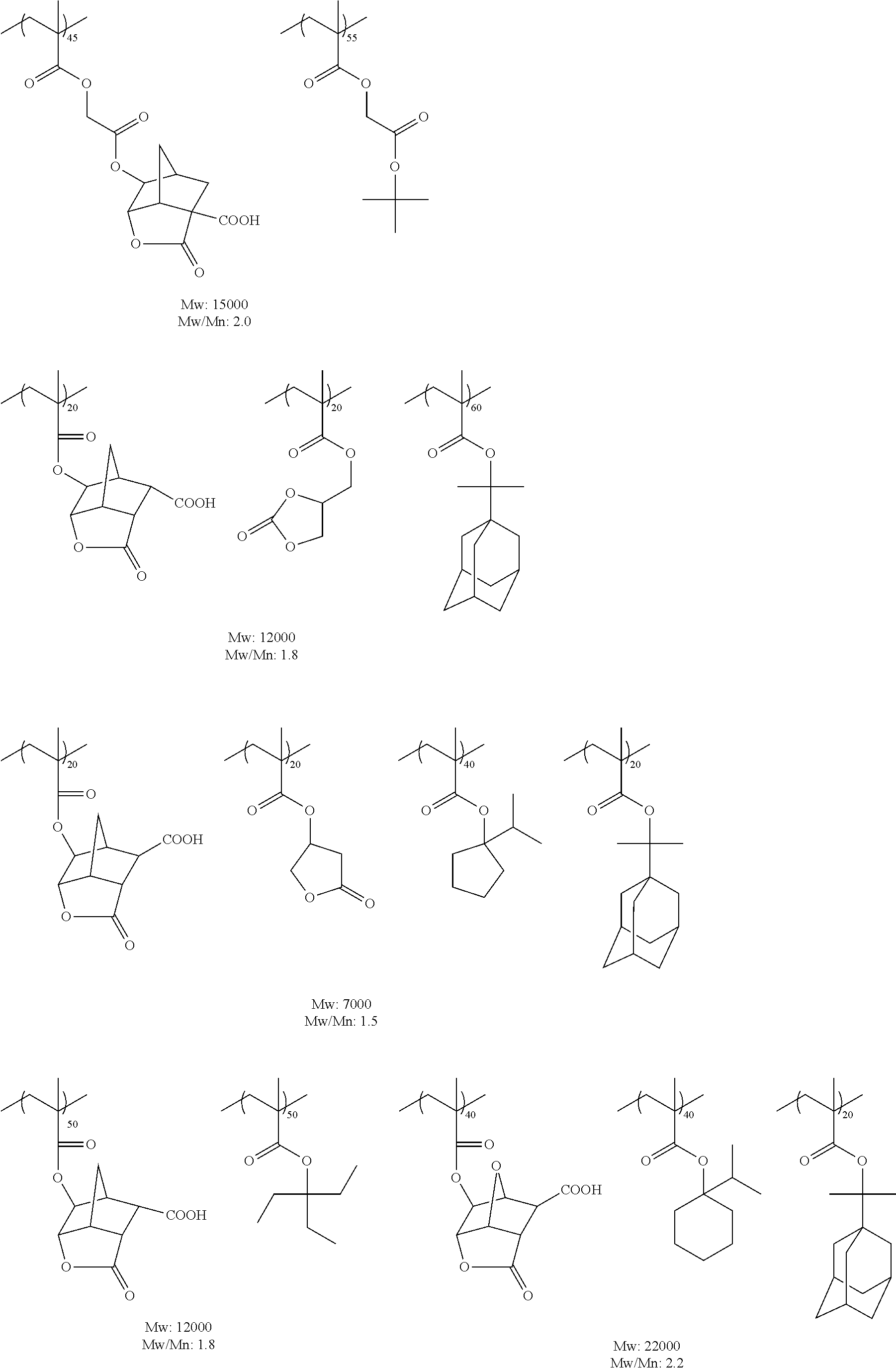

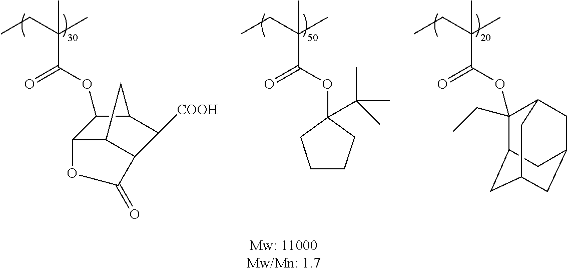

<Compound which Generates an Acid when Irradiated with Active Rays or Radiation>

The composition of the present invention preferably contains a compound which generates an acid when irradiated with active rays or radiation (also referred to below as “compound (B)” or an “acid generating agent”).

In an aspect of the present invention, examples of an acid generating agent include the compounds which are represented by General Formulas (ZI), (ZII), or (ZIII) below.

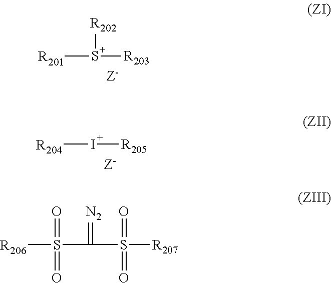

In General Formula (ZI) described above,

R₂₀₁, R₂₀₂, and R₂₀₃ each independently represents an organic group.

The number of carbon atoms of an organic group as R₂₀₁, R₂₀₂, and R₂₀₃ is generally 1 to 30 and preferably 1 to 20.

In addition, two out of R₂₀₁ to R₂₀₃ may form a ring structure by bonding with each other and may include an oxygen atom, a sulfur atom, an ester bond, an amide bond, and a carbonyl group in the ring. Examples of a group formed by two out of R₂₀₁ to R₂₀₃ bonding with each other include an alkylene group (for example, a butylene group and a pentylene group).

Here, the compound may have a plurality of structures which are represented by General Formula (ZI). For example, the compound may have a structure in which at least one of R₂₀₁ to R₂₀₃ of a compound which is represented by General Formula (ZI) is bonded to at least one of R₂₀₁ to R₂₀₃ of another compound which is represented by General Formula (ZI) via a single bond or a linking group.

Z⁻ represents a non-nucleophilic anion (an anion which has a remarkably low ability to cause a nucleophilic reaction).

Examples of Z⁻ include sulfonic acid anions (aliphatic sulfonic acid anions, aromatic sulfonic acid anions, camphor sulfonic acid anions, and the like), carboxylate anions (aliphatic carboxylate anions, aromatic carboxylate anions, aralkyl carboxylate anions, and the like), sulfonylimide anions, bis(alkylsulfonyl)imide anions, tris(alkylsulfonyl) methide anions, and the like.

An aliphatic site in an aliphatic sulfonic acid anion and an aliphatic carboxylate anion may be an alkyl group or a cycloalkyl group and preferable examples thereof include a straight-chain or branched alkyl group with 1 to 30 carbon atoms or a cycloalkyl group with 3 to 30 carbon atoms.

An aromatic group in an aromatic sulfonic acid anion and an aromatic carboxylate anion is preferably an aryl group with 6 to 14 carbon atoms and examples thereof include a phenyl group, a tolyl group, a naphthyl group, and the like.

The alkyl group, the cycloalkyl group, and the aryl group described above may have a substituent group. Specific examples thereof include a nitro group, a halogen atom such as a fluorine atom, a carboxyl group, a hydroxy group, an amino group, a cyano group, an alkoxy group (preferably with 1 to 15 carbon atoms), a cycloalkyl group (preferably with 3 to 15 carbon atoms), an aryl group (preferably with 6 to 14 carbon atoms), an alkoxycarbonyl group (preferably with 2 to 7 carbon atoms), an acyl group (preferably with 2 to 12 carbon atoms), an alkoxycarbonyloxy group (preferably with 2 to 7 carbon atoms), an alkylthio group (preferably with 1 to 15 carbon atoms), an alkylsulfonyl group (preferably with 1 to 15 carbon atoms), an alkyliminosulfonyl group (preferably with 2 to 15 carbon atoms), an aryloxysulfonyl group (preferably with 6 to 20 carbon atoms), an alkylaryloxysulfonyl group (preferably with 7 to 20 carbon atoms), a cycloalkylaryloxysulfonyl group (preferably with 10 to 20 carbon atoms), an alkyloxyalkyloxy group (preferably with 5 to 20 carbon atoms), a cycloalkylalkyloxyalkyloxy group (preferably with 8 to 20 carbon atoms), and the like. With regard to an aryl group and a ring structure of each group, an aralkyl group in an aralkyl carboxylate anion which may further have an alkyl group (preferably with 1 to 15 carbon atoms) as a substituent group is preferably an aralkyl group with 7 to 12 carbon atoms and examples thereof include a benzyl group, a phenethyl group, a naphthylmethyl group, a naphthylethyl group, a naphthylbutyl group, and the like.

Examples of sulfonylimide anions include saccharin anions.

An alkyl group in a bis(alkylsulfonyl)imide anion and a tris(alkylsulfonyl) methide anion is preferably an alkyl group with 1 to 5 carbon atoms. Examples of a substituent group of the alkyl groups include a halogen atom, an alkyl group which is substituted with a halogen atom, an alkoxy group, an alkylthio group, an alkyloxysulfonyl group, an aryloxysulfonyl group, a cycloalkylaryloxysulfonyl group, and the like, and a fluorine atom or an alkyl group which is substituted with a fluorine atom is preferable.

Examples of other Z⁻ include fluorinated phosphorus (for example, PF₆⁻), fluorinated boron (for example, BF₄⁻), fluorinated antimony (for example, SbF₆⁻), and the like.

Z⁻ is preferably an aliphatic sulfonic acid anion in which at least the α-position of the sulfonic acid is substituted with a fluorine atom, an aromatic sulfonic acid anion which is substituted with a fluorine atom or a group which has a fluorine atom, a bis(alkylsulfonyl)imide anion in which an alkyl group is substituted with a fluorine atom, a tris(alkylsulfonyl)methide anion in which an alkyl group is substituted with a fluorine atom.

In an aspect of the present invention, the number of fluorine atoms which are included in an anion as Z⁻ is preferably 2 or 3. Due to this, it is possible to increase the effect of the present invention.

From the point of view of the acid strength, the pKa of the generated acid is preferably −1 or less in order to improve the sensitivity.

Examples of the organic group of R₂₀₁, R₂₀₂, and R₂₀₃ include an aryl group (preferably with 6 to 15 carbon atoms), a straight-chain or branched alkyl group (preferably with 1 to 10 carbon atoms), a cycloalkyl group (preferably 3 to 15 carbon atoms), and the like.

Preferably, at least one out of R₂₀₁, R₂₀₂, and R₂₀₃ is an aryl group and, more preferably, all three are aryl groups. As the aryl group, in addition to a phenyl group, a naphthyl group, and the like, heteroaryl groups such as an indole residue and a pyrrole residue are also possible.

The aryl group, the alkyl group, and the cycloalkyl group as R₂₀₁, R₂₀₂, and R₂₀₃ may further have a substituent group. Examples of the substituent group include a nitro group, a halogen atom such as a fluorine atom, a carboxyl group, a hydroxy group, an amino group, a cyano group, an alkoxy group (preferably with 1 to 15 carbon atoms), a cycloalkyl group (preferably with 3 to 15 carbon atoms), an aryl group (preferably with 6 to 14 carbon atoms), an alkoxycarbonyl group (preferably with 2 to 7 carbon atoms), an acyl group (preferably with 2 to 12 carbon atoms), an alkoxycarbonyloxy group (preferably with 2 to 7 carbon atoms), and the like; however, the present invention is not limited thereto.

In addition, two selected from R₂₀₁, R₂₀₂, and R₂₀₃ may be bonded to each other via a single bond or a linking group. Examples of the linking group include an alkylene group (preferably with 1 to 3 carbon atoms), —O—, —S—, —CO—, —SO₂—, and the like; however, the present invention is not limited thereto.

Examples of a preferable structure in a case where at least one out of R₂₀₁, R₂₀₂, and R₂₀₃ is not an aryl group include cation structures such as the compounds exemplified as Formulas (I-1) to (I-70) in paragraphs “0046” and “0047” in JP2004-233661A, paragraphs “0040” to “0046” in JP2003-35948A, and US2003/0224288A1, the compounds exemplified as Formulas (IA-1) to (IA-54) and Formulas (IB-1) to (IB-24) in US2003/0077540A1, and the like.

More preferable examples of the compound which is represented by General Formula (ZI) include compounds which are represented by General Formula (ZI-3) or (ZI-4) which will be described below. Firstly, description will be given of the compound which is represented by General Formula (ZI-3).

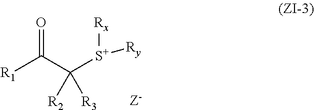

In General Formula (ZI-3) above,

R₁ represents an alkyl group, a cycloalkyl group, an alkoxy group, a cycloalkoxy group, an aryl group, or an alkenyl group,

R₂ and R₃ each independently represents a hydrogen atom, an alkyl group, a cycloalkyl group, or an aryl group, R₂ and R₃ may form a ring by bonding with each other,

R₁ and R₂ may form a ring by bonding with each other,

R_{X} and R_{Y} each independently represents an alkyl group, a cycloalkyl group, an alkenyl group, an aryl group, a 2-oxoalkyl group, a 2-oxocycloalkyl group, an alkoxycarbonylalkyl group, and an alkoxycarbonylcycloalkyl group, R_{X} and R_{Y} may form a ring by bonding with each other, and the ring structure thereof may include an oxygen atom, a nitrogen atom, a sulfur atom, a ketone group, an ether bond, an ester bond, and an amide bond.

Z⁻ represents a non-nucleophilic anion.

An alkyl group as R₁ is preferably a straight-chain or branched alkyl group with 1 to 20 carbon atoms and may have an oxygen atom, a sulfur atom, and a nitrogen atom in the alkyl chain. Specific examples thereof include straight-chain alkyl groups such as a methyl group, an ethyl group, an n-propyl group, an n-butyl group, an n-pentyl group, an n-hexyl group, an n-octyl group, an n-dodecyl group, an n-tetradecyl group, and an n-octadecyl group, and branched alkyl groups such as an isopropyl group, an isobutyl group, a t-butyl group, a neopentyl group, and a 2-ethylhexyl group. The alkyl group of R₁ may have a substituent group and examples of the alkyl group which has a substituent group include a cyanomethyl group, a 2,2,2-trifluoroethyl group, a methoxycarbonyl methyl group, and an ethoxycarbonyl methyl group.

A cycloalkyl group as R₁ is preferably a cycloalkyl group with 3 to 20 carbon atoms and may have an oxygen atom or a sulfur atom in a ring. Specific examples thereof include a cyclopropyl group, a cyclopentyl group, a cyclohexyl group, a norbornyl group, an adamantyl group, and the like. A cycloalkyl group as R₁ may have a substituent group and examples of the substituent group include an alkyl group and an alkoxy group.

An alkoxy group as R₁ is preferably an alkoxy group with 1 to 20 carbon atoms. Specific examples thereof include a methoxy group, an ethoxy group, an isopropyloxy group, a t-butyloxy group, a t-amyloxy group, and an n-butyloxy group. The alkoxy group of R₁ may have a substituent group and examples of the substituent group include an alkyl group and a cycloalkyl group.

A cycloalkoxy group as R₁ is preferably a cycloalkoxy group with 3 to 20 carbon atoms and examples thereof include a cyclohexyloxy group, a norbornyloxy group, an adamantyloxy group, and the like. The cycloalkoxy group of R₁ may have a substituent group and examples of the substituent group include an alkyl group and a cycloalkyl group.

An aryl group as R₁ is preferably an aryl group with 6 to 14 carbon atoms and examples thereof include a phenyl group, a naphthyl group, a biphenyl group, and the like. The aryl group of R₁ may have a substituent group and examples of a preferable substituent group include an alkyl group, a cycloalkyl group, an alkoxy group, a cycloalkoxy group, an aryloxy group, an alkylthio group, and an arylthio group. In a case where a substituent group is an alkyl group, a cycloalkyl group, an alkoxy group, or a cycloalkoxy group, examples thereof include the same examples as the alkyl group, the cycloalkyl group, the alkoxy group, and the cycloalkoxy group as R₁ described above.

Examples of an alkenyl group as R₁ include a vinyl group and an allyl group.

R₂ and R₃ represent a hydrogen atom, an alkyl group, a cycloalkyl group, or an aryl group and R₂ and R₃ may form a ring by linking with each other. However, at least one out of R₂ and R₃ represents an alkyl group, a cycloalkyl group, or an aryl group. Specific examples and preferable examples of the alkyl group, the cycloalkyl group, and the aryl group with regard to R₂ and R₃ include the same examples as the specific examples and preferable examples described above with regard to R₁. In a case where R₂ and R₃ form a ring by linking with each other, the total number of carbon atoms which contribute to the forming of a ring which is included in R₂ and R₃ is preferably 4 to 7 and particularly preferably 4 or 5.

R₁ and R₂ may form a ring by linking with each other. In a case where R₁ and R₂ form a ring by linking with each other, R₁ is preferably an aryl group (preferably a phenyl group or a naphthyl group which may have a substituent group) and R₂ is preferably an alkylene group with 1 to 4 carbon atoms (preferably a methylene group or an ethylene group) and examples of preferable substituent groups include the same examples as the substituent groups which the aryl group as R₁ described above may have. As another preferable form in a case where R₁ and R₂ form a ring by linking with each other, R₁ is a vinyl group and R₂ is an alkylene group with 1 to 4 carbon atoms.

An alkyl group which is represented by R_{X} and R_{y} is preferably an alkyl group with 1 to 15 carbon atoms and examples thereof include a methyl group, an ethyl group, a propyl group, an isopropyl group, an n-butyl group, an isobutyl group, a sec-butyl group, a pentyl group, a neopentyl group, a hexyl group, a heptyl group, an octyl group, a nonyl group, a decyl group, an undecyl group, a dodecyl group, a tridecyl group, a tetradecyl group, a pentadecyl group, a hexadecyl group, a heptadecyl group, an octadecyl group, a nonadecyl group, an eicosyl group, and the like.

A cycloalkyl group which is represented by R_{X} and R_{y} is preferably a cycloalkyl group with 3 to 20 carbon atoms and examples thereof include a cyclopropyl group, a cyclopentyl group, a cyclohexyl group, a norbornyl group, an adamantyl group, and the like.

An alkenyl group which is represented by R_{X} and R_{y} is preferably an alkenyl group with 2 to 30 carbon atoms and examples thereof include a vinyl group, an allyl group, and a styryl group.

An aryl group which is represented by R_{X} and R_{y} is, for example, preferably an aryl group with 6 to 20 carbon atoms and specific examples thereof include a phenyl group, a naphthyl group, an azulenyl group, an acenaphthylenyl group, a phenanthrenyl group, a phenalenyl group, a phenanthracenyl group, a fluorenyl group, an anthracenyl group, a pyrenyl group, a benzopyrenyl group, and the like. A phenyl group and a naphthyl group are preferable and a phenyl group is more preferable.

Examples of an alkyl group portion of a 2-oxoalkyl group and an alkoxycarbonylalkyl group which are represented by R_{X} and R_{y} include the examples given above as R_{X} and R_{y}.

Examples of a cycloalkyl group portion of a 2-oxocycloalkyl group and an alkoxycarbonylcycloalkyl group which are represented by R_{X} and R_{y} include the examples given above as R_{X} and R_{y}.

Examples of Z⁻ include the examples given as Z⁻ in General Formula (ZI) described above.

The compound which is represented by General Formula (ZI-3) is preferably a compound which is represented by General Formulas (ZI-3a) and (ZI-3b).

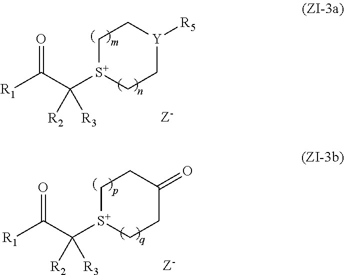

In General Formulas (ZI-3a) and (ZI-3b), R₁, R₂, and R₃ are as defined in General Formula (ZI-3) described above.

Y represents an oxygen atom, a sulfur atom, or a nitrogen atom and is preferably an oxygen atom or a nitrogen atom. m, n, p, and q signify integers, and are preferably 0 to 3, more preferably 1 or 2, and particularly preferably 1. An alkylene group which links S⁺ and Y may have a substituent group and examples of a preferable substituent group include an alkyl group.

R₅ represents a monovalent organic group in a case where Y is a nitrogen atom and is not present in a case where Y is an oxygen atom or a sulfur atom. R₅ is preferably a group which includes an electron-withdrawing group and is particularly preferably a group which is represented by General Formulas (ZI-3a-1) to (ZI-3a-4) below.

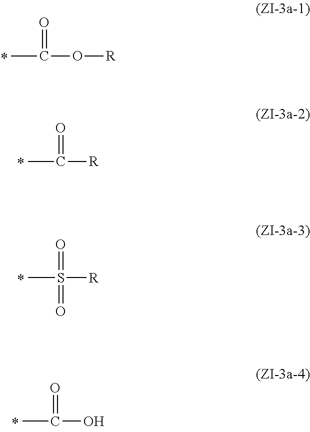

In (ZI-3a-1) to (ZI-3a-3) described above, R represents a hydrogen atom, an alkyl group, a cycloalkyl group, or an aryl group and is preferably an alkyl group. Specific examples and preferable examples of the alkyl group, the cycloalkyl group, and the aryl group with regard to R include the same examples as the specific examples and preferable examples described with regard to R₁ in General Formula (ZI-3) described above.

In (ZI-3a-1) to (ZI-3a-4) described above, * represents an atomic bond which is connected with a nitrogen atom as Y in a compound which is represented by General Formula (ZI-3a).

In a case where Y is a nitrogen atom, R₅ is particularly preferably a group which is represented by —SO₂—R₄. R₄ represents an alkyl group, a cycloalkyl group, or an aryl group and is preferably an alkyl group. Specific examples and preferable examples of the alkyl group, the cycloalkyl group, and the aryl group with regard to R₄ include the same examples as the specific examples and preferable examples described above with regard to R₁.

Examples of Z⁻ include the examples given as Z⁻ in General Formula (ZI) described above.

The compound which is represented by General Formula (ZI-3) is particularly preferably a compound which is represented by General Formulas (ZI-3a′) and (ZI-3b′) below.

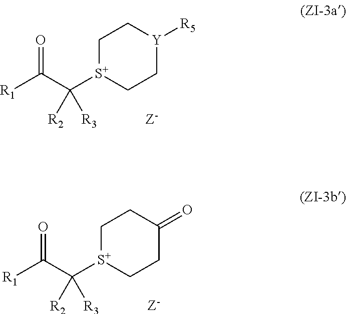

In General Formulas (ZI-3a′) and (ZI-3b′), R₁, R₂, R₃, Y, and R₅ are as defined in General Formulas (ZI-3a) and (ZI-3b).

Examples of Z⁻ include the examples given as Z⁻ in General Formula (ZI) described above.

Specific examples of cation portions of the compound which is represented by General Formula (ZI-3) will be given below.

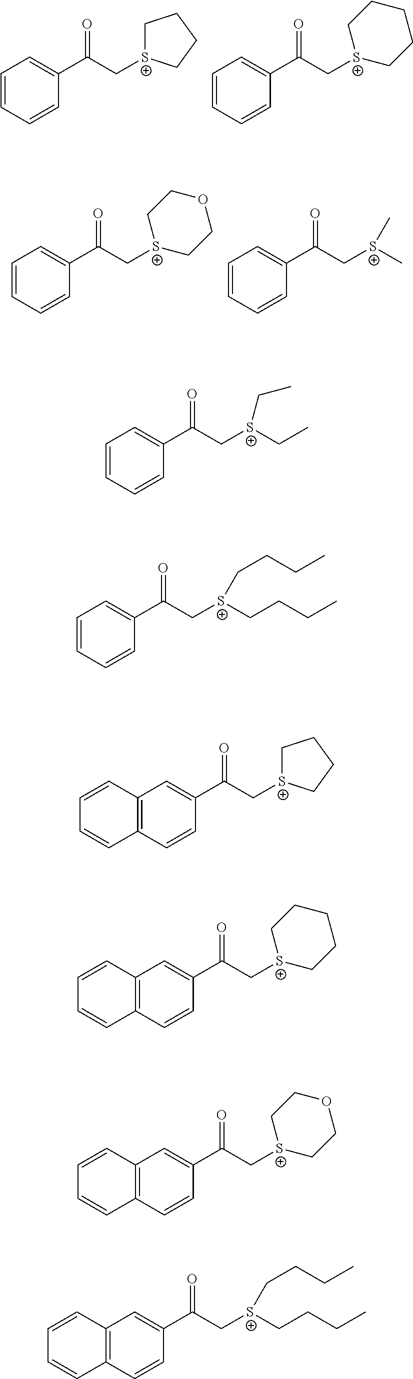

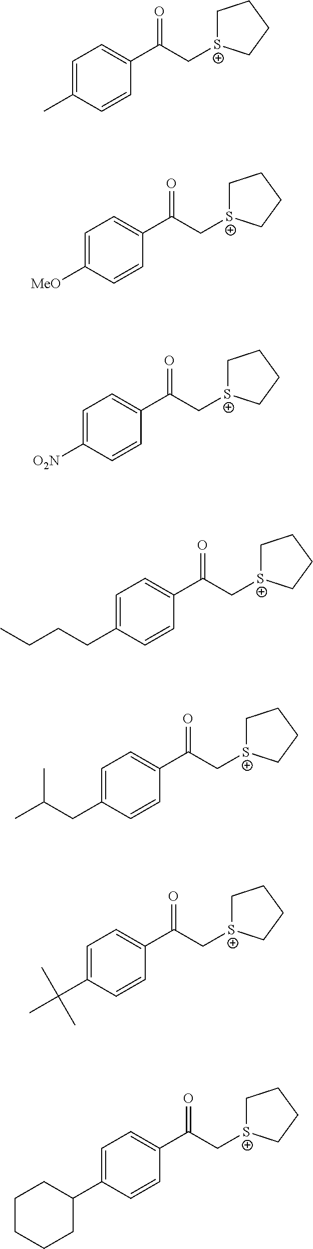

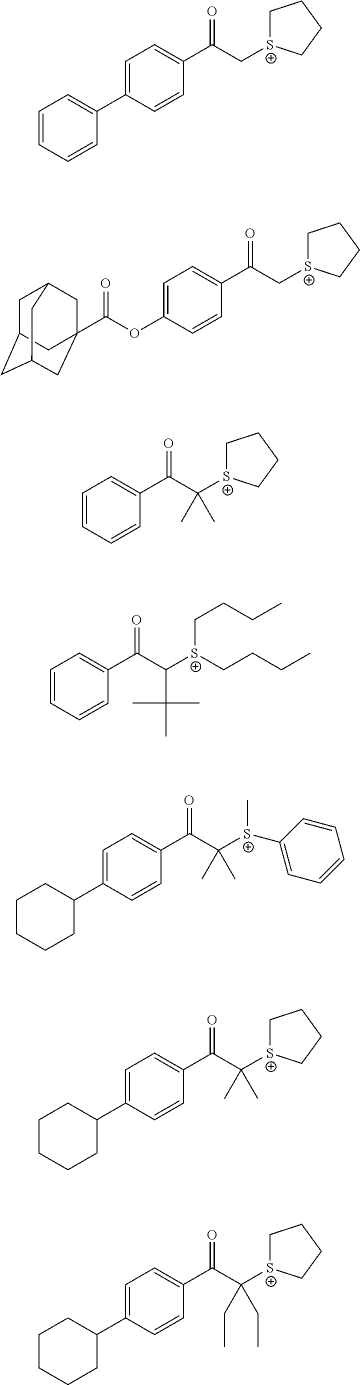

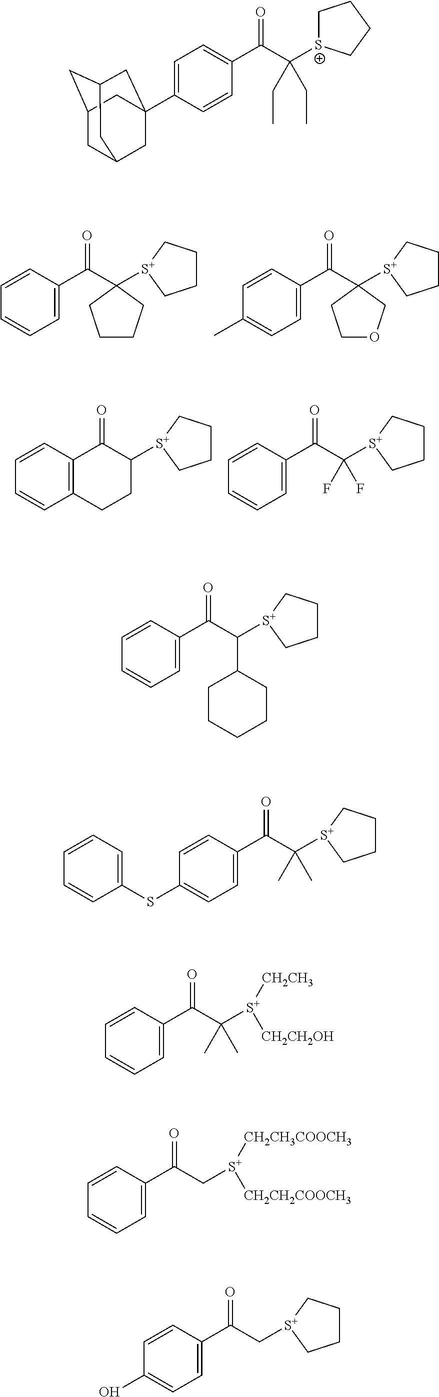

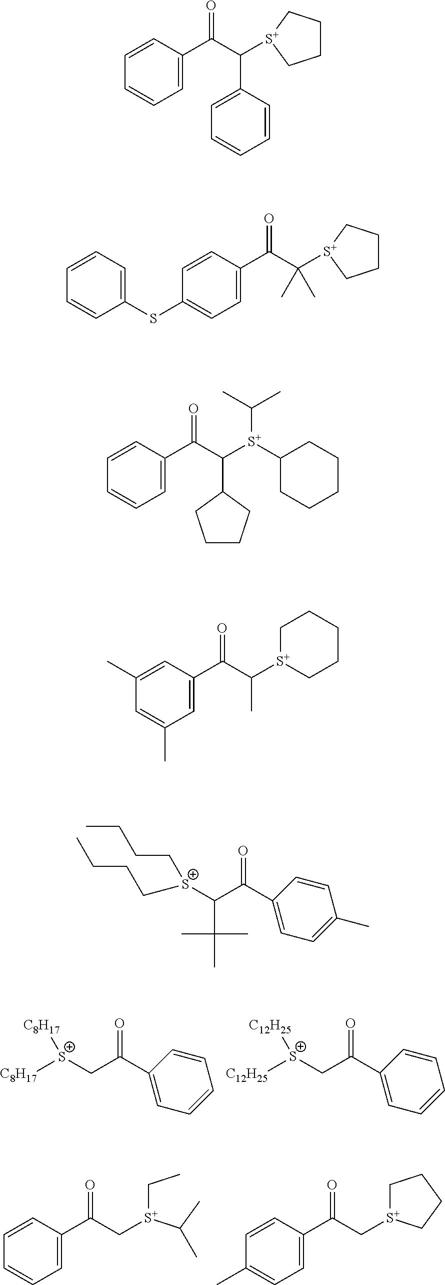

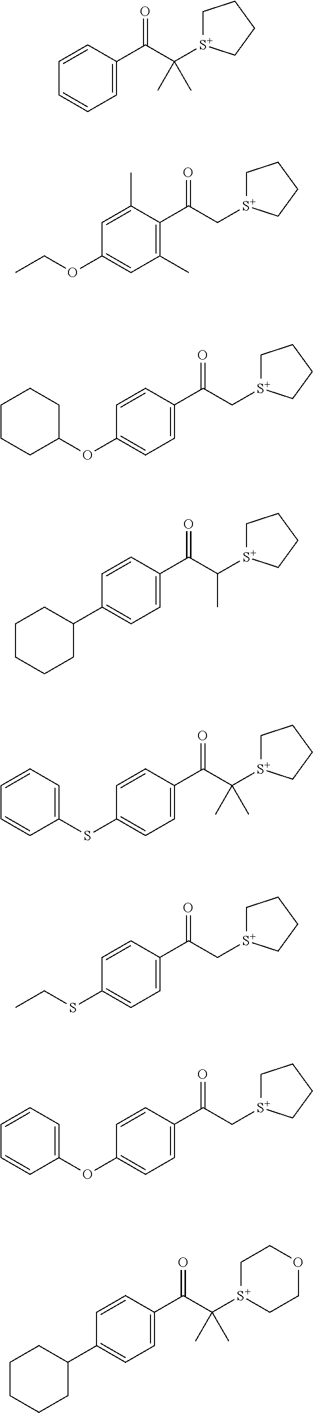

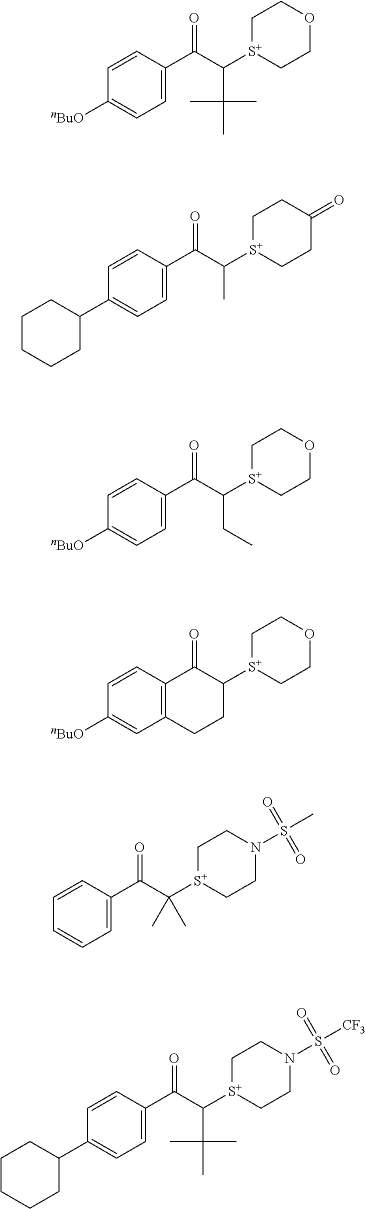

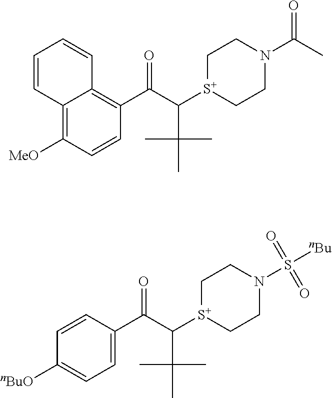

Next, description will be given of compounds which are represented by General Formula (ZI-4).

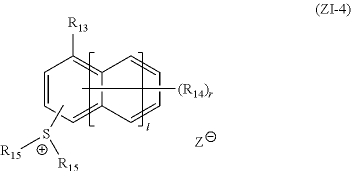

In General Formula (ZI-4),

R₁₃ represents a hydrogen atom, a fluorine atom, a hydroxy group, an alkyl group, a cycloalkyl group, an alkoxy group, an alkoxycarbonyl group, or a group which has a cycloalkyl group. These groups may have a substituent group.

In a case where a plurality of R₁₄ are present, each independently represents a hydroxy group, an alkyl group, a cycloalkyl group, an alkoxy group, an alkoxycarbonyl group, an alkylcarbonyl group, an alkylsulfonyl group, a cycloalkylsulfonyl group, or a group which has a cycloalkyl group. These groups may have a substituent group.

R₁₅ each independently represents an alkyl group, a cycloalkyl group, or a naphthyl group. Two of R₁₅ may form a ring by bonding with each other and may include a hetero atom such as an oxygen atom, a sulfur atom, and a nitrogen atom as an atom which configures a ring. These groups may have a substituent group.

l represents an integer of 0 to 2.

r represents an integer of 0 to 8.

Z⁻ represents a non-nucleophilic anion and examples thereof include the same non-nucleophilic anions as Z⁻ in General Formula (ZI).

In General Formula (ZI-4), an alkyl group of R₁₃, R₁₄, and R₁₅ is preferably a straight-chain or branched alkyl group with 1 to 10 carbon atoms.

Examples of the cycloalkyl group of R₁₃, R₁₄, and R₁₅ include a monocyclic or polycyclic cycloalkyl group.

An alkoxy group of R₁₃ and R₁₄ is preferably a straight-chain or branched alkoxy group with 1 to 10 carbon atoms.

An alkoxycarbonyl group of R₁₃ and R₁₄ is preferably a straight-chain or branched alkoxycarbonyl group with 2 to 11 carbon atoms.

Examples of a group which has a cycloalkyl group of R₁₃ and R₁₄ include a monocyclic or polycyclic group which has a cycloalkyl group. These groups may further have a substituent group.

Examples of the alkyl group of the alkylcarbonyl group of R₁₄ include the same specific examples as the alkyl groups as R₁₃ to R₁₅ described above.

An alkylsulfonyl group and a cycloalkylsulfonyl group of R₁₄ is preferably a straight-chain, branched, or cyclic group with 1 to 10 carbon atoms.

Examples of a substituent group which each of the groups described above may have include a halogen atom (for example, a fluorine atom), a hydroxy group, a carboxyl group, a cyano group, a nitro group, an alkoxy group, an alkoxyalkyl group, an alkoxycarbonyl group, an alkoxycarbonyloxy group, and the like.

Examples of a ring structure which two of R₁₅ may form by bonding with each other include a 5 membered or 6 membered ring formed by two of R₁₅ with a sulfur atom in General Formula (ZI-4), particularly preferably a 5 membered ring (that is, a tetrahydrothiophene ring or a 2,5-dihydrothiophene ring), and may be condensed with an aryl group or a cycloalkyl group. The divalent R₁₅ may have a substituent group and examples of the substituent group include a hydroxy group, a carboxyl group, a cyano group, a nitro group, an alkyl group, a cycloalkyl group, an alkoxy group, an alkoxyalkyl group, an alkoxycarbonyl group, an alkoxycarbonyloxy group, and the like. With respect to the ring structure, a plurality of substituent groups may be present and additionally, the substituent groups may form a ring by bonding with each other.

R₁₅ in General Formula (ZI-4) is preferably a methyl group, an ethyl group, a naphthyl group, a divalent group in which two of R₁₅ form a tetrahydrothiophene ring structure with a sulfur atom by bonding with each other, or the like, and particularly preferably a divalent group in which two of R₁₅ form a tetrahydrothiophene ring structure with a sulfur atom by bonding with each other.

The substituent group which R₁₃ and R₁₄ may have is preferably a hydroxy group, an alkoxy group, an alkoxycarbonyl group, or a halogen atom (particularly a fluorine atom).

l is preferably 0 or 1 and more preferably 1.

r is preferably 0 to 2.

Specific examples of a cation structure which the compounds which are represented by General Formula (ZI-3) or (ZI-4) described above include the cation structures in the chemical structures or the like exemplified in paragraphs “0046”, “0047”, “0072” to “0077”, and “0107” to “0110” in JP2011-53360A, the cation structures in the chemical structures or the like exemplified in paragraphs “0135” to “0137”, “0151”, and “0196” to “0199” in JP2011-53430A, and the like in addition to the cation structures of the compounds and the like exemplified in JP2004-233661A, JP2003-35948A, US2003/0224288A1, and US2003/0077540A1 described above.

In General Formulas (ZII) and (ZIII),

R₂₀₄ to R₂₀₇ each independently represents an aryl group, an alkyl group, or a cycloalkyl group.

The aryl group, the alkyl group, and the cycloalkyl group of R₂₀₄ to R₂₀₇ are the same as the aryl group, the alkyl group, and the cycloalkyl group of R₂₀₁ to R₂₀₃ in the compound (ZI) described above.

The aryl group, the alkyl group, and the cycloalkyl group of R₂₀₄ to R₂₀₇ may have a substituent group. Examples of the substituent group also include the substituent groups which the aryl group, the alkyl group, and the cycloalkyl group of R₂₀₁ to R₂₀₃ in the compound (ZI) described above may have.

Examples of Z⁻ include the examples given as Z⁻ in General Formula (ZI) described above.

In addition, apart from the compounds which are represented by General Formula (ZI-3) or (ZI-4), compounds which are represented by General Formula (ZI-5) below are also preferable as an acid generating agent. By using a compound which is represented by General Formula (I′) below, the transparency of the exposure light is improved and LWR and DOF are improved.

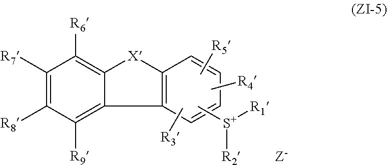

In General Formula (ZI-5) described above,

X′ represents an oxygen atom, a sulfur atom, or —N(Rx)-.

R₁′ and R₂′ each independently represents an alkyl group, a cycloalkyl group, or an aryl group.

R₃′ to R₉′ each independently represents a hydrogen atom, an alkyl group, a cycloalkyl group, an alkoxy group, an alkoxycarbonyl group, an acyl group, an alkylcarbonyloxy group, an aryl group, an aryloxy group, an aryloxycarbonyl group or an arylcarbonyloxy group.

Rx represents a hydrogen atom, an alkyl group, a cycloalkyl group, an acyl group, an alkenyl group, an alkoxycarbonyl group, an aryl group, an arylcarbonyl group, or an aryloxycarbonyl group.

R₁′ and R₂′ may form a ring by linking with each other. In addition, two or more in R₆′ to R₉′, R₃′ and R₉′, R₄′ and R₅′, R₅′ and Rx, and R₆′ and Rx may each form a ring by linking with each other.

X′ is preferably a sulfur atom or —N(Rx)- from the point of view of suppressing the light absorbance (for example, light absorbance at a wavelength of 193 nm) to be low.

Examples of Z⁻ include the examples given as Z⁻ in General Formula (ZI) described above.

The alkyl group as R₁′ to R₉′ and Rx may have a substituent group, is preferably a straight-chain or branched alkyl group with 1 to 20 carbon atoms, and may have an oxygen atom, a sulfur atom, a nitrogen atom in the alkyl chain.

Here, examples of an alkyl group which has a substituent group with regard to Rx include a cyanomethyl group, a 2,2,2-trifluoroethyl group, a methoxycarbonylmethyl group, an ethoxycarbonylmethyl group, and the like.

Examples of the alkyl group which has a substituent group with regard to R₁′ and R₂′ include a methoxyethyl group and the like.

In addition, in particular, examples thereof also include a group in which a straight-chain or branched alkyl group is substituted with a cycloalkyl group (for example, an adamantylmethyl group, an adamantylethyl group, a cyclohexylethyl group, a camphor residue, and the like) and the like.

A cycloalkyl group as R₁′ to R₉′ and Rx may have a substituent group, is preferably a cycloalkyl group with 3 to 20 carbon atoms, and may have an oxygen atom in a ring.

An acyl group as R₃′ to R₉′ and Rx may have a substituent group and is preferably an acyl group with 1 to 10 carbon atoms.

An alkenyl group as Rx is preferably an alkenyl group with 2 to 8 carbon atoms and examples thereof include a vinyl group, an allyl group, a butenyl group, and the like.

An alkoxy group as R₃′ to R₉′ may have a substituent group and is preferably an alkoxy group with 1 to 20 carbon atoms.

An alkoxycarbonyl group as R₃′ to R₉′ may have a substituent group and is preferably an alkoxycarbonyl group with 2 to 20 carbon atoms.

An alkylcarbonyloxy group as R₃′ to R₉′ may have a substituent group and is preferably an alkylcarbonyloxy group with 2 to 20 carbon atoms.

An aryl group as R₁′ to R₉′ and Rx may have a substituent group and is preferably an aryl group with 6 to 14 carbon atoms.

An aryloxy group as R₃′ to R₉′ may have a substituent group and is preferably an aryloxy group with 6 to 14 carbon atoms.

An aryloxycarbonyl group as R₃′ to R₉′ and Rx may have a substituent group and is preferably an aryloxycarbonyl group with 7 to 15 carbon atoms.

An arylcarbonyloxy group as R₃′ to R₉′ may have a substituent group and is preferably an arylcarbonyloxy group with 7 to 15 carbon atoms.

An arylcarbonyl group as Rx may have a substituent group and is preferably an arylcarbonyl group with 7 to 15 carbon atoms.

Examples of substituent groups which each of the alkyl groups as R₃′ to R₉′, the cycloalkyl groups as R₁′ to R₉′ and Rx, the acyl groups as R₃′ to R₉′ and Rx, the alkoxy groups as R₃′ to R₉′, the alkoxycarbonyl groups as R₃′ to R₉′, the alkylcarbonyloxy groups as R₃′ to R₉′, the aryl groups as R₁′ to R₉′ and Rx, the aryloxy groups as R₃′ to R₉′, the aryloxycarbonyl groups as R₃′ to R₉′ and Rx, the arylcarbonyloxy groups as R₃′ to R₉′, and the arylcarbonyl groups as Rx may further have include alkyl groups (may be any of straight-chain, branched, or cyclic alkyl groups, preferably with 1 to 12 carbon atoms), aryl groups (preferably with 6 to 14 carbon atoms), nitro groups, halogen atoms such as a fluorine atom, carboxyl groups, hydroxy groups, amino groups, cyano groups, alkoxy groups (preferably with 1 to 15 carbon atoms), cycloalkyl groups (preferably with 3 to 15 carbon atoms), acyl groups (preferably with 2 to 12 carbon atoms), and the like.

Examples of a ring structure which R₁′ and R₂′ may form by bonding with each other include a 5 membered or 6 membered ring formed by divalent R₁′ and R₂′ (for example, an ethylene group, a propylene group, a 1,2-cyclohexylene group, and the like) with a sulfur atom in General Formula (I′), particularly preferably a 5 membered ring (that is, a tetrahydrothiophene ring). However, from the point of view of the decomposition efficiency of the acid anion generation, R₁′ and R₂′ preferably do not form a ring by bonding with each other.

Examples of a ring structure which any two or more out of R₆′ to R₉′, R₃′ and R₉′, R₄′ and R₅′, R₅′ and Rx, and R₆′ and Rx may form by bonding with each other preferably include a 5 membered or 6 membered ring and particularly preferably include a 6 membered ring.

R₁′ and R₂′ are particularly preferably an alkyl group or an aryl group.

Particularly preferable examples of R₃′ to R₉′ include an alkyl group or a hydrogen atom which may have a substituent group; however, in a case of being used for an ArF resist, a hydrogen atom is particularly preferable from the point of view of the absorption strength at 193 nm.

Rx is particularly preferably an alkyl group or an acyl group.

Next, description will be given of preferable structures of the non-nucleophilic anion Z⁻.

The non-nucleophilic anion Z⁻ is preferably a sulfonic acid anion which is represented by General Formula (2).

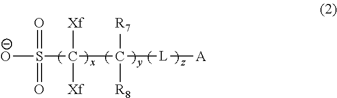

In General Formula (2),

Xf each independently represents a fluorine atom, or an alkyl group which is substituted with at least one fluorine atom.

R₇ and R₈ each independently represents a hydrogen atom, a fluorine atom, an alkyl group, or an alkyl group which is substituted with at least one fluorine atom and R₇ and R₈ may each be the same or may be different in a case where a plurality thereof are present.

L represents a divalent linking group and L may be the same or may be different in a case where a plurality thereof are present.

A represents an organic group which includes a ring structure.

x represents an integer of 1 to 20. y represents an integer of 0 to 10. z represents an integer of 0 to 10.

More detailed description will be given of anions of General Formula (2).

As described above, Xf is a fluorine atom or an alkyl group which is substituted with at least one fluorine atom and the alkyl group in the alkyl group which is substituted with a fluorine atom is preferably an alkyl group with 1 to 10 carbon atoms and more preferably an alkyl group with 1 to 4 carbon atoms. In addition, the alkyl group of Xf which is substituted with a fluorine atom is preferably a perfluoroalkyl group.

Xf is preferably a fluorine atom or a perfluoroalkyl group with 1 to 4 carbon atoms. In detail, a fluorine atom and CF₃ are preferable. In particular, both of Xf are preferably fluorine atoms.

As described above, R₇ and R₈ represent a hydrogen atom, a fluorine atom, an alkyl group, or an alkyl group which is substituted with at least one fluorine atom and the alkyl group preferably has 1 to 4 carbon atoms. A perfluoroalkyl group with 1 to 4 carbon atoms is more preferable. Specific examples of the alkyl group of R₇ and R₈ which is substituted with at least one fluorine atom include CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉, and CH₂CH₂C₄F₉ and among these, CF₃ is preferable.

L represents a divalent linking group and examples thereof include —COO—, —OCO—, —CO—, —O—, —S—, —SO—, —SO₂—, —N(Ri)- (in the formulas, Ri represents a hydrogen atom or alkyl), an alkylene group (preferably with 1 to 6 carbon atoms), a cycloalkylene group (preferably with 3 to 10 carbon atoms), an alkenylene group (preferably with 2 to 6 carbon atoms), a —COO— alkylene group, or a divalent linking group combining a plurality thereof, and the like, —COO—, —OCO—, —CO—, —SO₂—, —CON(Ri)-, —SO₂N(Ri)-, —CON(Ri)-alkylene group-, —N(Ri)CO-alkylene group-, or —OCO-alkylene group- is preferable and —COO—, —OCO—, —SO₂—, —CON(Ri)-, or —SO₂N(Ri)- is more preferable. L may be the same or may be different in a case where a plurality thereof are present.

An alkyl group as Ri is preferably a straight-chain or branched alkyl group with 1 to 20 carbon atoms and may have an oxygen atom, a sulfur atom, and a nitrogen atom in the alkyl chain. Specific examples thereof include straight-chain alkyl groups such as a methyl group, an ethyl group, an n-propyl group, an n-butyl group, an n-pentyl group, an n-hexyl group, an n-octyl group, an n-dodecyl group, an n-tetradecyl group, and an n-octadecyl group and branched alkyl groups such as an isopropyl group, an isobutyl group, a t-butyl group, a neopentyl group, and a 2-ethylhexyl group. Examples of an alkyl group which has a substituent group include a cyanomethyl group, a 2,2,2-trifluoroethyl group, a methoxycarbonylmethyl group, an ethoxycarbonylmethyl group, and the like.

An organic group which includes the ring structure of A is not particularly limited as long as the group has a ring structure and examples thereof include an alicyclic group, an aryl group, a group which has a steroid skeleton (a group which has a carbon skeleton of cyclopentahydrophenanthrene), hetero ring groups (including not only hetero ring groups which have aromaticity but also hetero ring groups which do not have aromaticity and, for example, a tetrahydropyran ring and a lactone ring structure are also included), and the like.

The alicyclic group may be monocyclic or polycyclic and is preferably a monocyclic cycloalkyl group such as a cyclopentyl group, a cyclohexyl group, or a cyclooctyl group or a polycyclic cycloalkyl group such as a norbornyl group, a norbornene-yl group, a tricyclodecanyl group (for example, a tricyclo[5.2.1.0(2,6)]decanyl group), a tetracyclododecanyl group, a tetracyclodecanyl group, or an adamantyl group. In addition, nitrogen atom-containing alicyclic groups such as a piperidine group, a decahydroquinoline group, and a decahydroisoquinoline group are also preferable. Among these, alicyclic groups which have a bulky structure with 7 or more carbon atoms such as a norbornyl group, a tricyclodecanyl group, a tetracyclodecanyl group, a tetracyclodecanyl group, an adamantyl group, a decahydroquinoline group, and a decahydroisoquinoline group are preferable from the point of view that it is possible to suppress the in-film diffusibility in a PEB step (heating after exposure) and that the exposure latitude is improved.

Examples of an aryl group include a benzene ring, a naphthalene ring, a phenanthrene ring, and an anthracene ring. Among these, naphthalene with low light absorbance is preferable from the point of view of light absorbance at 193 nm.

Examples of hetero ring groups include a furan ring, a thiophene ring, a benzofuran ring, a benzothiophene ring, a dibenzofuran ring, a dibenzothiophene ring, and a pyridine group. Among these, a furan ring, a thiophene ring, and a pyridine ring are preferable.

The cyclic organic groups described above may have a substituent group and examples of the substituent groups include alkyl groups (may be any of straight-chain, branched, and cyclic alkyl groups, preferably with 1 to 12 carbon atoms), an aryl group (preferably with 6 to 14 carbon atoms), a hydroxy group, an alkoxy group, an ester group, an amide group, a urethane group, a ureide group, a thioether group, a sulfonamide group, a sulfonic acid ester group, a cyano group, and the like.

Here, the carbon which configures the organic group which includes a ring structure (carbon which contributes to the ring forming) may be carbonyl carbon.

x is preferably 1 to 8, more preferably 1 to 4, and particularly preferably 1. y is preferably 0 to 4, more preferably 0 or 1, and even more preferably 0. z is preferably 0 to 8, more preferably 0 to 4, and even more preferably 1.

In addition, in an aspect of the present invention, the number of fluorine atoms which are included in an anion which is represented by General Formula (2) is preferably 2 or 3. Due to this, it is possible to further increase the effects of the invention.

Specific examples of a sulfonic acid anion structure which is represented by General Formula (2) will be given below; however, the present invention is not limited thereto.

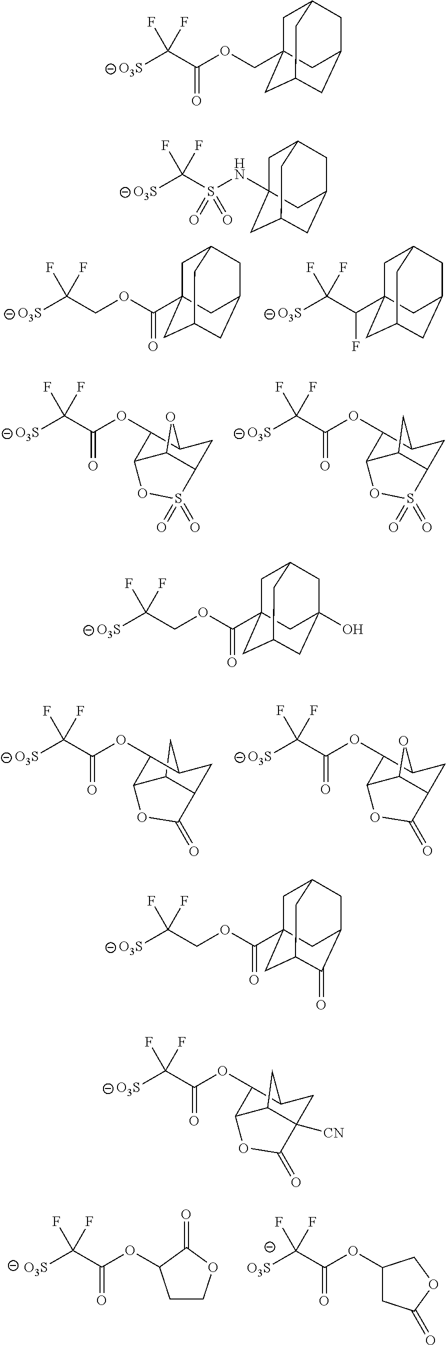

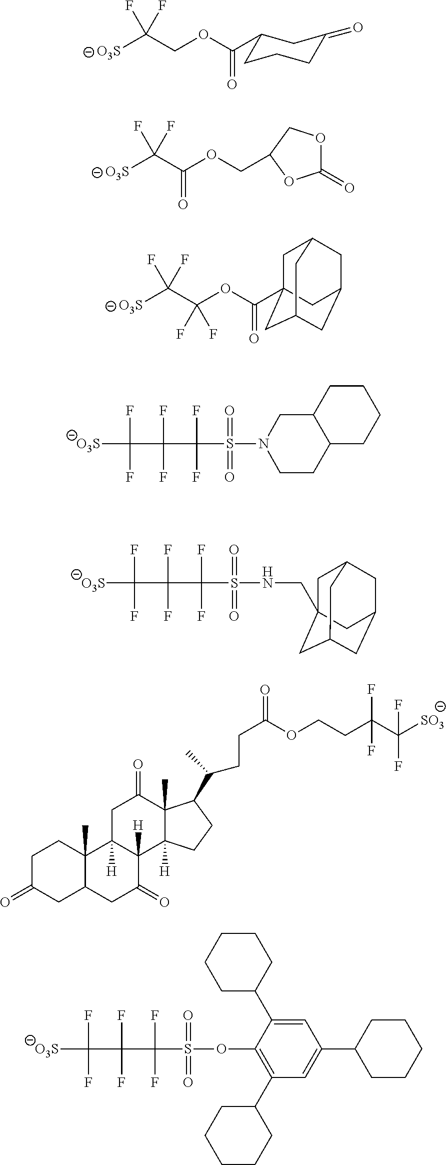

As Z⁻, a sulfonic acid anion which is represented by General Formula (B-1) below is also preferable.

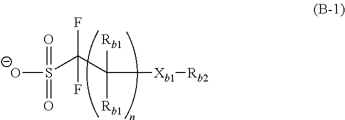

In General Formula (B-1) described above,

R_{b1} each independently represents a hydrogen atom, a fluorine atom, or a trifluoromethyl group (CF₃).

n represents an integer of 0 to 4.

n is preferably an integer of 0 to 3 and more preferably 0 or 1.

X_{b1} represents a single bond, an alkylene group, an ether bond, an ester bond (—OCO— or —COO—), a sulfonic acid ester bond (—OSO₂— or —SO₃—), or a combination thereof.

X_{b1} is preferably an ester bond (—OCO— or —COO—) or a sulfonic acid ester bond (—OSO₂— or —SO₃—) and more preferably an ester bond (—OCO— or —COO—).

R_{b2} represents an organic group with 6 or more carbon atoms.

An organic group with 6 or more carbon atoms with regard to R_{b2} is preferably a bulky group and examples thereof include an alkyl group, an alicyclic group, an aryl group, a hetero ring group with 6 or more carbon atoms, and the like.

An alkyl group with 6 or more carbon atoms with regard to R_{b2} may be a straight-chain form or a branched form, is preferably a straight-chain or branched alkyl group with 6 to 20 carbon atoms, and examples thereof include a straight-chain or branched hexyl group, a straight-chain or branched heptyl group, a straight-chain or branched octyl group, and the like. From the viewpoint of bulkiness, a branched alkyl group is preferable.

An alicyclic group with 6 or more carbon atoms with regard to R_{b2} may be monocyclic or may be polycyclic. Examples of the monocyclic alicyclic group include monocyclic cycloalkyl groups such as a cyclohexyl group and a cyclooctyl group. Examples of the polycyclic alicyclic group include polycyclic cycloalkyl groups such as a norbornyl group, a tricyclodecanyl group, a tetracyclodecanyl group, a tetracyclododecanyl group, and an adamantyl group. Among these, alicyclic groups which have a bulky structure with 7 or more carbon atoms such as a norbornyl group, a tricyclodecanyl group, a tetracyclodecanyl group, a tetracyclododecanyl group, and an adamantyl group are preferable from the point of view of suppressing the in-film diffusibility in a PEB step (heating after exposure) and of improving the Mask Error Enhancement Factor (MEEF).

The aryl group with 6 or more carbon atoms with regard to R_{b2} may be monocyclic or may be polycyclic. Examples of the aryl group include a phenyl group, a naphthyl group, a phenanthryl group, and an anthryl group. Among these, a naphthyl group with relatively low light absorbance at 193 nm is preferable.

A hetero ring group with 6 or more carbon atoms with regard to R_{b2} may be monocyclic or may be polycyclic; however, a polycyclic group is able to suppress diffusion of an acid to a greater extent. In addition, the hetero ring group may have aromaticity or may not have aromaticity. Examples of a hetero ring which has aromaticity include a benzofuran ring, a benzothiophene ring, a dibenzofuran ring, and a dibenzothiophene ring. Examples of a hetero ring which does not have aromaticity include a tetrahydropyran ring, a lactone ring, a sultone ring, and a decahydroisoquinoline ring.

The substituent groups with 6 or more carbon atoms with regard to R_{b2} described above may further have a substituent group. Examples of the further substituent groups include alkyl groups (may be either straight-chain or branched, preferably with 1 to 12 carbon atoms), cycloalkyl groups (may be any of monocyclic, polycyclic, and a spiro ring, preferably with 3 to 20 carbon atoms), aryl groups (preferably with 6 to 14 carbon atoms), hydroxy groups, alkoxy groups, ester groups, amide groups, urethane groups, ureide groups, thioether groups, sulfonamide groups, and sulfonic acid ester groups. Here, the carbon which configures the alicyclic group, the aryl group, or the hetero ring group described above (carbon which contributes to the ring forming) may be carbonyl carbon.

Specific examples of a sulfonic acid anion structure which is represented by General Formula (B-1) will be given below; however, the present invention is not limited thereto. Here, in the specific examples below, structures which are equivalent to the sulfonic acid anion which is represented by General Formula (2) described above are also included.

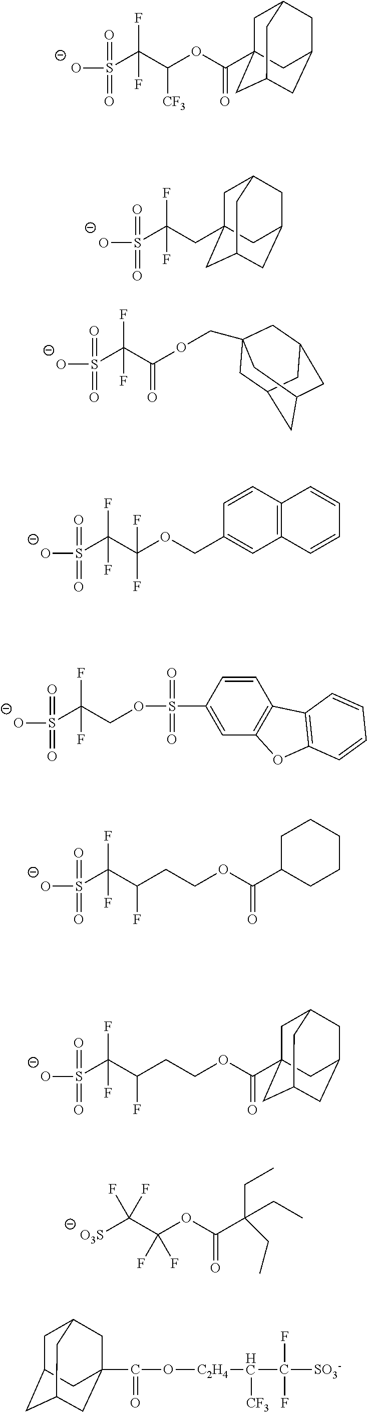

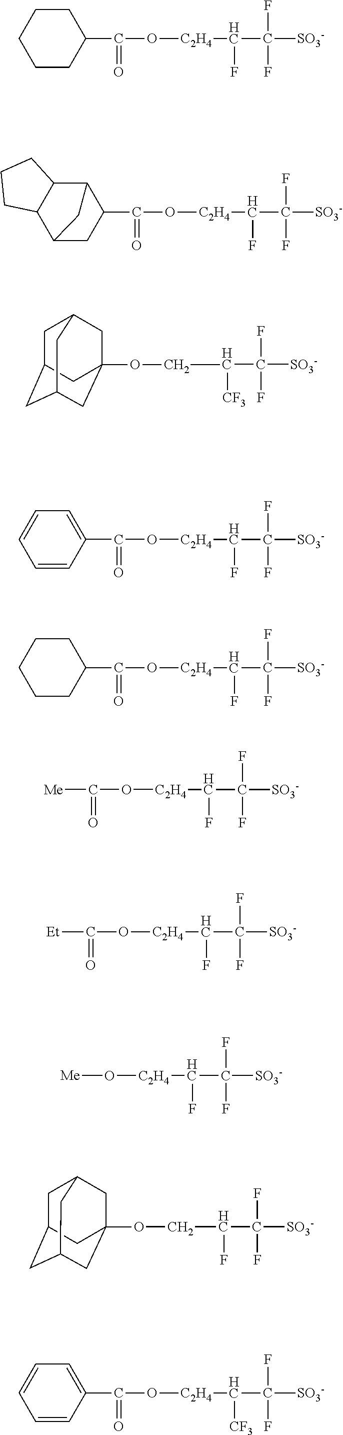

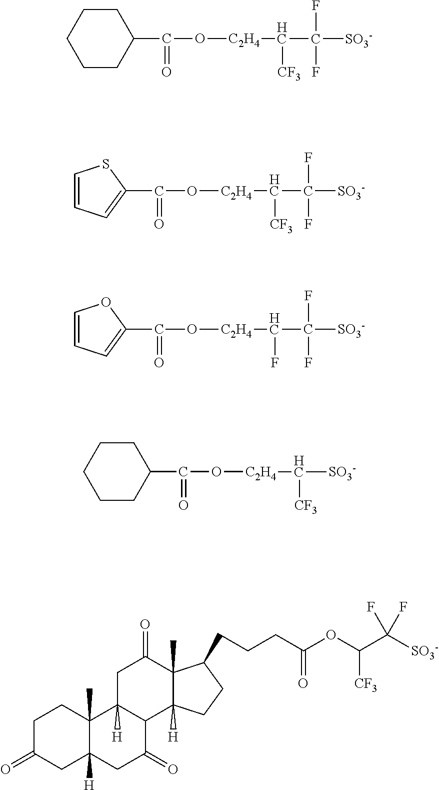

The non-nucleophilic anion Z⁻ may be a disulfonyl imidic acid anion which is represented by General Formula (2′).

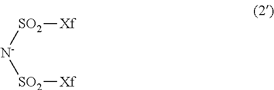

In General Formula (2′),

Xf is as defined in General Formula (2) described above and the preferable examples thereof are the same. In General Formula (2′), two of Xf may form a ring structure by linking with each other.

The disulfonyl imidic acid anion with regard to Z⁻ is preferably a bis(alkylsulfonyl)imide anion.

An alkyl group in the bis(alkylsulfonyl)imide anion is preferably an alkyl group with 1 to 5 carbon atoms.

Two alkyl groups in the bis(alkylsulfonyl)imide anion may form an alkylene group (preferably, with 2 to 4 carbon atoms) by linking with each other and form a ring with an imide group and two sulfonyl groups. The ring structures described above which the bis(alkylsulfonyl)imide anion may form are preferably a 5 to 7 membered ring and more preferably a 6 membered ring.

Examples of a substituent group which the alkyl groups and the alkylene group which two alkyl groups form by linking with each other may have include a halogen atom, an alkyl group which is substituted with a halogen atom, an alkoxy group, an alkylthio group, an alkyloxysulfonyl group, an aryloxysulfonyl group, a cycloalkylaryloxysulfonyl group, and the like, and a fluorine atom or an alkyl group which is substituted with a fluorine atom is preferable.

Examples of the acid generating agent also further include the compounds which are represented by General Formula (ZV) below.

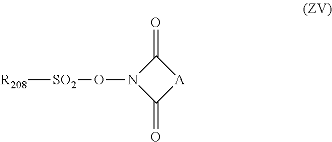

In General Formula (ZV),

R₂₀₈ represents an alkyl group, a cycloalkyl group or an aryl group.

A represents an alkylene group, an alkenylene group, or an arylene group.

Specific examples of the aryl group of R₂₀₈ include the same examples as the specific examples of the aryl group as R₂₀₁ to R₂₀₃ in General Formula (ZI) described above.

Specific examples of the alkyl group and the cycloalkyl group of R₂₀₈ respectively include the same examples as the specific examples of the alkyl group and the cycloalkyl group as R₂₀₁ to R₂₀₃ in General Formula (ZI) described above.

Examples of an alkylene group of A include an alkylene group with 1 to 12 carbon atoms (for example, a methylene group, an ethylene group, a propylene group, an isopropylene group, a butylene group, an isobutylene group, and the like), examples of an alkenylene group of A include an alkenylene group with 2 to 12 carbon atoms (for example, a vinylene group, a propenylene group, a butenylene group, and the like), and examples of an arylene group of A include an arylene group with 6 to 10 carbon atoms (for example, a phenylene group, a tolylene group, a naphthylene group, and the like).

Examples of the acid generating agent will be given below. However, the present invention is not limited thereto.

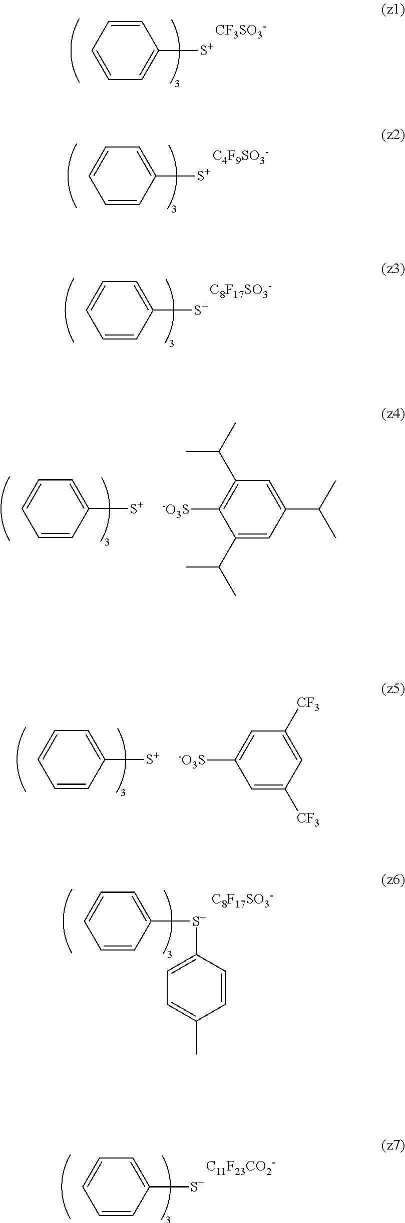

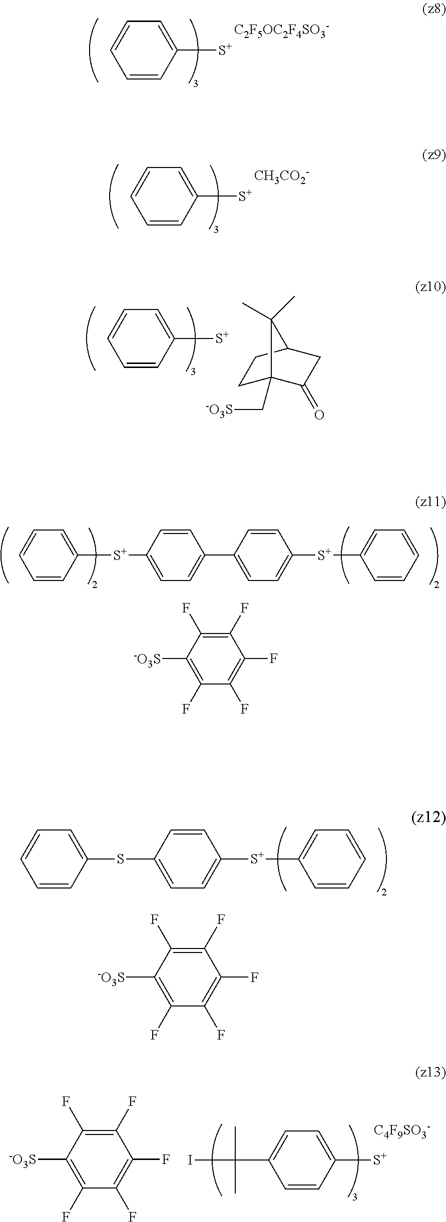

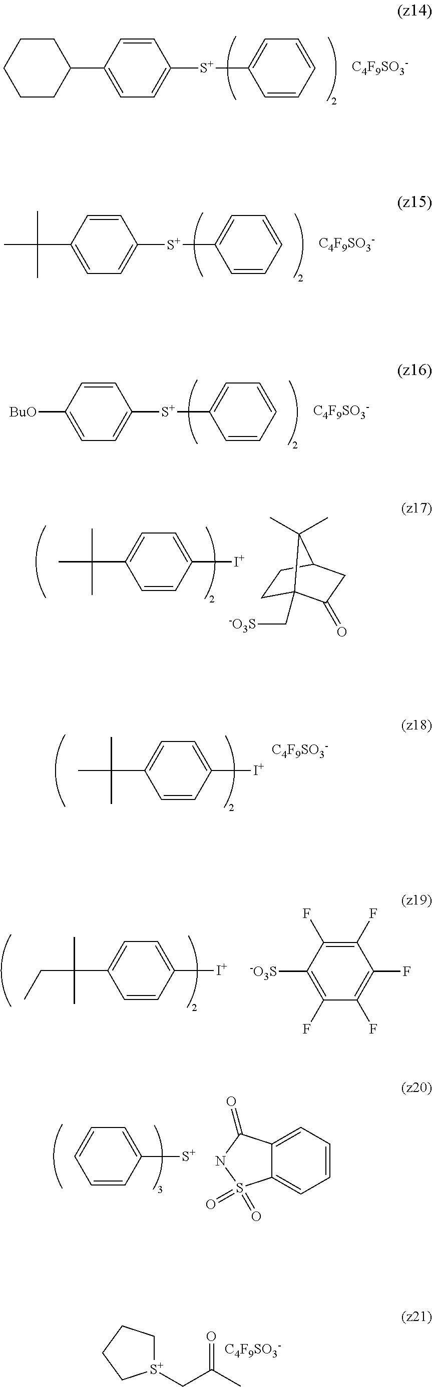

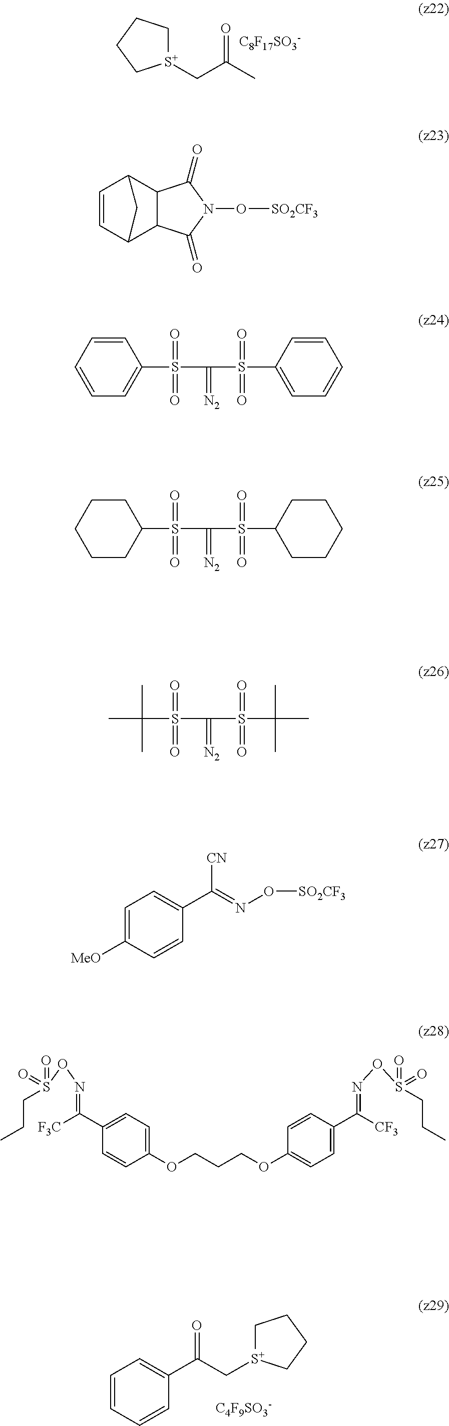

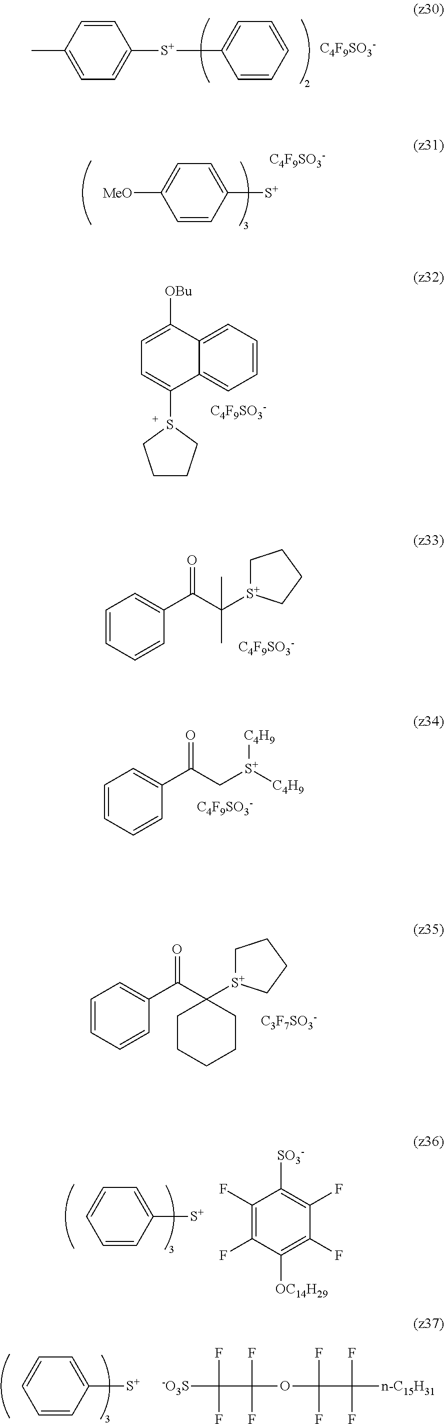

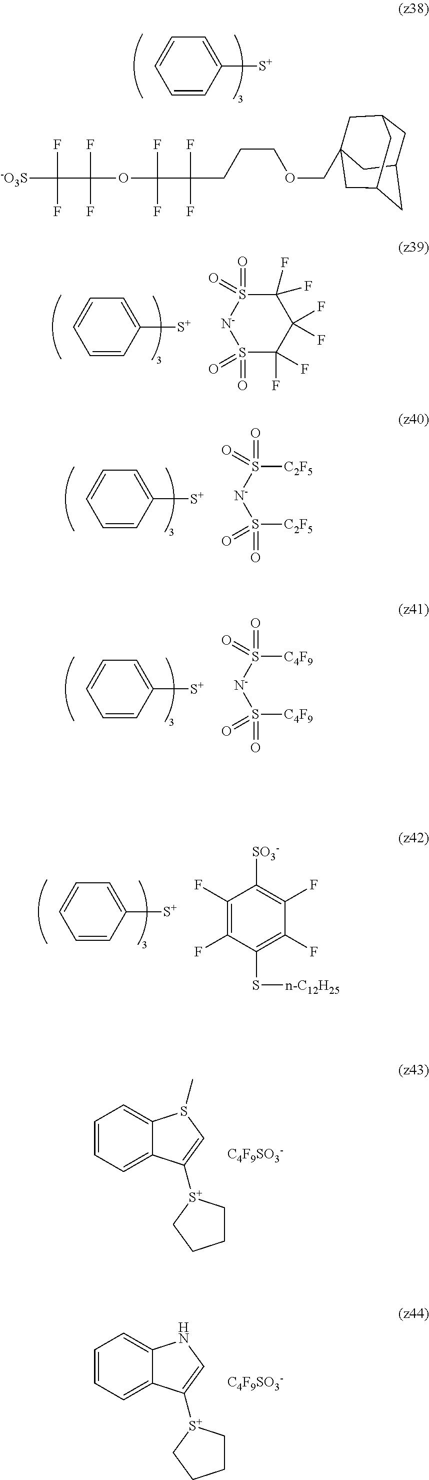

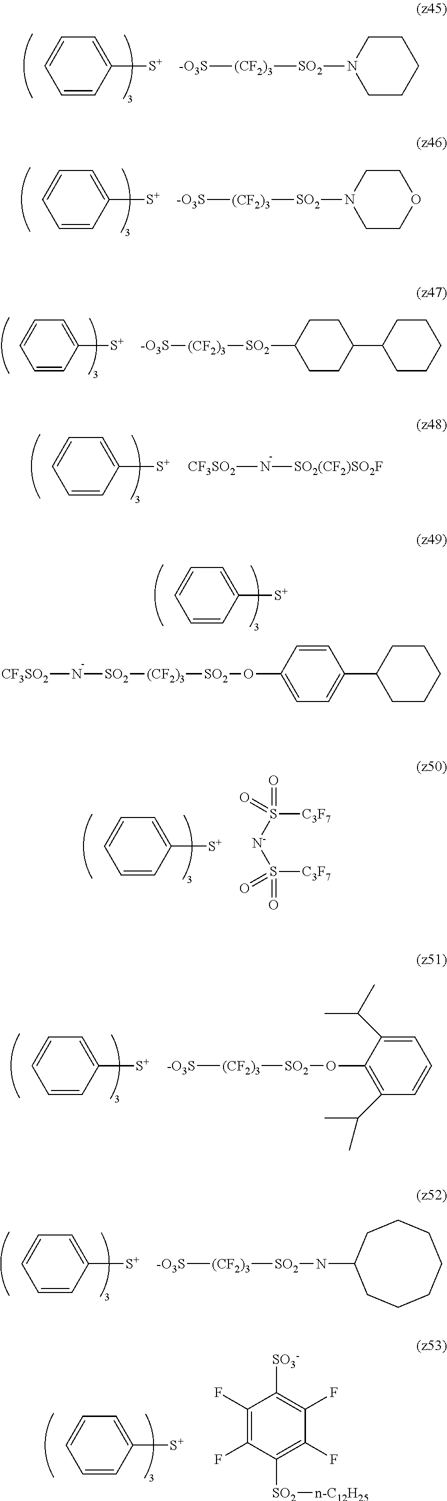

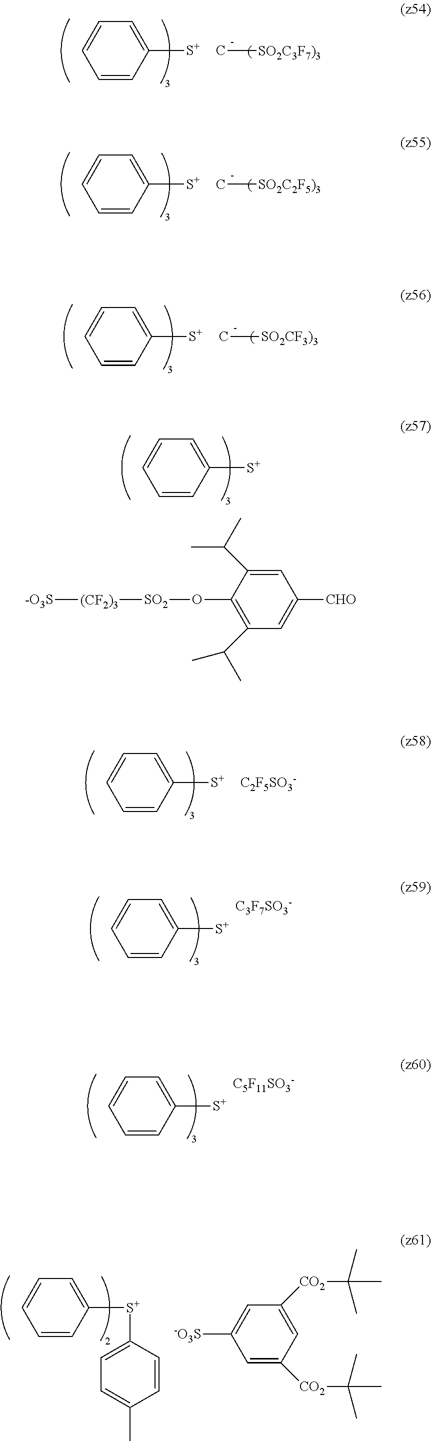

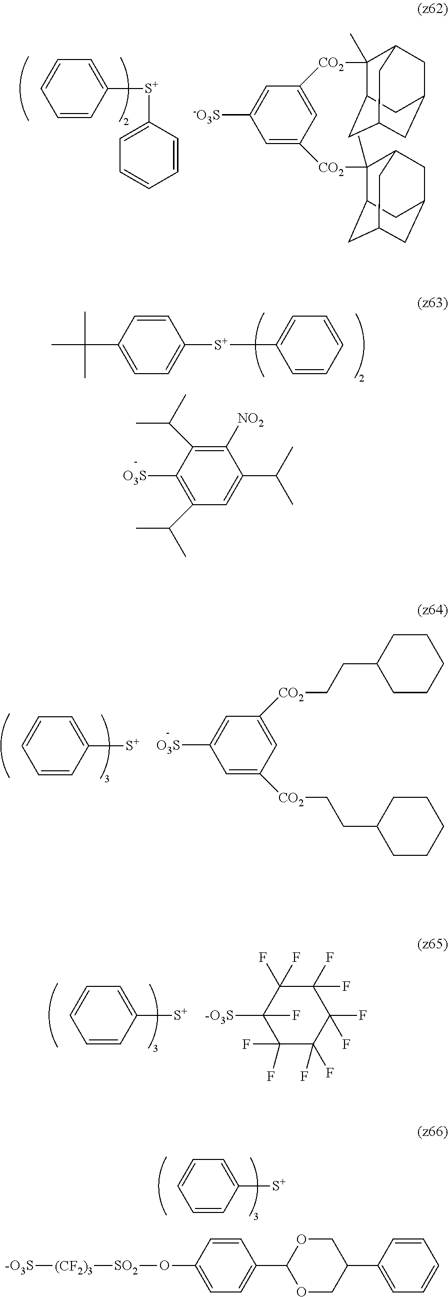

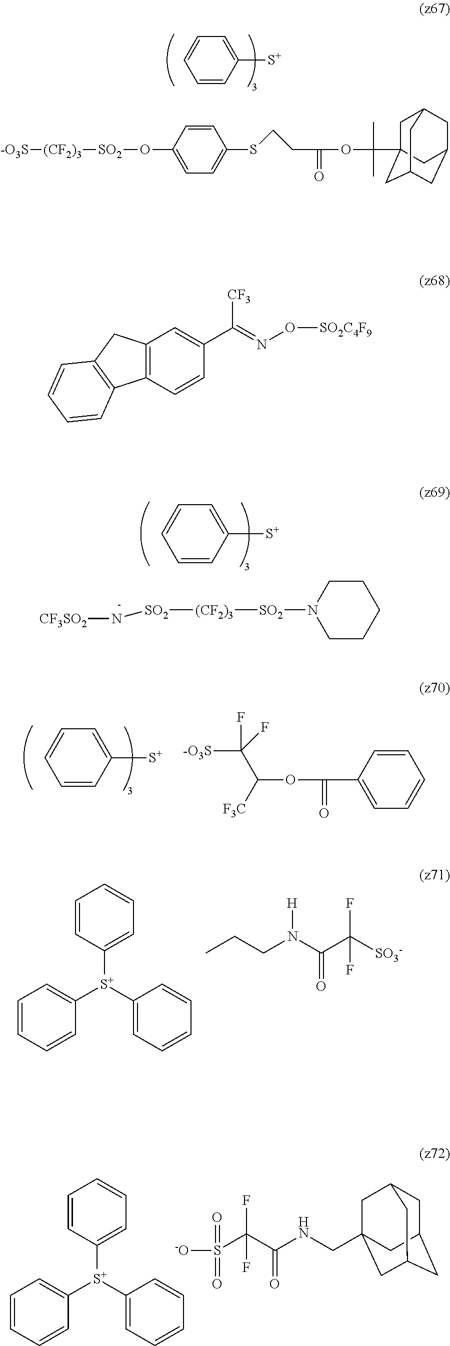

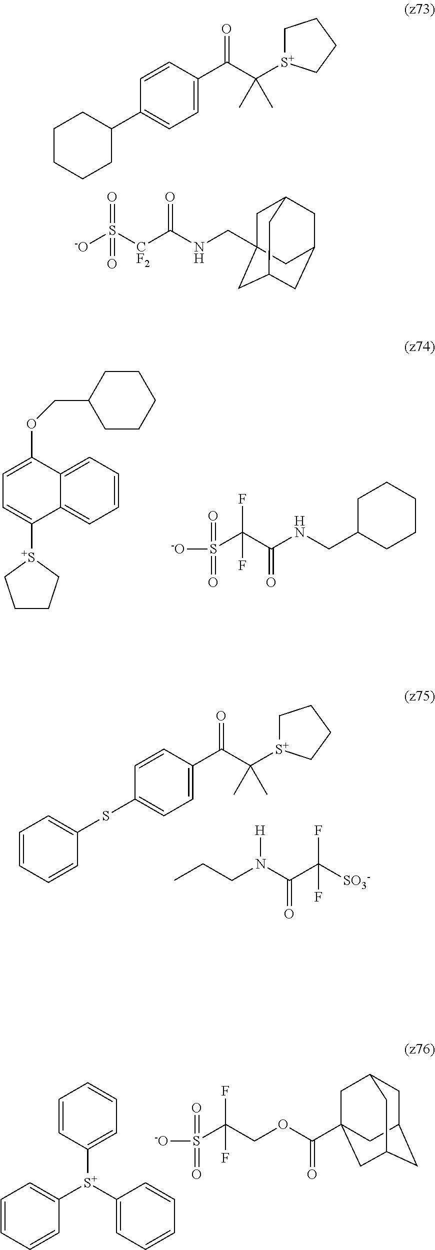

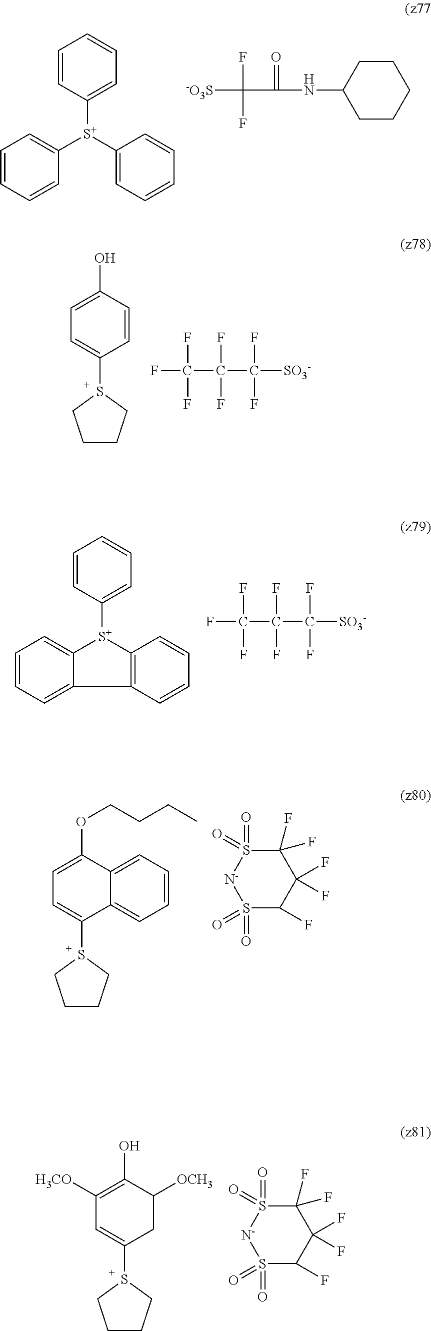

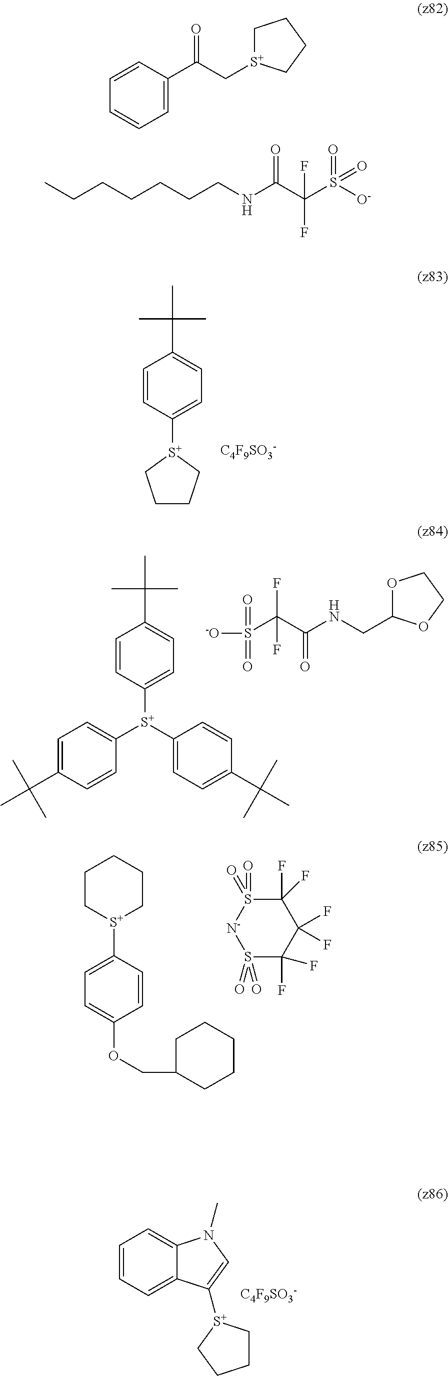

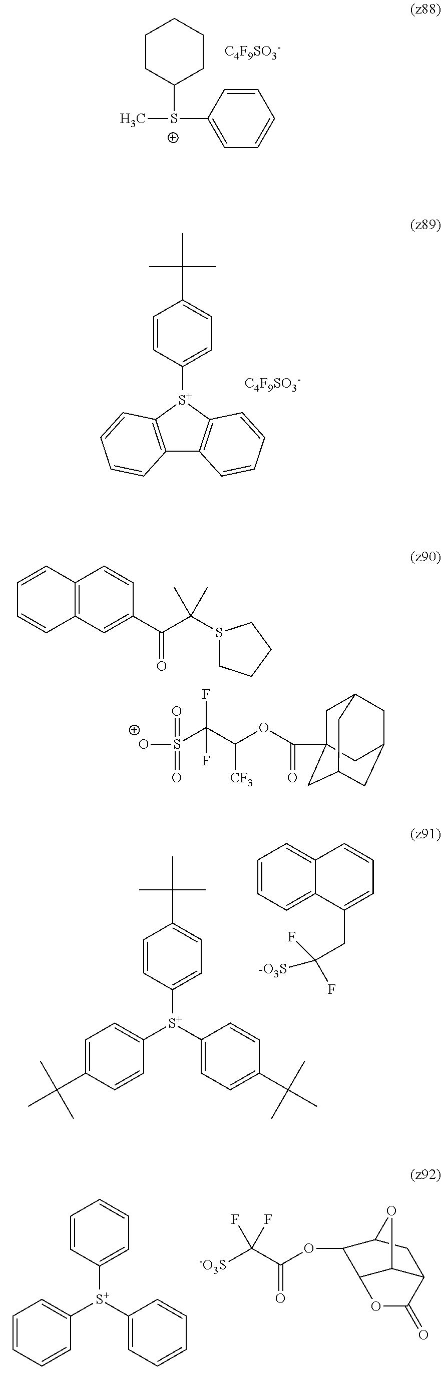

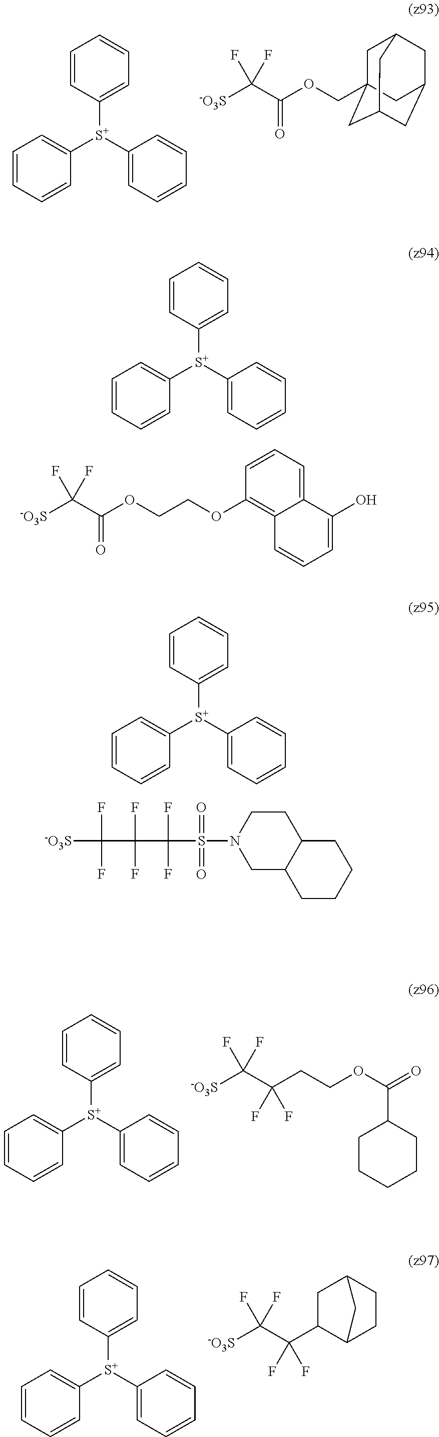

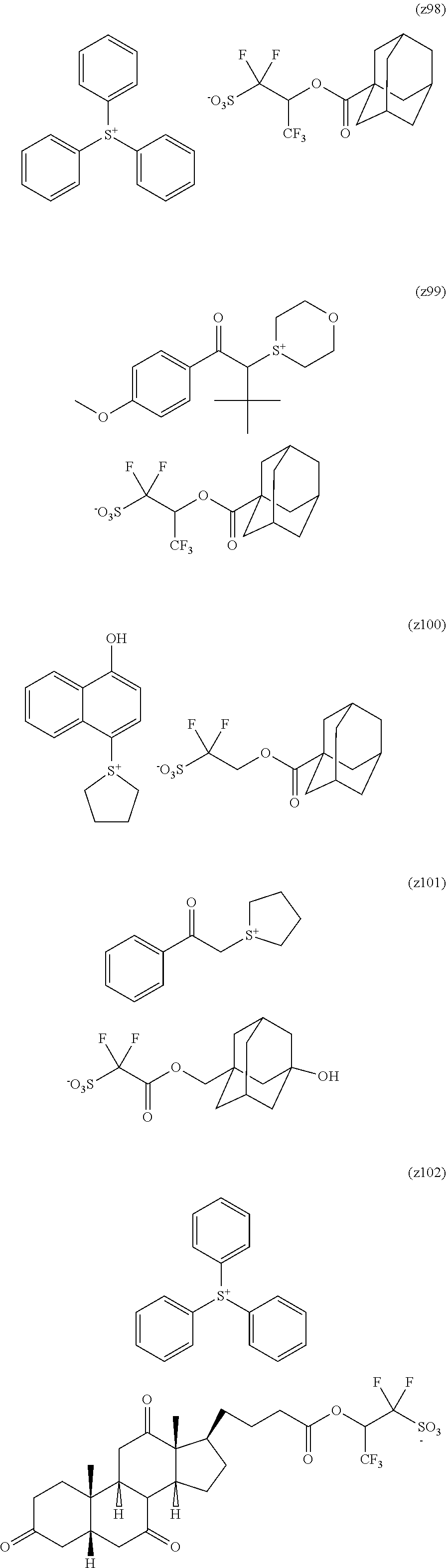

It is possible to use the acid generating agent as one type individually or in a combination of two or more types.

The content ratio of the acid generating agent in the composition is preferably 0.1 mass % to 30 mass % on the basis of the total solid content of the composition, more preferably 5 mass % to 28 mass %, and even more preferably 10 mass % to 25 mass %.

<Basic Compound>

The active light sensitive or radiation sensitive resin composition of the present invention preferably contains a basic compound in order to reduce changes in performance over time from the exposure to the heating. Usable basic compounds are not particularly limited; however, for example, it is possible to use compounds divided into (1) to (5) below.

(1) Basic Compound (N)

Examples of the basic compound preferably include a compound (N) which has a structure which is represented by Formulas (A) to (E) below.

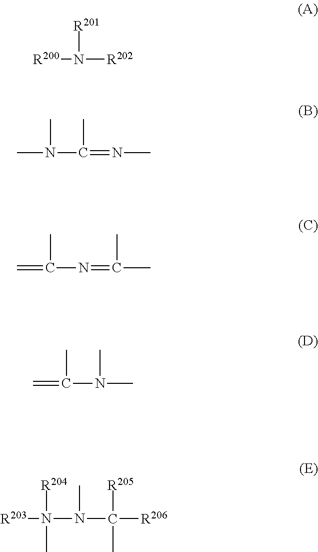

In General Formulas (A) and (E),

R²⁰⁰, R²⁰¹, and R²⁰² may be the same or may be different and represent a hydrogen atom, an alkyl group (preferably, 1 to 20 carbon atoms), a cycloalkyl group (preferably with 3 to 20 carbon atoms), or an aryl group (with 6 to 20 carbon atoms), and here, R²⁰¹ and R²⁰² may form a ring by bonding with each other.

R²⁰³, R²⁰⁴, R²⁰⁵, and R²⁰⁶ may be the same or may be different and represent an alkyl group with 1 to 20 carbon atoms.

With regard to the alkyl group described above, the alkyl group which has a substituent group is preferably an aminoalkyl group with 1 to 20 carbon atoms, a hydroxyalkyl group with 1 to 20 carbon atoms, or a cyanoalkyl group with 1 to 20 carbon atoms.

The alkyl groups in General Formulas (A) and (E) are preferably unsubstituted.

Examples of a preferable compound (N) include guanidine, aminopyrrolidine, pyrazole, pyrazoline, piperazine, aminomorpholine, aminoalkyl morpholine, piperidine, and the like, and examples of a more preferable compound (N) include a compound (N) which has an imidazole structure, a diazabicylo structure, an onium hydroxide structure, an onium carboxylate structure, a trialkylamine structure, an aniline structure, or a pyridine structure, an alkylamine derivative which has a hydroxy group and/or an ether bond, an aniline derivative which has a hydroxy group and/or an ether bond, and the like.

Examples of the compound (N) which has an imidazole structure include imidazole, 2,4,5-triphenyl imidazole, benzimidazole, 2-phenylbenzoimidazole, and the like. Examples of the compound (N) which has a diazabicyclo structure include 1,4-diazabicyclo[2,2,2]octane, 1,5-diazabicyclo[4,3,0]nona-5-en, 1,8-diazabicyclo[5,4,0]undeca-7-en, and the like. Examples of the compound (N) which has an onium hydroxide structure include tetrabutylammonium hydroxide, triarylsulfonium hydroxide, phenacylsulfonium hydroxide, sulfonium hydroxide which has a 2-oxoalkyl group, specifically, triphenylsulfonium hydroxide, tris(t-butylphenyl) sulfonium hydroxide, bis(t-butylphenyl) iodonium hydroxide, phenacyl thiophenium hydroxide, 2-oxopropylthiophenium hydroxide, and the like. The compound (N) which has an onium carboxylate structure is a compound where an anion section of a compound (N) which has an onium hydroxide structure is a carboxylate and examples thereof include acetate, adamantane-1-carboxylate, perfluoroalkyl carboxylate, and the like. Examples of the compound (N) which has a trialkylamine structure include tri(n-butyl)amine, tri(n-octyl)amine, and the like. Examples of the aniline compound (N) include 2,6-diisopropyl aniline, N,N-dimethyl aniline, N,N-dibutyl aniline, N,N-dihexyl aniline, and the like. Examples of the alkylamine derivative which has a hydroxy group and/or an ether bond include ethanol amine, diethanol amine, triethanol amine, N-phenyldiethanol amine, tris(methoxyethoxyethyl)amine, and the like. Examples of the aniline derivative which has a hydroxy group and/or an ether bond include N,N-bis(hydroxyethyl)aniline and the like.

Examples of a preferable basic compound (N) further include an amine compound which has a phenoxy group, an ammonium salt compound which has a phenoxy group, an amine compound which has a sulfonic acid ester group, and an ammonium salt compound which has a sulfonic acid ester group. Examples of the compounds include the compounds (C1-1) to (C3-3) exemplified in paragraph “0066” in US2007/0224539A1.

In addition, the compounds below are also preferable as the basic compound (N).

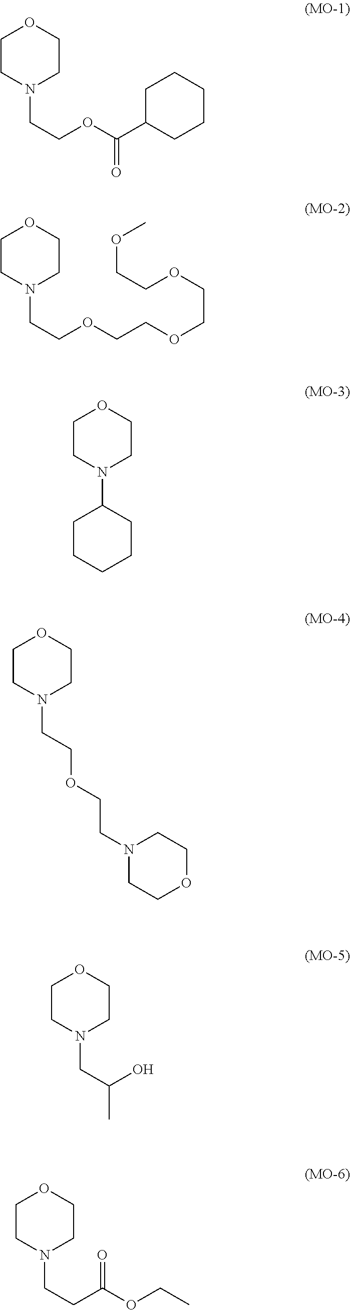

As the basic compound (N), apart from the compounds described above, it is also possible to use the compounds or the like described in paragraphs “0180” to “0225” in JP2011-22560A, paragraphs “0218” and “0219” in JP2012-137735A, and paragraphs “0416” to “0438” in WO2011/158687A1. The basic compound (N) may be a basic compound or an ammonium salt compound of which the basicity decreases when irradiated with active rays or radiation.

The basic compounds (N) may be used as one type individually or may be used in a combination of two or more types.

The composition of the present invention may or may not contain the basic compound (N); however, when contained, the content ratio of the basic compound (N) is generally 0.001 mass % to 10 mass % on the basis of the total solid content of the active light sensitive or radiation sensitive resin composition and preferably 0.01 mass % to 5 mass %.

The usage ratio of the acid generating agent and the basic compound (N) in the composition is preferably acid generating agent/basic compound (molar ratio)=2.5 to 300. That is, the molar ratio is preferably 2.5 or more from the point of view of the sensitivity and resolution and preferably 300 or less from the point of the view of suppressing decreases in the resolution due to the resist pattern becoming thick over time up to the heating process after the exposure. Acid generating agent/basic compound (N) (molar ratio) is more preferably 5.0 to 200 and even more preferably 7.0 to 150.

(2) Basic Compound or Ammonium Salt Compound (E) of which the Basicity Decreases when Irradiated with Active Rays or Radiation

The active light sensitive or radiation sensitive resin composition in the present invention preferably contains a basic compound or an ammonium salt compound of which the basicity decreases when irradiated with active rays or radiation (also referred to below as a “compound (E)”).

The compound (E) is preferably a compound (E-1) which has a basic functional group or an ammonium group and a group which generates an acidic functional group when irradiated with active rays or radiation. That is, the compound (E) is preferably a basic compound which has a basic functional group and a group which generates an acidic functional group when irradiated with active rays or radiation, or an ammonium salt compound which has an ammonium group and a group which generates an acidic functional group when irradiated with active rays or radiation.

Examples of a compound of which the basicity is decreased and which is generated due to the compound (E) or (E-1) being decomposed by irradiation with active rays or radiation include the compounds which are represented by General Formula (PA-I), (PA-II), or (PA-III) below and the compounds which are represented by General Formula (PA-II) or (PA-III) are particularly preferable from the point of view that it is possible to have all of excellent effects with regard to LWR, uniformity of a local pattern dimensions, and DOF at high dimensions.

Firstly, description will be given of the compound which is represented by General Formula (PA-I).

Q-A₁-(X)ₙ—B—R (PA-I)

In General Formula (PA-I),

A₁ represents a single bond or a divalent linking group.

Q represents —SO₃H or —CO₂H. Q is equivalent to an acidic functional group which is generated by irradiation with active rays or radiation.

X represents —SO₂— or —CO—.

n represents 0 or 1.

B represents a single bond, an oxygen atom, or —N(Rx)-.

Rx represents a hydrogen atom or a monovalent organic group.

R represents a monovalent organic group which has a basic functional group or a monovalent organic group which has an ammonium group.

Next, description will be given of compounds which are represented by General Formula (PA-II).

Q₁-X₁—NH—X₂-Q₂ (PA-II)

In General Formula (PA-II),

Q₁ and Q₂ each independently represents a monovalent organic group. However, one of Q₁ and Q₂ has a basic functional group. Q₁ and Q₂ may form a ring by bonding with each other and the formed ring may have a basic functional group.

X₁ and X₂ each independently represents —CO— or —SO₂—.

Here, —NH— is equivalent to an acidic functional group which is generated by irradiation with active rays or radiation.

Next, description will be given of compounds which are represented by General Formula (PA-III).

Q₁-X₁—NH—X₂-A₂-(X₃)ₘB-Q₃ (PA-III)

In General Formula (PA-III),

Q₁ and Q₃ each independently represents a monovalent organic group. However, any one of Q₁ and Q₃ has a basic functional group. Q₁ and Q₃ may form a ring by bonding with each other and the formed ring may have a basic functional group.

X₁, X₂, and X₃ each independently represents —CO— or —SO₂—.

A₂ represents a divalent linking group.

B represents a single bond, an oxygen atom, or —N(Qx)-.

Qx represents a hydrogen atom or a monovalent organic group.

When B is —N(Qx)-, Q₃ and Qx may form a ring by bonding with each other.

m represents 0 or 1.

Here, —NH— is equivalent to an acidic functional group which is generated by irradiation with active rays or radiation.

Specific examples of the compound (E) will be given below; however, the present invention is not limited thereto. In addition, other than the compounds, it is also possible to favorably use the compounds of (A-1) to (A-44) in US2010/0233629A or the compounds of (A-1) to (A-23) in US2012/0156617A.

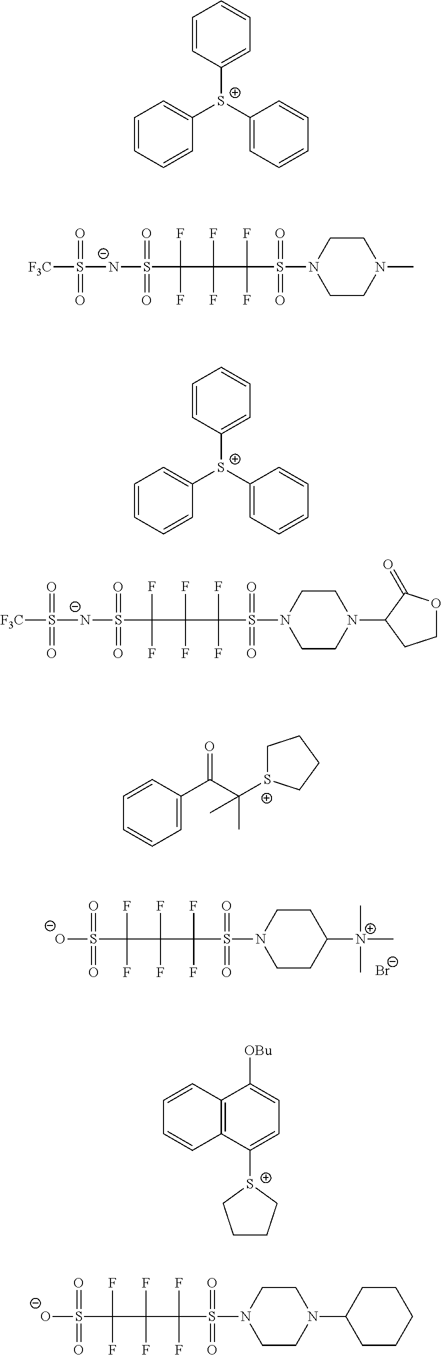

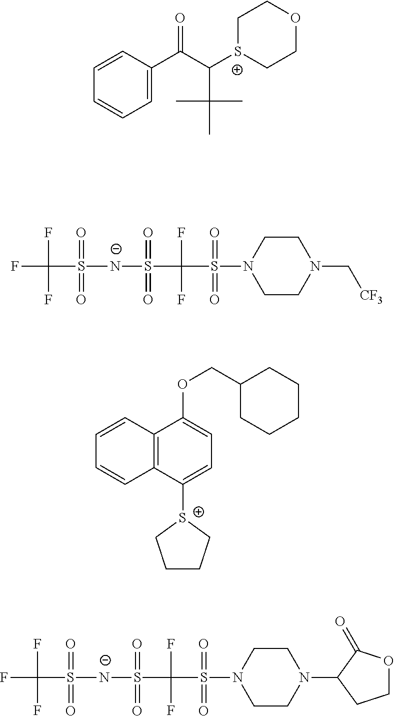 [SMILES: CC(C)(C)C(C(=O)c1ccccc1)[S+]1CCOCC1 ; O=S(=O)([N-]S(=O)(=O)C(F)(F)S(=O)(=O)N1CCN(CC(F)(F)F)CC1)C(F)(F)F ; c1ccc2c([S+]3CCCC3)ccc(OCC3CCCCC3)c2c1 ; O=C1OCCC1N1CCN(S(=O)(=O)C(F)(F)S(=O)(=O)[N-]S(=O)(=O)C(F)(F)F)CC1]

It is possible to synthesize the compound (E), in particular, based on the synthesis examples or the like in JP2006-330098A and JP2011-100105A.

The molecular weight of the compound (E) is preferably 500 to 1000.

The active light sensitive or radiation sensitive resin composition in the present invention may or may not contain the compound (E); however, when contained, the content of the compound (E) is preferably 0.1 mass % to 20 mass % on the basis of the total solid content of the active light sensitive or radiation sensitive resin composition and more preferably 0.1 mass % to 10 mass %.

In addition, as an aspect of the compound (E), examples thereof also include a compound (E-2) decomposed when irradiated with active rays or radiation which generates an acid (a weak acid) with a strength which does not acid-decompose the acid-decomposable group of the resin (A).

Examples of the compound include a carboxylic acid onium salt which does not have a fluorine atom (preferably sulfonium salt), a sulfonic acid onium salt which does not have a fluorine atom (preferably sulfonium salt), and the like. Preferable examples of a cation structure of sulfonium salt preferably include sulfonium cation structures exemplified in the acid generating agent (B).

Specific examples of the compound (E-2) include the compounds exemplified in paragraph “0170” in WO2012/053527A, the compounds of paragraphs “0268” and “0269” in JP2012-173419A, and the like.

(3) Low Molecular Compound (F) which has a Nitrogen Atom and which has a Group which is Desorbed by the Action of an Acid

The composition of the present invention may contain a compound which has a nitrogen atom and a group which is desorbed by the action of an acid (also referred to below as a “compound (F)”).

The group which is desorbed by the action of an acid is not particularly limited but is preferably an acetal group, a carbonate group, a carbamate group, a tertiary ester group, a tertiary hydroxy group, a hemiaminal ether group and particularly preferably a carbamate group and a hemiaminal ether group.

The molecular weight of a compound (N″) which has a group which is desorbed by the action of an acid is preferably 100 to 1000, more preferably 100 to 700, and particularly preferably 100 to 500.

The compound (F) is preferably an amine derivative which has a group which is desorbed by the action of an acid on a nitrogen atom.

The compound (F) may have a carbamate group which has a protective group on a nitrogen atom. It is possible to represent the protective group which configures the carbamate group using General Formula (d-1) below.

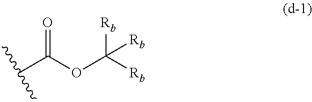

In General Formula (d-1),

Rb each independently represents a hydrogen atom, an alkyl group (preferably, with 1 to 10 carbon atoms), a cycloalkyl group (preferably, with 3 to 30 carbon atoms), an aryl group (preferably, with 3 to 30 carbon atoms), an aralkyl group (preferably with 1 to 10 carbon atoms), or an alkoxyalkyl group (preferably, with 1 to 10 carbon atoms). Rb may form a ring by linking with each other.

The alkyl group, the cycloalkyl group, the aryl group, and the aralkyl group indicated by Rb may be substituted with a hydroxyl group, a cyano group, an amino group, a pyrrolidino group, a piperidino group, a morpholino group, a functional group such as an oxo group, an alkoxy group, and a halogen atom. The alkoxyalkyl group indicated by Rb is the same.

Rb is preferably a straight-chain or branched alkyl group, a cycloalkyl group, and an aryl group. A straight-chain or branched alkyl group and a cycloalkyl group are more preferable.

Examples of a ring formed by two of Rb linking with each other include an alicyclic hydrocarbon group, an aromatic hydrocarbon group, a heterocyclic hydrocarbon group, or derivatives thereof, and the like.

Examples of a specific structure of a group which is represented by General Formula (d-1) include the structures disclosed in the paragraph “0466” in US2012/0135348A1; however, the present invention is not limited thereto.

The compound (F) particularly preferably has a structure which is represented by General Formula (6) below.

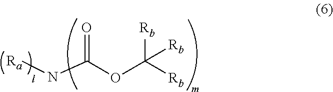

In General Formula (6), Ra represents a hydrogen atom, an alkyl group, a cycloalkyl group, an aryl group, or an aralkyl group. When 1 is 2, two of Ra may be the same or may be different and two of Ra may form a hetero ring with a nitrogen atom in the formula by linking with each other. Other hetero atoms than a nitrogen atom in the formula may be included in the hetero ring.

Rb is the same as in General Formula (d-1) described above and the preferable examples are also the same.

l represents an integer of 0 to 2, m represents an integer of 1 to 3, and l+m=3 is satisfied.

In General Formula (6), the alkyl group, the cycloalkyl group, the aryl group, and the aralkyl group as Ra may be substituted with the same group as the groups described above with which the alkyl group, the cycloalkyl group, the aryl group, and the aralkyl group as Rb may be substituted.

Preferable examples of the alkyl group, the cycloalkyl group, the aryl group, and the aralkyl group of the Ra (the alkyl group, the cycloalkyl group, the aryl group, and the aralkyl group may be substituted with the groups described above) include the same groups as the preferable examples described above with regard to Rb.

In addition, the hetero ring formed by Ra linking with each other preferably has 20 or less carbon atoms and examples thereof include a group which is derived from a heterocyclic compound such as pyrrolidine, piperidine, morpholine, 1,4,5,6-tetrahydropyrimidine, 1,2,3,4-tetrahydroquinoline, 1,2,3,6-tetrahydropyridine, homopiperazine, 4-azabenzimidazole, benzotriazole, 5-azabenzotriazole, 1H-1,2,3-triazole, 1,4,7-triazacyclononane, tetrazole, 7-azaindole, indazole, benzimidazole, imidazo[1,2-a]pyridine, (1S,4S)-(+)-2,5-diazabicyclo[2.2.1]heptane, 1,5,7-triazabicyclo[4.4.0]dec-5-en, indole, indoline, 1,2,3,4-tetrahydroquinoxaline, perhydroquinoline, and 1,5,9-triazacyclododecane, a group which substitutes a group which is derived from these heterocyclic compounds with one or more of one or more types of functional groups such as a straight-chain or branched group which is derived from alkane, a group which is derived from cycloalkane, a group which is derived from an aromatic compound, a group which is derived from a heterocyclic compound, a hydroxyl group, a cyano group, an amino group, a pyrrolidino group, a piperidino group, a morpholino group, and an oxo group.

Specific examples of a particularly preferable compound (F) in the present invention include the compounds disclosed in paragraph “0475” in US2012/0135348A1; however, the present invention is not limited thereto.

It is possible to synthesize the compound which is represented by General Formula (6) based on JP2007-298569A, JP2009-199021A, and the like.

In the present invention, it is possible to use the low molecular compound (F) as one type individually or in a mixture of two or more types.

The content of the compound (F) in the active light sensitive or radiation sensitive resin composition of the present invention is preferably 0.001 mass % to 20 mass % on the basis of the total solid content of the composition, more preferably 0.001 mass % to 10 mass %, and even more preferably 0.01 mass % to 5 mass %.

(4) Onium Salt

In addition, the composition of the present invention may include onium salt which is represented by General Formula (6A) or (6B) below as a basic compound. The onium salt is expected to control the diffusion of generated acid in a resist system in relation to the acid strength of a photoacid generator which is normally used in resist compositions.

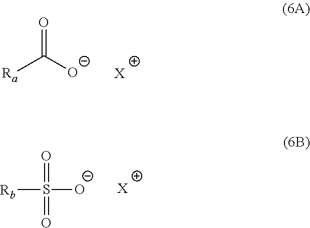

In General Formula (6A),

Ra represents an organic group. However, an organic group in which a carbon atom which is directly bonded to a carboxylic acid group in the formula is substituted with a fluorine group is excluded.

X⁺ represents an onium cation.

In General Formula (6B),

Rb represents an organic group. However, an organic group in which a carbon atom which is directly bonded to a sulfonic acid group in the formula is substituted with a fluorine group is excluded.

X⁺ represents an onium cation.

With regard to the organic group which is represented by Ra and Rb, the atom which is directly bonded to a carboxylic acid group or a sulfonic acid group in the formula is preferably a carbon atom. However, in this case, in order to make an acid relatively weaker than the acid which is generated from the photoacid generator described above, the carbon atom which is directly bonded to a sulfonic acid group or a carboxylic acid group is not substituted with a fluorine atom.

Examples of the organic group which is represented by Ra and Rb include an alkyl group with 1 to 20 carbon atoms, a cycloalkyl group with 3 to 20 carbon atoms, an aryl group with 6 to 30 carbon atoms, an aralkyl group with 7 to 30 carbon atoms, a heterocyclic group with 3 to 30 carbon atoms, and the like. With regard to the groups, some or all of the hydrogen atoms may be substituted.

Examples of a substituent group which the alkyl group, the cycloalkyl group, the aryl group, the aralkyl group, and the heterocyclic group described above may have include a hydroxyl group, a halogen atom, an alkoxy group, a lactone group, an alkyl carbonyl group, and the like.

Examples of the onium cation which is represented by X⁺ in General Formulas (6A) and (6B) include a sulfonium cation, an ammonium cation, an iodonium cation, a phosphonium cation, a diazonium cation, and the like, and a sulfonium cation is more preferable among these.

The sulfonium cation is preferably, for example, an arylsulfonium cation which has at least one aryl group and more preferably a triarylsulfonium cation. The aryl group may have a substituent group and the aryl group is preferably a phenyl group.

Examples of the sulfonium cation and the iodonium cation also preferably include the sulfonium cation structure of General Formula (ZI) in the compound (B) or the iodonium structure in General Formula (ZII).

Specific structures of the onium salt which is represented by General Formula (6A) or (6B) will be shown below.

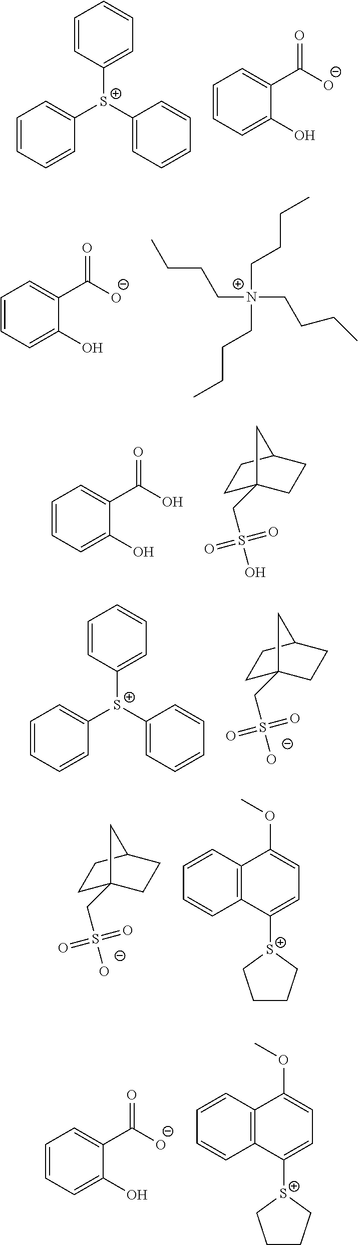

In a case where the composition of the present invention contains onium salt which is represented by General Formula (6A) or (6B), the content ratio is generally 0.01 mass % to 10 mass % on the basis of the total solid content of the active light sensitive or radiation sensitive resin composition and more preferably 0.1 mass % to 5 mass %.

(5) Betaine Compound

Furthermore, with regard to the composition of the present invention, it is also possible to preferably use compounds (also referred to below as “betaine compounds”) which have both an onium salt structure and an acid anion structure in one molecule such as the compounds which are included in Formula (I) in JP2012-189977A, the compounds which are represented by Formula (I) in JP2013-6827A, the compounds which are represented by Formula (I) in JP2013-8020A, and the compounds which are represented by Formula (I) in JP 2012-252124A. Examples of the onium salt structure include sulfonium, iodonium, and ammonium structures and a sulfonium or iodonium salt structure is preferable. In addition, an acid anion structure is preferably a sulfonic acid anion or a carboxylic acid anion. Examples of the compounds include the following.

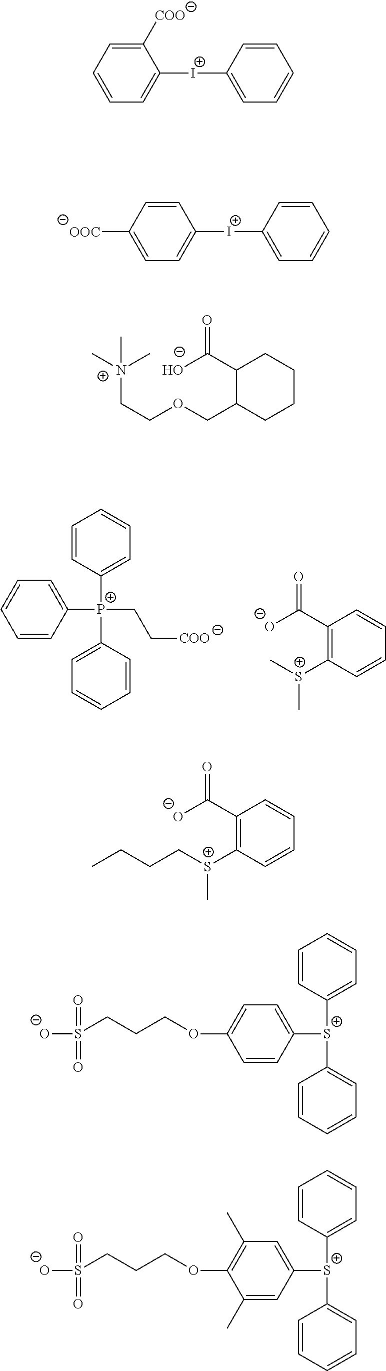

(6) Nitrogen-Containing Compound (C)

In one aspect, the composition of the present invention may contain a nitrogen-containing compound (C) which is represented by General Formula (5) below as a basic compound.

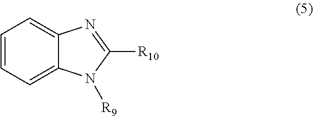

In the formula,

R₉ represents a hydrogen atom or an organic group which is decomposed by the action of an acid.

R₁₀ represents a hydrogen atom, an alkyl group, or an aryl group.

A group which is represented by R₉ is preferably a hydrogen atom.

An alkyl group which is represented by R₁₀ is preferably an alkyl group with 1 to 4 carbon atoms and examples thereof include a methyl group, an isopropyl group, and the like.

An aryl group which is represented by R₁₀ is, for example, preferably an aryl group with 6 to 14 carbon atoms and examples thereof include a phenyl group, a naphthyl group, and the like.

The alkyl group and the aryl group described above may have a substituent group and examples of the substituent include a fluorine atom and the like.

Specific examples of the nitrogen-containing compound (C) include the compounds below.

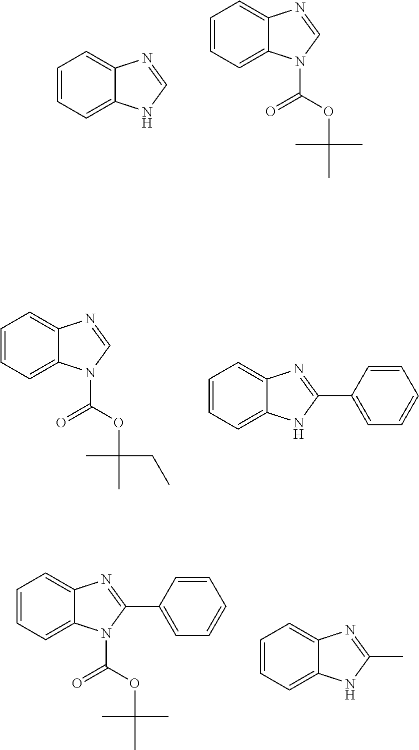

Hydrophobic Resin

The composition of the present invention may contain a hydrophobic resin (also referred to below as a “hydrophobic resin (HR)” or “resin (HR)”) which includes at least either a fluorine atom or a silicon atom.

A fluorine atom and/or a silicon atom in the hydrophobic resin (HR) may be included in the main chain of a resin or may be included in a side chain.

In a case where the hydrophobic resin (HR) includes a fluorine atom, the resin is preferably provided with an alkyl group which includes a fluorine atom, a cycloalkyl group which includes a fluorine atom, or an aryl group which includes a fluorine atom as a partial structure which includes a fluorine atom.

An alkyl group which includes a fluorine atom is a straight-chain or branched chain alkyl group in which at least one hydrogen atom is substituted with a fluorine atom. The alkyl group preferably has 1 to 10 carbon atoms and more preferably has 1 to 4 carbon atoms. The alkyl group which includes a fluorine atom may further have a substituent group other than a fluorine atom.

A cycloalkyl group which includes a fluorine atom is a monocyclic or polycyclic cycloalkyl group in which at least one hydrogen atom is substituted with a fluorine atom. The cycloalkyl group which includes a fluorine atom may further have a substituent group other than a fluorine atom.

An aryl group which includes a fluorine atom is an aryl group in which at least one hydrogen atom is substituted with a fluorine atom. Examples of the aryl group include a phenyl group and a naphthyl group. The aryl group which includes a fluorine atom may further have a substituent group other than a fluorine atom.

Preferable examples of the alkyl group which includes a fluorine atom, the cycloalkyl group which includes a fluorine atom, and the aryl group which includes a fluorine atom include groups which are represented by General Formulas (F2) to (F4) below.

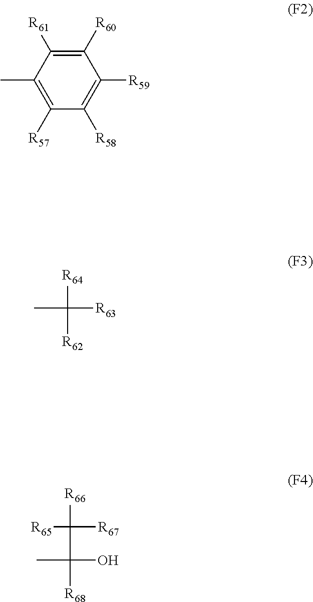

In General Formulas (F2) to (F4), R₅₇ to R₆₈ each independently represents a hydrogen atom, a fluorine atom, or an alkyl group. However, at least one out of R₅₇ to R₆₁ represents a fluorine atom or an alkyl group in which at least one hydrogen atom is substituted with a fluorine atom. At least one out of R₆₂ to R₆₄ represents a fluorine atom or an alkyl group in which at least one hydrogen atom is substituted with a fluorine atom. At least one out of R₆₅ to R₆₈ represents a fluorine atom or an alkyl group in which at least one hydrogen atom is substituted with a fluorine atom. The alkyl groups are preferably with 1 to 4 carbon atoms.

R₅₇ to R₆₁ and R₆₅ to R₆₇ are preferably all fluorine atoms.

R₆₂, R₆₃, and R₆₈ are preferably an alkyl group in which at least one hydrogen atom is substituted with a fluorine atom and more preferably a perfluoroalkyl group with 1 to 4 carbon atoms. Here, R₆₂ and R₆₃ may form a ring by bonding with each other.

Specific examples of a repeating unit which includes a fluorine atom will be shown below.

In the specific examples, X₁ represents a hydrogen atom, —CH₃, —F, or —CF₃. X₂ represents —F or —CF₃.

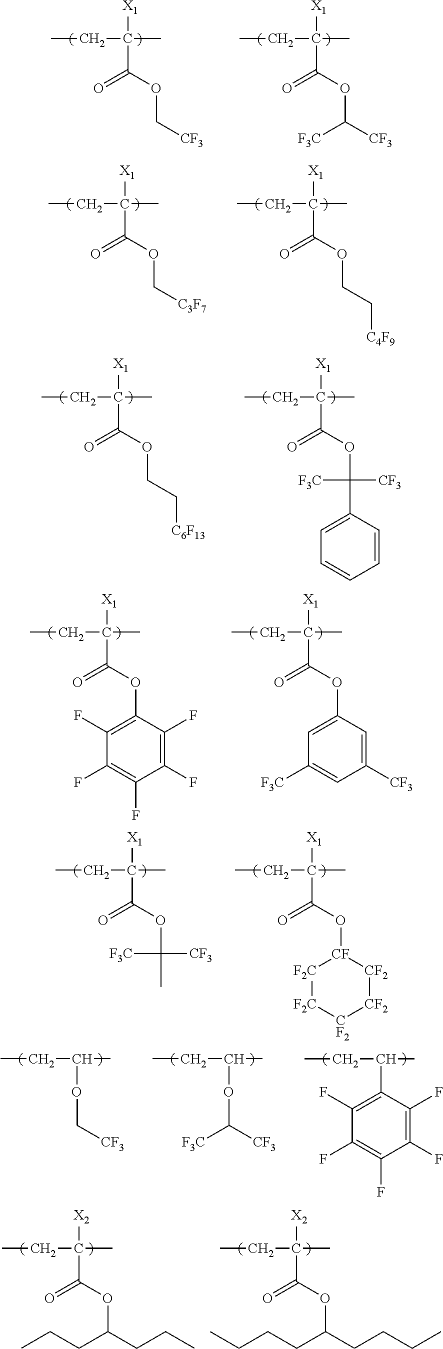

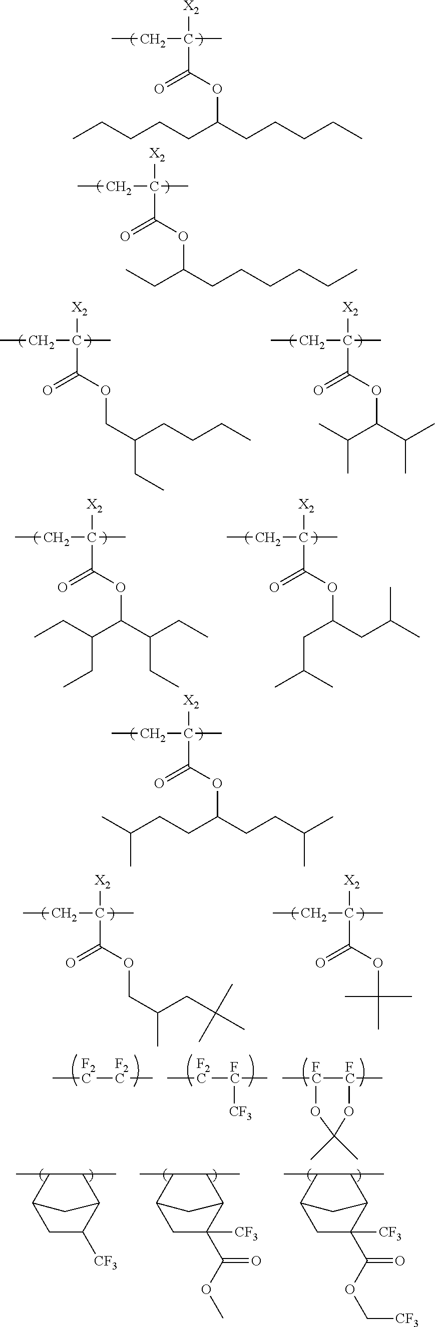

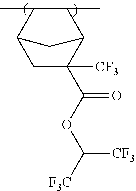 [SMILES: CC1C2CC(C1C)C(C(=O)OC(C(F)(F)F)C(F)(F)F)(C(F)(F)F)C2]

In a case where the hydrophobic resin (HR) includes a silicon atom, the resin is preferably provided with an alkylsilyl structure or a cyclic siloxane structure as a partial structure which includes a silicon atom. The alkylsilyl structure is preferably a structure which includes a trialkylsilyl group.

Preferable examples of the alkylsilyl structure and the cyclic siloxane structure include groups which are represented by General Formulas (CS-1) to (CS-3) below.

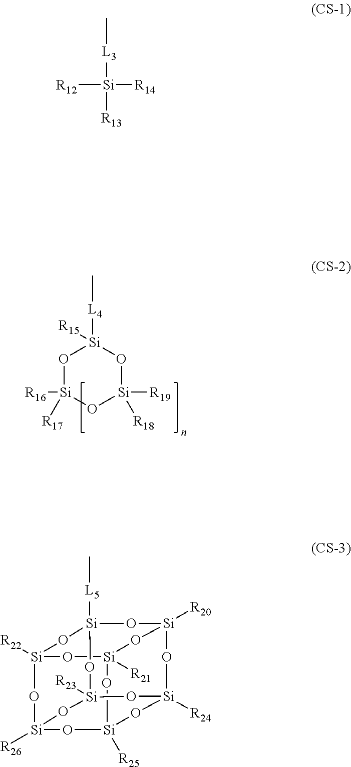

In General Formulas (CS-1) to (CS-3), R₁₂ to R₂₆ each independently represents a straight-chain or branched chain alkyl group or a cycloalkyl group. The alkyl group preferably has 1 to 20 carbon atoms. The cycloalkyl group preferably has 3 to 20 carbon atoms.

L₃ to L₅ represent a single bond or a divalent linking group. Examples of the divalent linking group include an alkylene group, a phenylene group, an ether bond, a thioether group, a carbonyl group, an ester bond, an amide bond, a urethane bond, a urea bond, or a combination thereof n represents an integer of 1 to 5. n is preferably an integer of 2 to 4.

Specific examples of a repeating unit which has a group which is represented by General Formulas (CS-1) to (CS-3) will be given below. In the specific examples, X₁ represents a hydrogen atom, —CH₃, —F, or —CF₃.

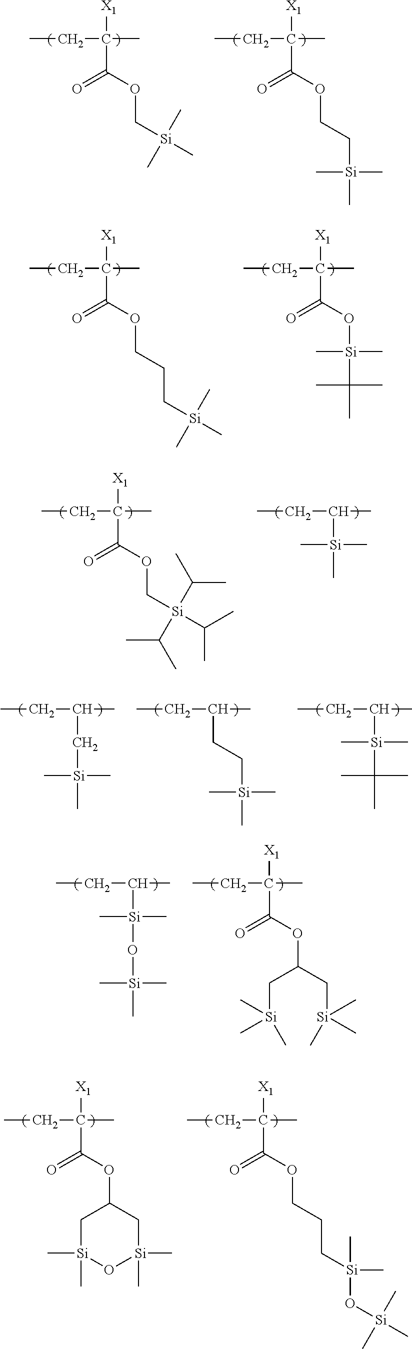

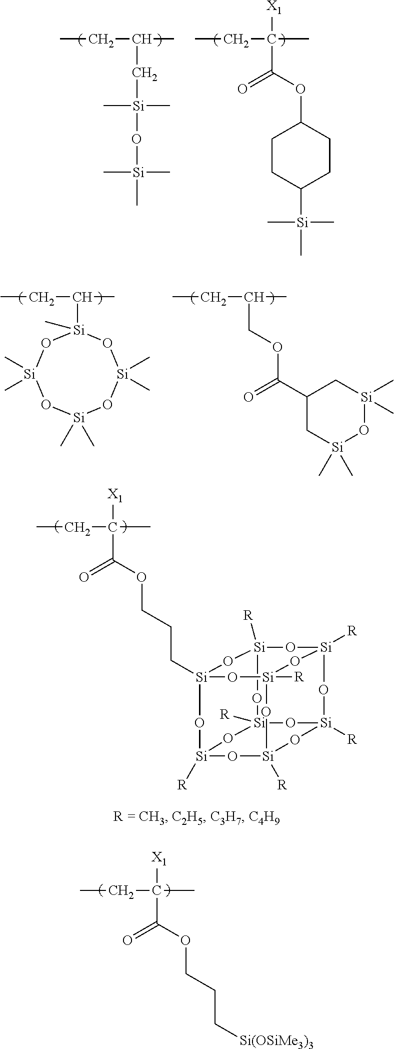

In one aspect, the hydrophobic resin (HR) preferably has a repeating unit which is provided with a basic group or a group of which the basicity is increased by the action of an acid (also referred to below as a “basic site”). The aspect may be a resin (also referred to below as a “resin (HR-a)”) which has a repeating unit which has at least one of a fluorine atom and a silicon atom and a repeating unit which is provided with a basic site, or may be a resin (also referred to below as “a resin (HR-b)”) which has a repeating unit which is provided with at least one of a fluorine atom and a silicon atom, and a basic site.

In the resin (HR-a), specific examples of the repeating unit which has at least one of a fluorine atom or a silicon atom include the examples described above.

In the resin (HR-a), the repeating unit which has a basic group or a group of which the basicity is increased by the action of an acid is preferably the repeating unit which is represented by General Formula (B-I) below.

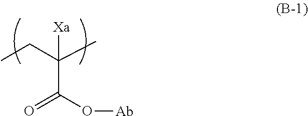

In General Formula (B-I), Xa represents a hydrogen atom, a methyl group which may have a substituent group, or a group which is represented by —CH₂—R₉. R₉ represents a hydroxy group or a monovalent organic group, examples of the monovalent organic group include an alkyl group with 5 or less carbon atoms and an acyl group with 5 or less carbon atoms, an alkyl group with 3 or less carbon atoms is preferable, and a methyl group is more preferable. Xa is preferably a hydrogen atom, a methyl group, a trifluoromethyl group, or a hydroxymethyl group and more preferably a hydrogen atom, a methyl group, or a hydroxymethyl group.

Ab represents a group which has a basic group or a group which has a group of which the basicity is increased by the action of an acid.

In Ab, the group which has basic group and a group of which the basicity increases by the action of an acid preferably both include a nitrogen atom.

A group which has a basic group as Ab is preferably a group which has a skeleton of a basic compound described in the “basic compound” or an ammonium group.

In addition, examples of a repeating unit which is provided with at least one of a fluorine atom and a silicon atom and a basic site in the resin (HR-b) include the specific examples shown below.

Specific examples of a repeating unit which has a basic group or a group of which the basicity is increased by the action of an acid in the resin (HR) will be given below; however, the present invention is not limited thereto. In the specific examples, X represents a hydrogen atom, —CH₃, —CH₂OH, —F, or —CF₃.

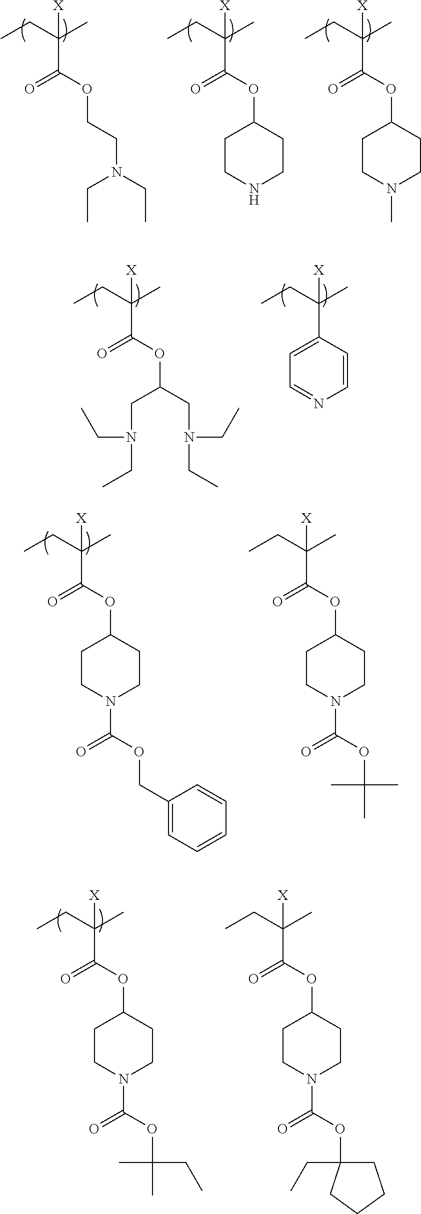

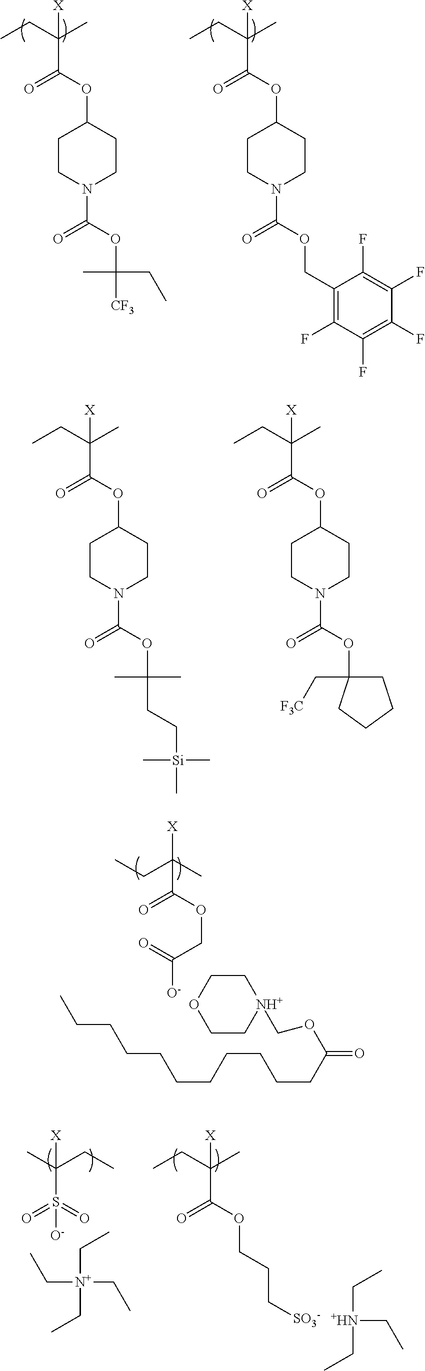

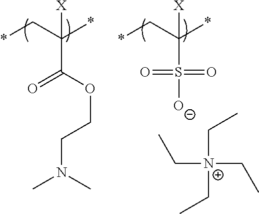

The resin (HR) may further include a repeating unit which is represented by General Formula (III′) below.

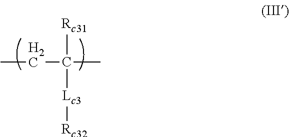

Rc₃₁ represents a hydrogen atom, an alkyl group (which may be substituted with a fluorine atom and the like), a cyano group, or a —CH₂—O-Rac₂ group. In the formula, Rac₂ represents a hydrogen atom, alkyl group, or an acyl group.

Rc₃₁ is preferably a hydrogen atom, a methyl group, and a trifluoromethyl group and particularly preferably a hydrogen atom and a methyl group.

Rc₃₂ represents an alkyl group, a cycloalkyl group, an alkenyl group, a cycloalkenyl group, or a group which has an aryl group. The groups may be substituted with groups which include silicon atoms, fluorine atoms, and the like.

L_{c3} represents a single bond or a divalent linking group.

An alkyl group of R_{c32} is preferably a straight-chain or branched chain alkyl group with 3 to 20 carbon atoms.

A cycloalkyl group preferably has 3 to 20 carbon atoms.

An alkenyl group preferably has 3 to 20 carbon atoms.

A cycloalkenyl group preferably has 3 to 20 carbon atoms.

R_{c32} is preferably an unsubstituted alkyl group or an alkyl group in which at least one hydrogen atom is substituted with a fluorine atom.

L_{c3} represents a single bond or a divalent linking group. Examples of the divalent linking group include an ester group, an alkylene group (preferably with 1 to 5 carbon atoms), an oxy group, a phenylene group, an ester bond (a group which is represented by —COO—), or a group formed with a combination of two or more types thereof and a linking group with 1 to 12 total carbon atoms is preferable.

The resin (HR) may further include a repeating unit which is represented by General Formula (CII-AB) below.

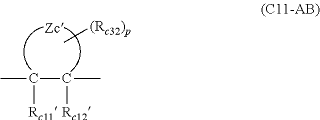

In Formula (CII-AB),

R_{c11}′ and R_{c12}′ each independently represents a hydrogen atom, a cyano group, a halogen atom, or an alkyl group. Zc′ represents an atomic group which is necessary to form an alicyclic structure together with two carbon atoms (C—C) with which R_{c11}′ and R_{c12}′ are bonded.

Rc₃₂ is a substituent group with respect to the alicyclic structure described above and the definition thereof is the same as R_{c32} in General Formula (III′).

p represents an integer of 0 to 3 and is preferably 0 or 1.

Specific examples of the repeating unit which is represented by General Formula (III′) or (CII-AB). In the specific examples, Ra represents H, CH₃, CH₂OH, CF₃, or CN.

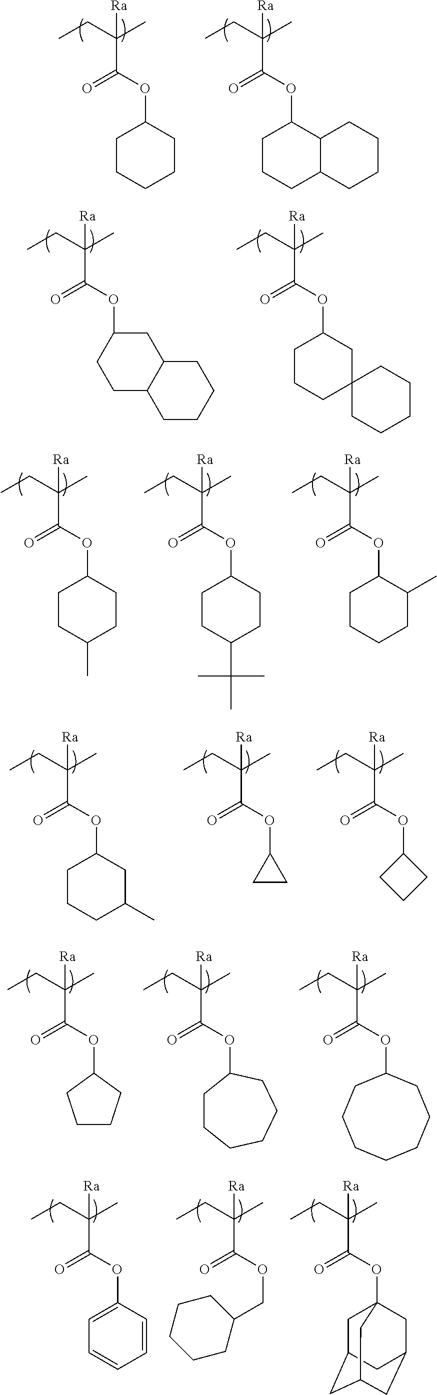

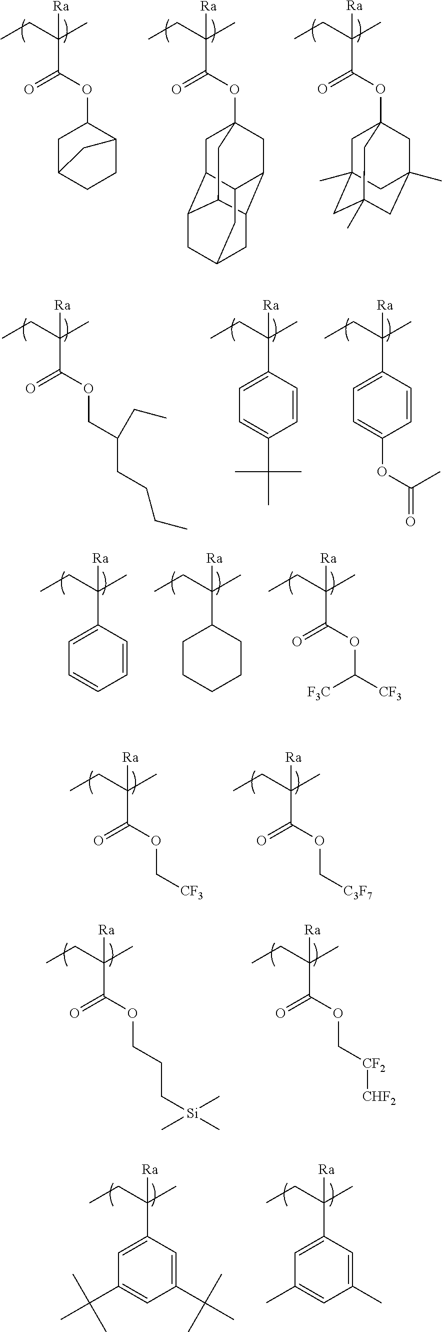

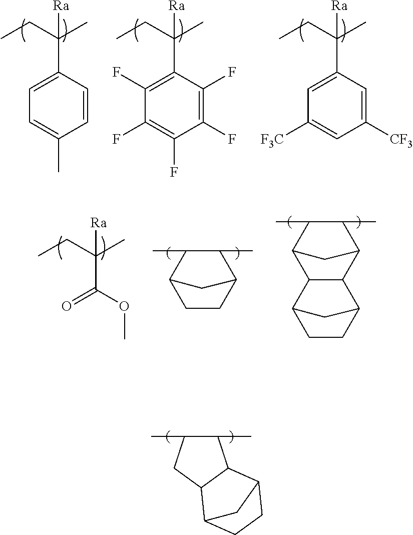

Specific examples of the resin (HR) will be given below; however, the present invention is not limited thereto.

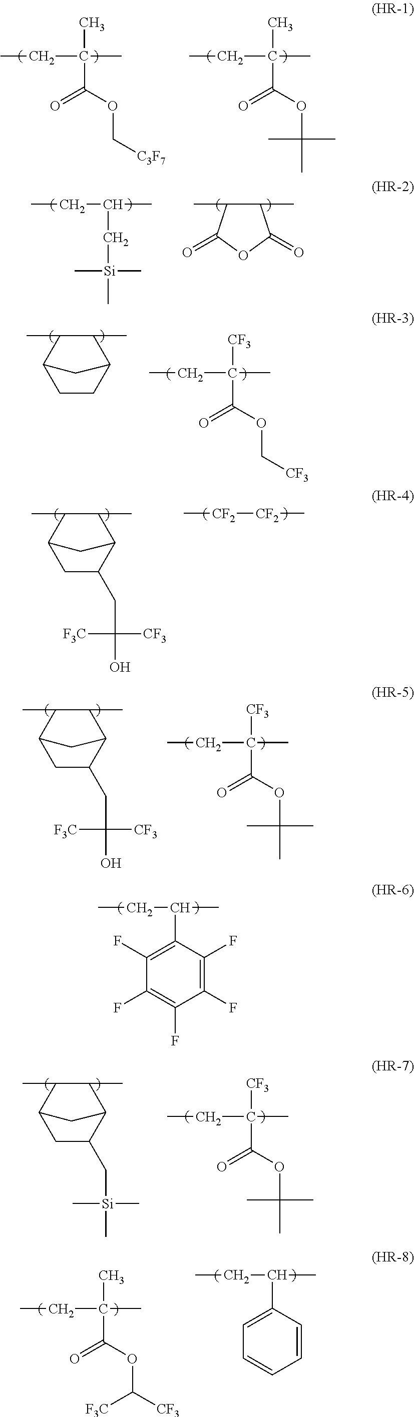

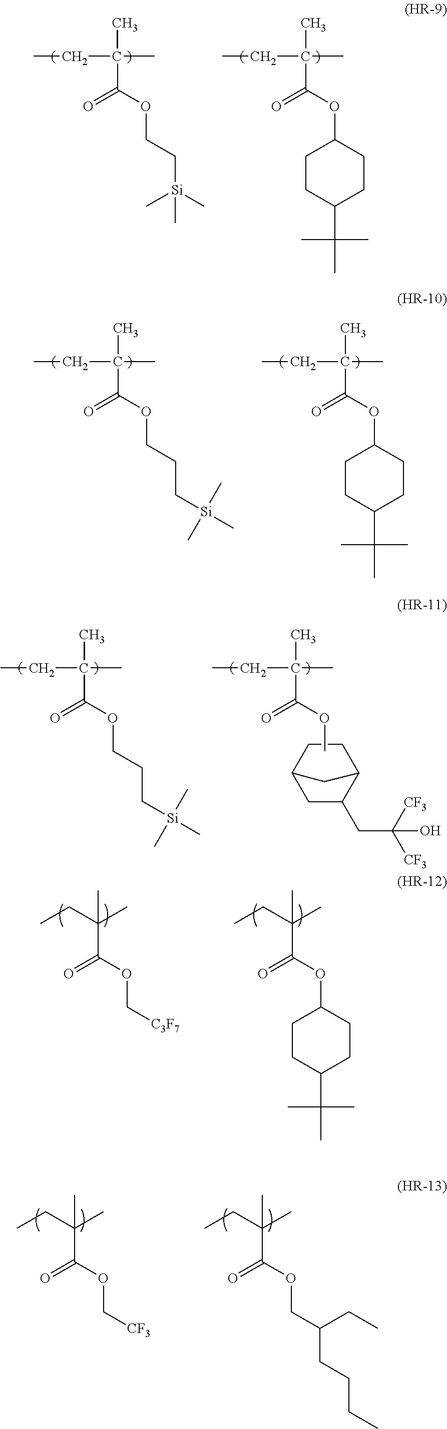

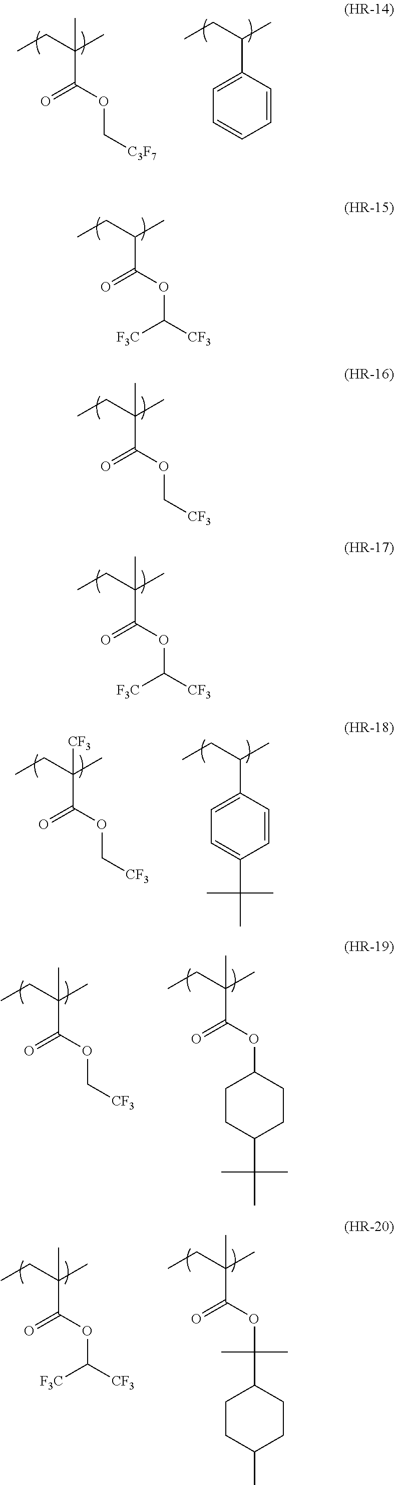

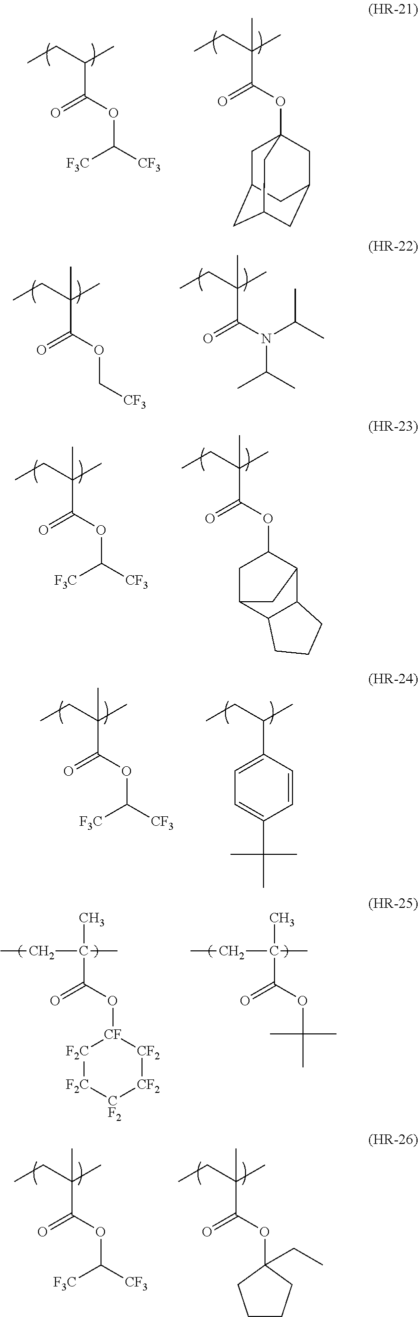

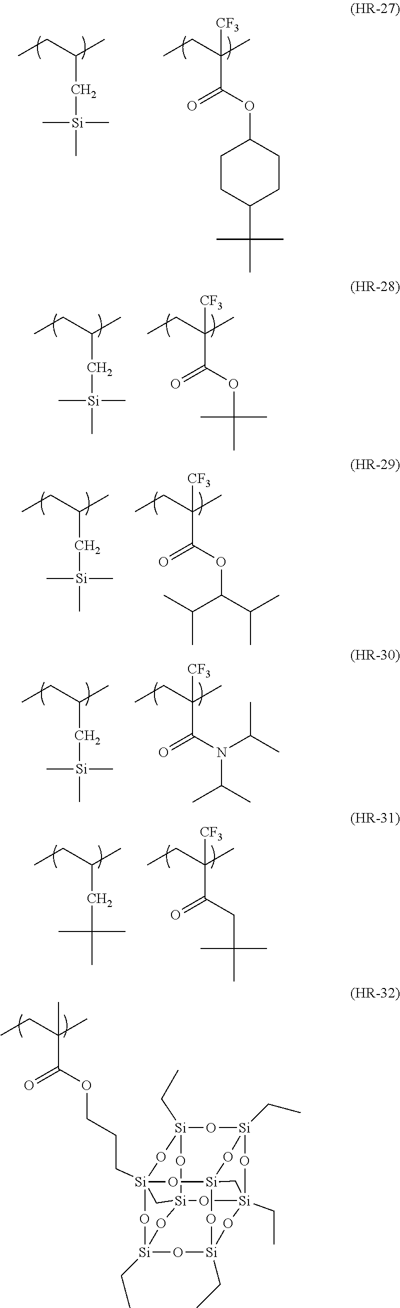

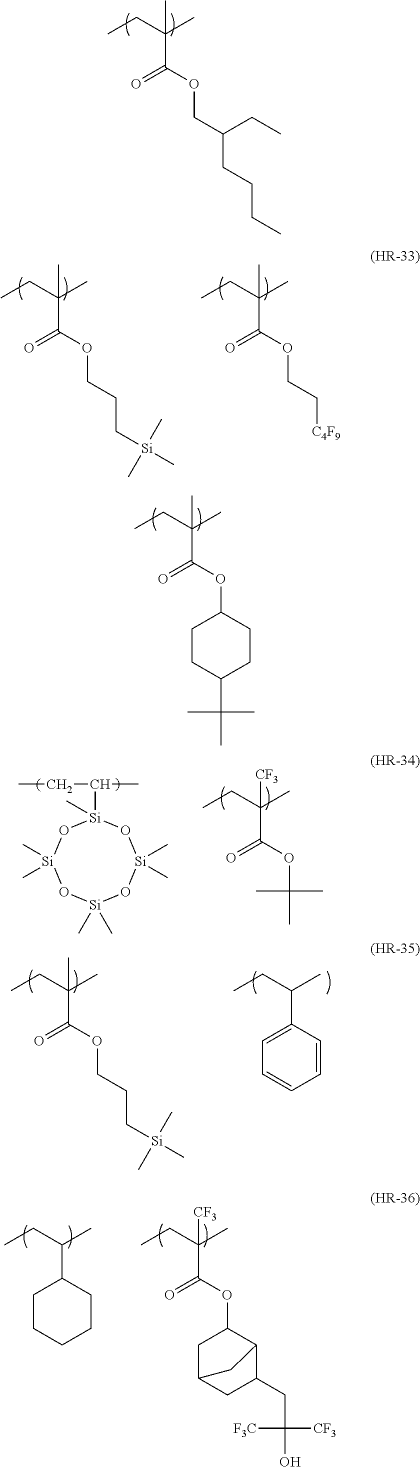

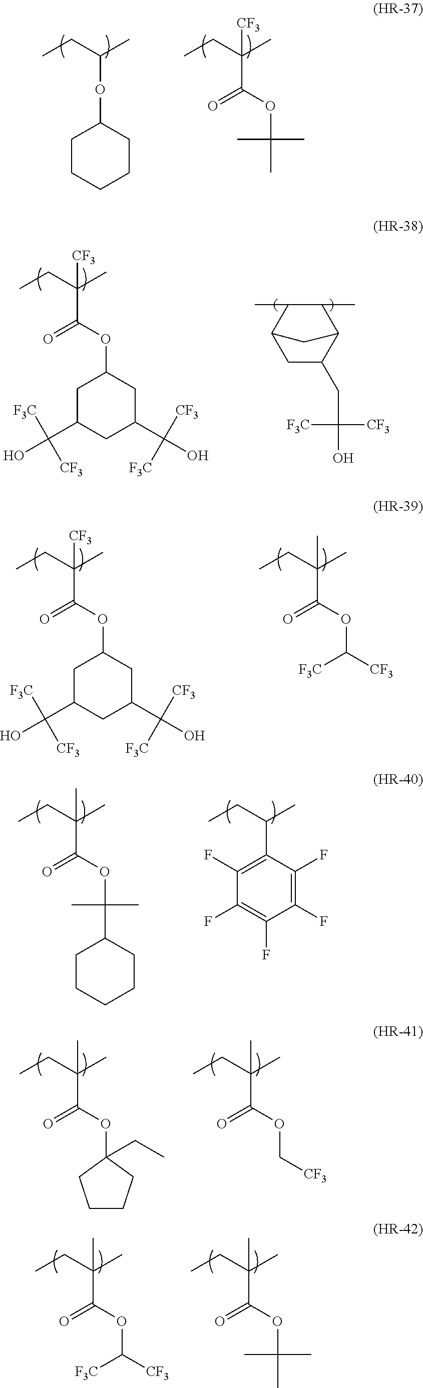

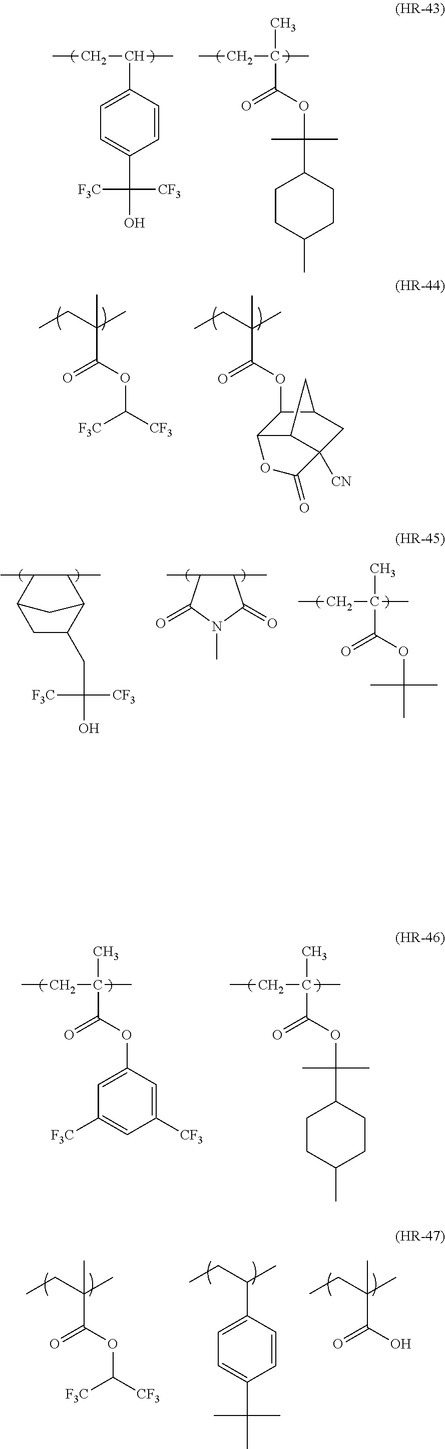

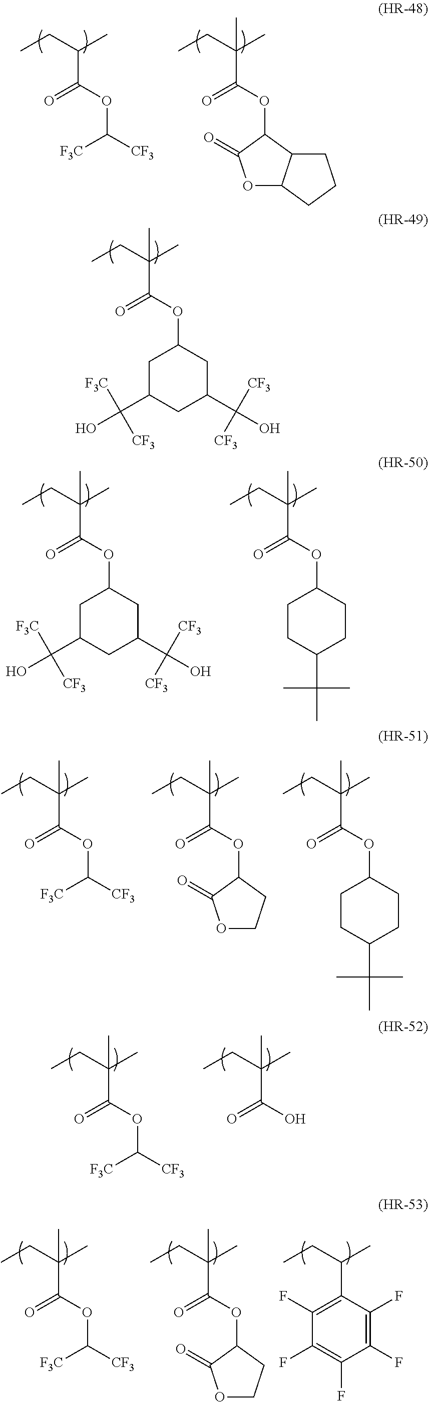

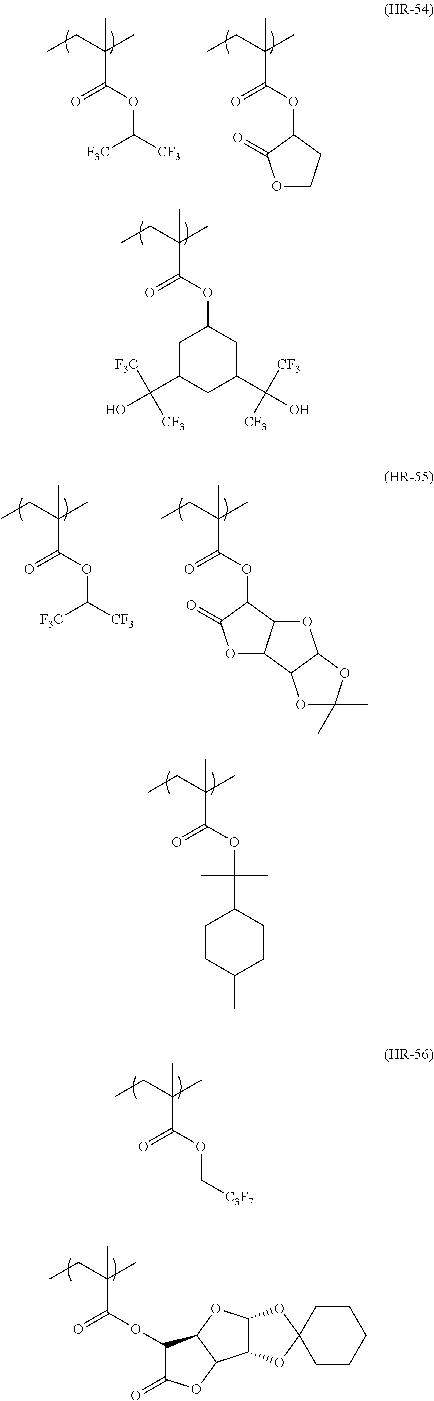

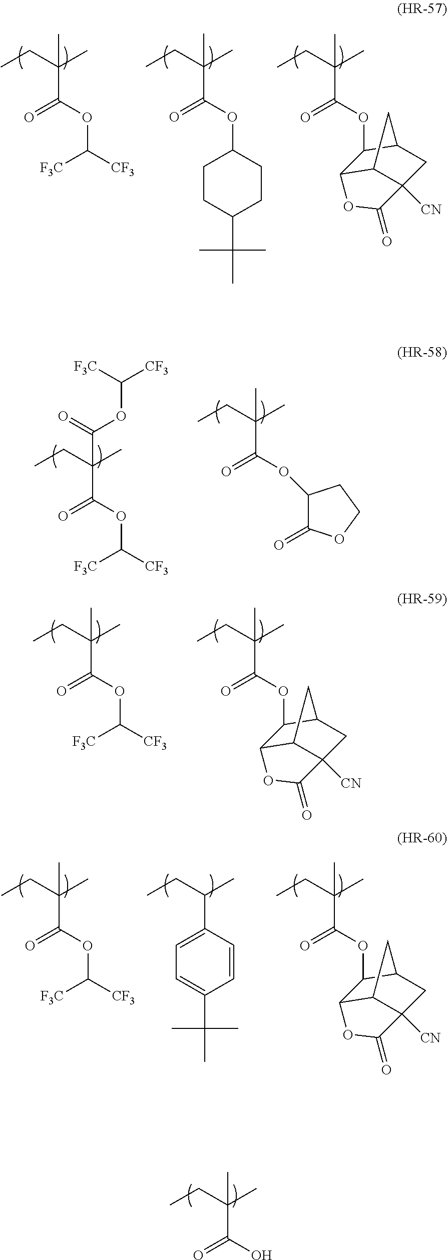

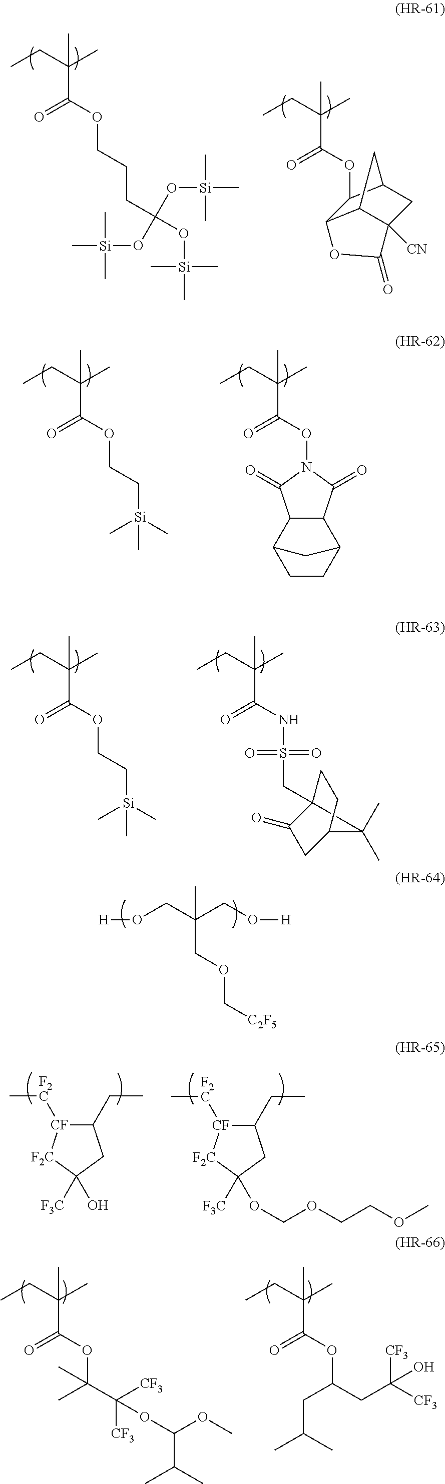

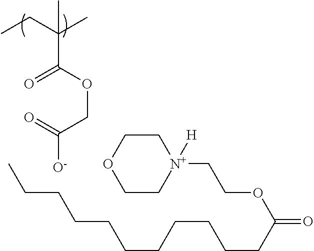

TABLE 1

| Resin | Composition | Mw | Mw/Mn |
|---|---|---|---|
| HR-1 | 50/50 | 4900 | 1.4 |
| HR-2 | 50/50 | 5100 | 1.6 |
| HR-3 | 50/50 | 4800 | 1.5 |
| HR-4 | 50/50 | 5300 | 1.6 |
| HR-5 | 50/50 | 4500 | 1.4 |
| HR-6 | 100 | 5500 | 1.6 |
| HR-7 | 50/50 | 5800 | 1.9 |
| HR-8 | 50/50 | 4200 | 1.3 |
| HR-9 | 50/50 | 5500 | 1.8 |
| HR-10 | 40/60 | 7500 | 1.6 |
| HR-11 | 70/30 | 6600 | 1.8 |
| HR-12 | 40/60 | 3900 | 1.3 |
| HR-13 | 50/50 | 9500 | 1.8 |
| HR-14 | 50/50 | 5300 | 1.6 |
| HR-15 | 100 | 6200 | 1.2 |
| HR-16 | 100 | 5600 | 1.6 |
| HR-17 | 100 | 4400 | 1.3 |
| HR-18 | 50/50 | 4300 | 1.3 |
| HR-19 | 50/50 | 6500 | 1.6 |
| HR-20 | 30/70 | 6500 | 1.5 |
| HR-21 | 50/50 | 6000 | 1.6 |
| HR-22 | 50/50 | 3000 | 1.2 |
| HR-23 | 50/50 | 5000 | 1.5 |
| HR-24 | 50/50 | 4500 | 1.4 |
| HR-25 | 30/70 | 5000 | 1.4 |
| HR-26 | 50/50 | 5500 | 1.6 |
| HR-27 | 50/50 | 3500 | 1.3 |
| HR-28 | 50/50 | 6200 | 1.4 |
| HR-29 | 50/50 | 6500 | 1.6 |
| HR-30 | 50/50 | 6500 | 1.6 |
| HR-31 | 50/50 | 4500 | 1.4 |
| HR-32 | 30/70 | 5000 | 1.6 |
| HR-33 | 30/30/40 | 6500 | 1.8 |
| HR-34 | 50/50 | 4000 | 1.3 |
| HR-35 | 50/50 | 6500 | 1.7 |
| HR-36 | 50/50 | 6000 | 1.5 |
| HR-37 | 50/50 | 5000 | 1.6 |
| HR-38 | 50/50 | 4000 | 1.4 |
| HR-39 | 20/80 | 6000 | 1.4 |
| HR-40 | 50/50 | 7000 | 1.4 |
| HR-41 | 50/50 | 6500 | 1.6 |
| HR-42 | 50/50 | 5200 | 1.6 |
| HR-43 | 50/50 | 6000 | 1.4 |
| HR-44 | 70/30 | 5500 | 1.6 |
| HR-45 | 50/20/30 | 4200 | 1.4 |
| HR-46 | 30/70 | 7500 | 1.6 |
| HR-47 | 40/58/2 | 4300 | 1.4 |
| HR-48 | 50/50 | 6800 | 1.6 |
| HR-49 | 100 | 6500 | 1.5 |
| HR-50 | 50/50 | 6600 | 1.6 |
| HR-51 | 30/20/50 | 6800 | 1.7 |
| HR-52 | 95/5 | 5900 | 1.6 |
| HR-53 | 40/30/30 | 4500 | 1.3 |
| HR-54 | 50/30/20 | 6500 | 1.8 |
| HR-55 | 30/40/30 | 7000 | 1.5 |
| HR-56 | 60/40 | 5500 | 1.7 |
| HR-57 | 40/40/20 | 4000 | 1.3 |
| HR-58 | 60/40 | 3800 | 1.4 |
| HR-59 | 80/20 | 7400 | 1.6 |
| HR-60 | 40/40/15/5 | 4800 | 1.5 |
| HR-61 | 60/40 | 5600 | 1.5 |
| HR-62 | 50/50 | 5900 | 2.1 |
| HR-63 | 80/20 | 7000 | 1.7 |
| HR-64 | 100 | 5500 | 1.8 |
| HR-65 | 50/50 | 9500 | 1.9 |
| HR-66 | 35/60/5 | 8900 | 1.9 |

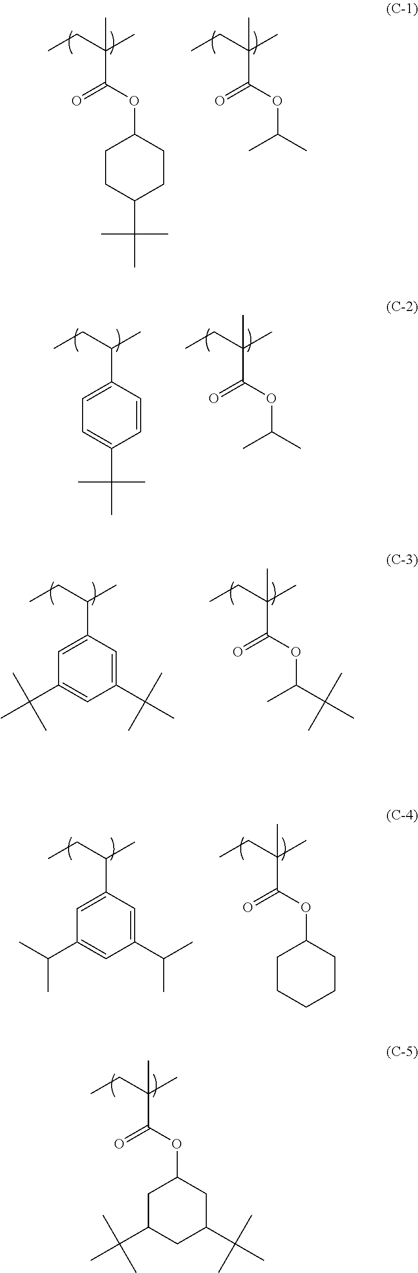

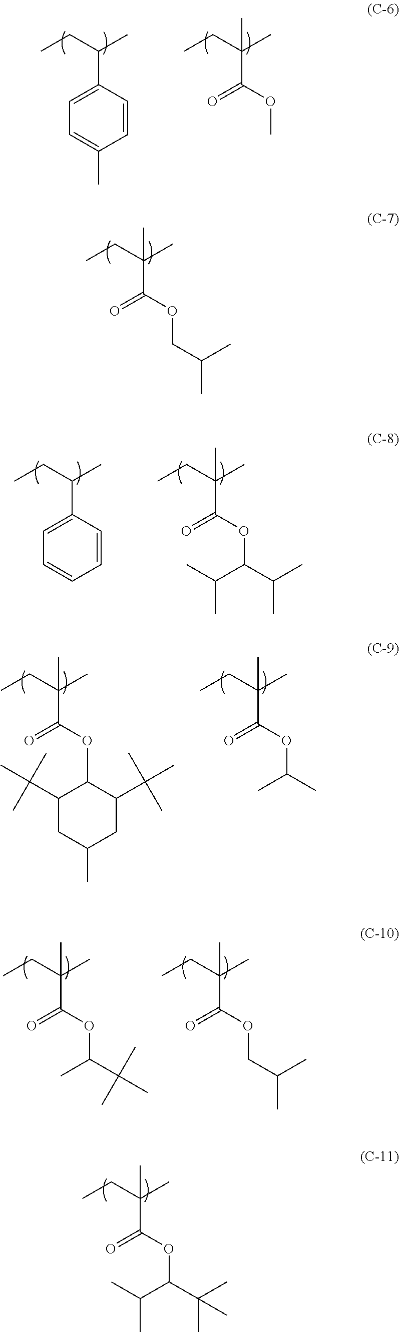

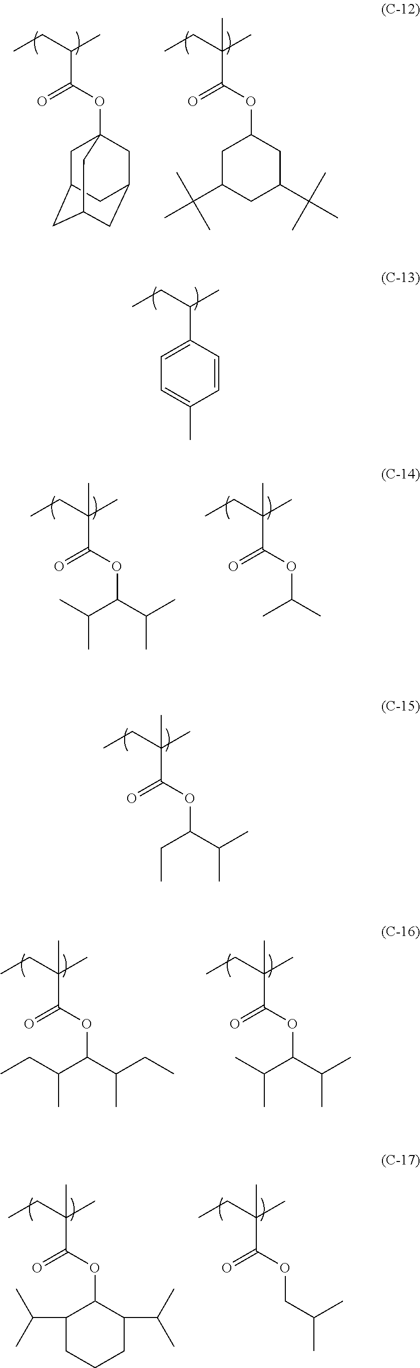

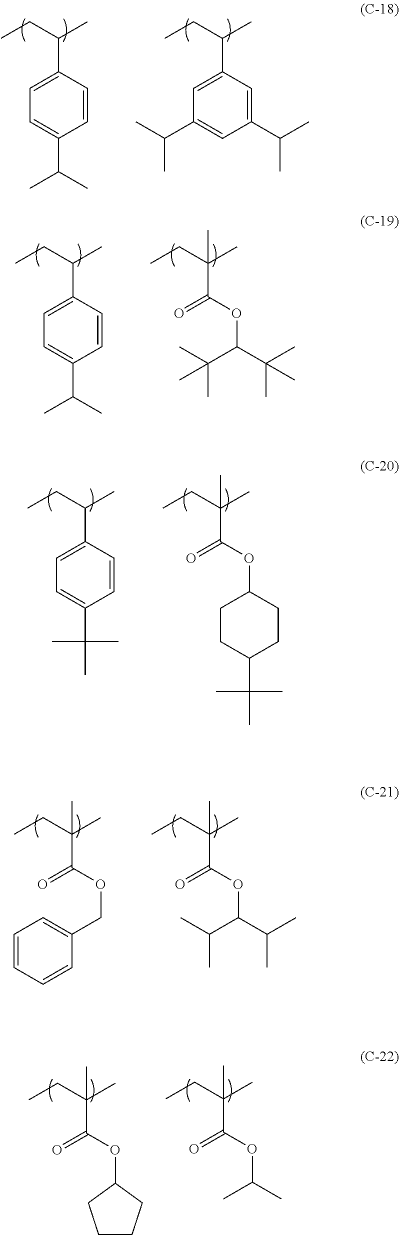

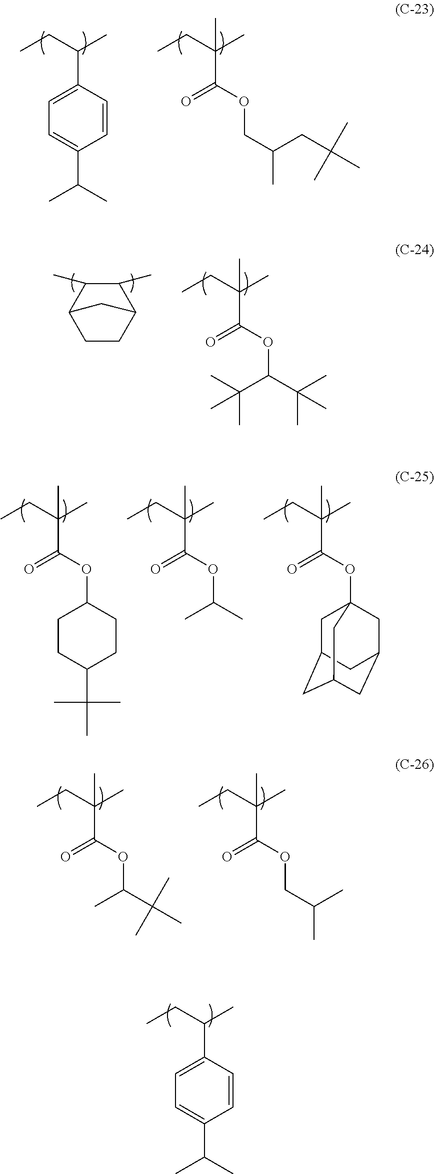

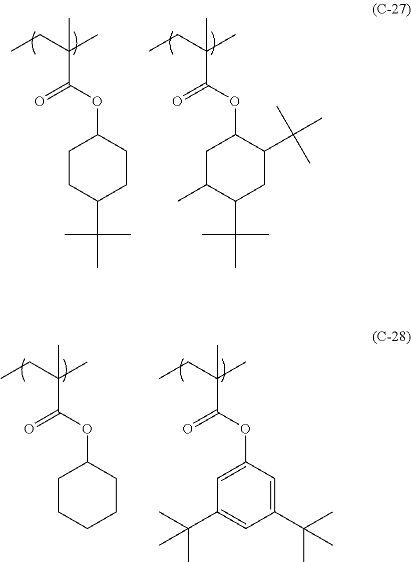

TABLE 2

| Resin | Composition | Mw | Mw/Mn |
|---|---|---|---|
| C-1 | 50/50 | 9600 | 1.74 |
| C-2 | 60/40 | 34500 | 1.43 |
| C-3 | 30/70 | 19300 | 1.69 |
| C-4 | 90/10 | 26400 | 1.41 |
| C-5 | 100 | 27600 | 1.87 |
| C-6 | 80/20 | 4400 | 1.96 |
| C-7 | 100 | 16300 | 1.83 |
| C-8 | 5/95 | 24500 | 1.79 |
| C-9 | 20/80 | 15400 | 1.68 |
| C-10 | 50/50 | 23800 | 1.46 |
| C-11 | 100 | 22400 | 1.57 |
| C-12 | 10/90 | 21600 | 1.52 |
| C-13 | 100 | 28400 | 1.58 |
| C-14 | 50/50 | 16700 | 1.82 |
| C-15 | 100 | 23400 | 1.73 |
| C-16 | 60/40 | 18600 | 1.44 |
| C-17 | 80/20 | 12300 | 1.78 |
| C-18 | 40/60 | 18400 | 1.58 |
| C-19 | 70/30 | 12400 | 1.49 |
| C-20 | 50/50 | 23500 | 1.94 |
| C-21 | 10/90 | 7600 | 1.75 |
| C-22 | 5/95 | 14100 | 1.39 |
| C-23 | 50/50 | 17900 | 1.61 |
| C-24 | 10/90 | 24600 | 1.72 |
| C-25 | 50/40/10 | 23500 | 1.65 |
| C-26 | 60/30/10 | 13100 | 1.51 |
| C-27 | 50/50 | 21200 | 1.84 |
| C-28 | 10/90 | 19500 | 1.66 |

In a case where the hydrophobic resin (HR) includes a fluorine atom, the content of the fluorine atoms is preferably 5% to 80% on the basis of the molecular weight of the hydrophobic resin (HR), and more preferably 10% to 80%.

In a case where the hydrophobic resin (HR) includes a silicon atom, the content of the silicon atoms is preferably 2% to 50% on the basis of the molecular weight of the hydrophobic resin (HR) and more preferably 2% to 30%.

Since the fluorine atoms and the silicon atoms are sufficiently included in the hydrophobic resin (HR) by the content of fluorine atoms or silicon atoms being in this range on the basis of the molecular weight of the hydrophobic resin (HR), it is possible to sufficiently reduce the surface free energy of the hydrophobic resin (HR) and it is possible to more reliably unevenly distribute the hydrophobic resin (HR) in a surface layer section of a resist film. Due to this, it is possible to reliably catch excess acids which are generated on a surface layer of an exposed section and it is possible to reliably make the acid concentration distribution in the thickness direction of the exposed section of the resist film even, and thus it is considered that it is possible to more reliably suppress defects such as the T-top shape or the bridge defects described above.

The content of the “repeating unit which has at least one of a fluorine atom and a silicon atom” in the resin (HR-a) is preferably 20 mol % to 99 mol % with respect to all of the repeating units which configure the hydrophobic resin (HR), more preferably 25 mol % to 95 mol %, and particularly preferably 30 mol % to 90 mol %.

The content of the “repeating unit which has a basic group or a group of which the basicity increases by the action of an acid” in the resin (HR-a) is preferably 15 mol % with respect to all of the repeating units which configure the hydrophobic resin (HR), more preferably 8 mol % or less, and particularly preferably 1 mol % to 8 mol %.

The content of the “repeating unit which has at least one of a fluorine atom and a silicon atom and a group which has a basic group or a group of which the basicity is increased by the action of an acid” in the resin (HR-a) is preferably 20 mol % to 100 mol % with respect to all of the repeating units which configure the hydrophobic resin (HR), more preferably 25 mol % to 100 mol %, and particularly preferably 30 mol % to 100 mol %.

The content of the repeating unit which is represented by General Formula (III′) or (CII-AB) in the hydrophobic resin (HR) is preferably 20 mol % to 80 mol % with respect to all of the repeating units which configure the hydrophobic resin (HR), more preferably 25 mol % to 70 mol %, and particularly preferably 30 mol % to 60 mol %.

As a polystyrene converted value using a GPC method, the weight average molecular weight of the resin (HR) is preferably 1,000 to 100,000, more preferably 1,000 to 50,000, and even more preferably 7,500 to 15,000.

The dispersity of the resin (HR) is preferably 1 to 5, more preferably 1 to 3, and even more preferably 1 to 2. By doing this, it is possible to achieve a superior resolution, pattern forming shape, and roughness characteristics.

The hydrophobic resin (HR) may be used as one type individually or may be used in a combination of two or more types.

The content ratio of the hydrophobic resin (HR) is preferably 0.01 mass % to 10 mass % on the basis of the total solid content in the composition, more preferably 0.05 mass % to 8 mass %, and even more preferably 0.1 mass % to 5 mass %.

As the hydrophobic resin (HR), commercially available products may be used or resins which are synthesized by normal methods may be used. Examples of the general methods for synthesizing the hydrophobic resin (HR) include the same methods described with regard to the resin (B) above.

While the hydrophobic resin (HR) naturally has a few impurities such as metals, the remaining amount of monomers and oligomer components is preferably 0 mass % to 10 mass %, more preferably 0 mass % to 5 mass %, and even more preferably 0 mass % to 1 mass %. Due to this, it is possible to reduce the amount of foreign matter in the liquid and reduce changes in the sensitivity and the like over time.

Solvent

The composition of the present invention may contain a solvent. The solvent is not particularly limited as long as the solvent is able to be used when preparing the composition of the present invention and examples thereof include organic solvents such as alkylene glycol monoalkyl ether carboxylate, alkylene glycol monoalkyl ether, alkyl lactate ester, alkoxypropionic acid alkyl, cyclic lactone (preferably with 4 to 10 carbon atoms), a monoketone compound (preferably with 4 to 10 carbon atoms) which may have a ring, alkylenecarbonate, alkoxy alkyl acetate, and alkyl pyruvate.

Specific examples of the solvents include the solvents described in paragraphs “0441” to “0455” in US2008/0187860A.

In the present invention, a mixed solvent in which a solvent which contains a hydroxy group in the structure and a solvent which does not contain a hydroxy group are mixed may be used as the organic solvent.

As the solvent which contains a hydroxy group and the solvent which does not contain a hydroxy group, it is possible to appropriately select the exemplified compounds; however, the solvent which contains a hydroxy group is preferably alkylene glycol monoalkyl ether, alkyl lactate, or the like and more preferably propylene glycol monomethyl ether (PGME, another name 1-methoxy-2-propanol) and ethyl lactate. In addition, the solvent which does not contain a hydroxy group is preferably alkylene glycol monoalkyl ether acetate, alkylalkoxypropionate, a monoketone which may contain a ring, cyclic lactone, alkyl acetate, or the like and among these, particularly preferably propylene glycol monomethyl ether acetate (PGMEA, also called 1-methoxy-2-acetoxypropane), ethylethoxypropionate, 2-heptanone, γ-butyrolactone, cyclohexanone, or butyl acetate, and most preferably propylene glycol monomethyl ether acetate, ethylethoxypropionate, or 2-heptanone.

The mixing ratio (mass) of the solvent which contains a hydroxy group and the solvent which does not contain a hydroxy group is 1/99 to 99/1, preferably 10/90 to 90/10, and more preferably 20/80 to 60/40. A mixed solvent which contains 50 mass % or more of a solvent which does not contain a hydroxy group is particularly preferable from the point of view of coating uniformity.

In an aspect of the present invention, the solvent preferably includes propylene glycol monomethyl ether acetate and is preferably an individual solvent of propylene glycol monomethyl ether acetate or a mixed solvent of two or more types which contains propylene glycol monomethyl ether acetate.

In addition, in another aspect, the solvent is preferably a mixed solvent which contains γ-butyrolactone (a compound of Formula (7) below). The content ratio of γ-butyrolactone in this case is preferably 10 mass % or less on the basis of the total mass of the solvent and more preferably 5 mass % or less. The lower limit is not particularly limited but is typically 0.1 mass % or more.

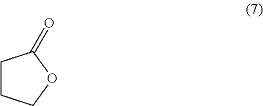

Surfactant

The composition of the present invention may or may not further contain a surfactant and, when contained, either a fluorine and/or silicon-based surfactant (a fluorine-based surfactant, a silicon-based surfactant, a surfactant which has both fluorine atoms and silicon atoms) or two or more types are more preferably contained.

By the active light sensitive or radiation sensitive resin composition in the present invention containing a surfactant, it is possible to impart a resist pattern with less adhesiveness and fewer developing defects with a favorable sensitivity and resolution while using an exposure light source of 250 nm or less, particularly 220 nm or less.

Examples of the fluorine-based and/or silicon-based surfactants include the surfactants described in paragraph “0276” in US2008/0248425A and are, for example, Eftop EF301 and EF303 (produced by Shin-Akita Kasei Co., Ltd.), Fluorad FC430, 431, and 4430 (produced by Sumitomo 3M Inc.), Megafac F171, F173, F176, F189, F113, F110, F177, F120, and R08 (produced by DIC Inc.), Surflon S-382, SC101, 102, 103, 104, 105, 106, and KH-20 (produced by Asahi Glass Co., Ltd.), Troyzol S-366 (produced by Troy Chemical Industries, Inc.), GF-300 and GF-150 (produced by Toagosei Co., Ltd.), Surflon S-393 (produced by Seimi Chemical Co., Ltd.), Eftop EF121, EF122A, EF122B, RF122C, EF125M, EF135M, EF351, EF352, EF801, EF802, and EF601 (produced by Jemco Inc.), PF636, PF656, PF6320, and PF6520 (produced by OMNOVA Corp.), FTX-204G, 208G, 218G, 230G, 204D, 208D, 212D, 218D, and 222D (produced by Neos Co., Ltd.), and the like. In addition, it is also possible to use polysiloxane polymer KP-341 (produced by Shin-Etsu Chemical Co., Ltd.) as a silicon-based surfactant.

In addition, as a surfactant, other than the surfactants known in the art as described above, it is possible to use a surfactant which uses a polymer which has a fluoro aliphatic group which is derived from a fluoro aliphatic compound which is produced by a telomerization method (also referred to as a telomer method) or an oligomerization method (also referred as to an oligomer method). It is possible to synthesize the fluoro aliphatic compound using the method described in JP2002-90991A.

Examples of surfactants which correspond to the surfactants described above include Megafac F178, F-470, F-473, F-475, F-476, and F-472 (produced by DIC Inc.), a copolymer of acrylate (or methacrylate) which has a C₆F₁₃ group and (poly(oxyalkylene))acrylate (or methacrylate), a copolymer of an acrylate (or methacrylate) which has a C₃F₇ group, (poly(oxyethylene))acrylate (or methacrylate), and (poly(oxypropylene))acrylate (or methacrylate), and the like.

In addition, in the present invention, it is also possible to use other surfactants than the fluorine-based and/or the silicon-based surfactants described in paragraphs “0280” in US2008/0248425A.

The surfactants may be used individually or may also be used in various combinations.

In a case where the active light sensitive or radiation sensitive resin composition contains a surfactant, the usage amount of the surfactant is preferably 0.0001 mass % to 2 mass % with respect to the total amount of the active light sensitive or radiation sensitive resin composition (excluding a solvent) and is more preferably 0.0005 mass % to 1 mass %.

On the other hand, by setting the added amount of the surfactant to 10 ppm or less with respect to the total amount of the active light sensitive or radiation sensitive resin composition (excluding a solvent), the surface uneven distribution characteristics of the resin (D) according to the present invention are increased and, due to this, it is possible to make the resist film surface more hydrophobic and it is possible to improve the water conformance at the time of liquid immersion exposure.

Other Additive Agents

It is possible for the composition of the present invention to further contain a compound (for example, a phenol compound with a molecular weight of 1000 or less, an alicyclic or aliphatic compound which has a carboxyl group) or the like which promotes the solubility with respect to a dye, a plasticizer, a photosensitizer, a light absorption agent, an alkali-soluble resin, a dissolution inhibitor, and a developer as necessary.

It is possible for a person skilled in the art to easily synthesize a phenol compound with a molecular weight of 1000 or less with reference to, for example, JP1992-122938A (JP-H4-122938A), JP1990-28531A (JP-H2-28531A), U.S. Pat. No. 4,916,210A, EP219294A, and the like.

Specific examples of an alicyclic or aliphatic compound which has a carboxyl group include a carbonic acid derivative which has a steroid structure such as cholic acid, deoxycholic acid, and lithocholic acid, an adamantane carbonic acid derivative, adamantane dicarbonic acid, cyclohexane carbonic acid, cyclohexane dicarbonic acid, and the like; however, the present invention is not limited thereto.

The composition of the present invention is preferably used with a film thickness of 30 nm to 250 nm and more preferably with a film thickness of 30 nm to 200 nm from the point of view of improving resolving power. It is possible to set such a film thickness by setting the solid content concentration in the composition to an appropriate range to have a suitable viscosity and improve the coating property and film-forming property.

The solid content concentration of the composition of the present invention is generally 1.0 mass % to 10 mass %, preferably 2.0 mass % to 5.7 mass %, and more preferably 2.0 mass % to 5.3 mass %. By setting the solid content concentration to these ranges, it is possible to evenly coat a substrate with the resist solution and moreover, it is possible to form a resist pattern with excellent line width roughness. The reason is not clear; however, it is considered that, by setting the solid content concentration to 10 mass % or less and preferably 5.7 mass % or less, the aggregation of materials, particularly the photoacid generator, in the resist solution is suppressed and, as a result, it is possible to form a uniform resist film.

The solid content concentration is the weight percentage of the weight of other resist components excluding the solvent with respect to the total weight of the active light sensitive or radiation sensitive resin composition.

The active light sensitive or radiation sensitive resin composition in the present invention is used to coat a predetermined support body (substrate) after dissolving the components described above in a predetermined organic solvent, preferably the mixed solvent, and filtering using a filter. The pore size of the filter which is used for the filtering using a filter is 0.1 μm or less, more preferably 0.05 μm or less, and even more preferably 0.03 μm or less and polytetrafluoroethylene, polyethylene, or nylon filters are preferable. In the filtering using a filter, for example, circulative filtering as in JP2002-62667A may be performed or filtering may be performed by connecting a plurality of types of filters in series or in parallel. In addition, a composition may be filtered a plurality of times. Furthermore, before or after the filtering using a filter, a degassing process or the like may be performed with respect to the composition.

Pattern Forming Method

Next, description will be given of a pattern forming method according to the present invention.

The pattern forming method of the present invention

includes at least a step of forming an active light sensitive or radiation sensitive film by coating a substrate with an active light sensitive or radiation sensitive resin composition,

a step of exposing the film described above, and

a step of forming a negative-type pattern by developing the exposed active light sensitive or radiation sensitive film described above using a developer which includes an organic solvent.

In the pattern forming method of the present invention, the exposure may be liquid immersion exposure.

The pattern forming method of the present invention may include the exposing step a plurality of times.

In addition, the pattern forming method of the present invention may include the heating step a plurality of times.

In addition, the pattern forming method of the present invention may include the developing step a plurality of times.

In the pattern forming method of the present invention, it is possible to perform the step of forming an active light sensitive or radiation sensitive film on a substrate using an active light sensitive or radiation sensitive resin composition, the step of exposing the active light sensitive or radiation sensitive film, and the developing step using commonly known methods.

The pattern forming method of the present invention also preferably includes a preheating step (PB; Prebake) after film-forming and before the exposing step.

In addition, it is also preferable to include a post-exposure heating step (PEB; Post Exposure Bake) after the exposing step and before the developing step.

It is preferable to perform both the PB and PEB at a heating temperature of 70° C. to 130° C. and more preferably at 80° C. to 120° C.

The heating time is preferably 30 seconds to 300 seconds, more preferably 30 seconds to 180 seconds, and even more preferably 30 seconds to 90 seconds.

The heating is able to be performed with means which is provided in a general exposure and developing machine and may also be performed using a hot plate or the like.

Due to the baking, the reaction in exposed sections is promoted and the sensitivity or pattern profile is improved.

There is no limit on the wavelength of the light source which is used for the exposure apparatus in the present invention; however, examples thereof include infrared light, visible light, ultraviolet light, far ultraviolet light, extreme ultraviolet light, X-rays, electron beams, and the like, and far ultraviolet light with a wavelength of preferably 250 nm or less, more preferably 220 nm or less, and particularly preferably 1 nm to 200 nm, specifically, a KrF excimer laser (248 nm), an ArF excimer laser (193 nm), an F2 excimer laser (157 nm), X-rays, EUV (13 nm), electron beams, and the like, and a KrF excimer laser, an ArF excimer laser, EUV, or electron beams are preferable, and an ArF excimer laser is more preferable.

In addition, as described above, it is possible to apply a liquid immersion exposure method in a step of performing the exposure of the present invention. It is possible to combine the liquid immersion exposure method with a super-resolution technique such as a phase shift method or a modified lighting method.

In a case of performing liquid immersion exposure, a step of cleaning the surface of the film with a water-based chemical liquid may be carried out (1) after forming the film on a substrate and before the exposure step, and/or (2) after the step of carrying out exposure on a film via an immersion liquid and before the step of heating the film.

The immersion liquid is preferably a liquid which is transparent with respect to the exposure wavelength and where the temperature coefficient of the refractive index is as small as possible in order to keep the deformation of an optical image which is projected on a film to a minimum; however, in particular, in a case where the exposure light source is an ArF excimer laser (wavelength; 193 nm), water is preferably used from the point of view of availability and ease of handling in addition to the points of view described above.

In a case of using water, an additive agent (a liquid) which increases surface activity in addition to reducing the surface tension of the water may be added at a small ratio. It is preferable that the additive agent does not dissolve a resist layer on a wafer and that any influence with respect to an optical coating on a lower surface of a lens element is negligible.

The additive agent is, for example, preferably an aliphatic alcohol which has substantially the same refractive index as water and specific examples thereof include methyl alcohol, ethyl alcohol, an isopropyl alcohol, and the like. By adding alcohol which has substantially the same refractive index as water, it is possible to obtain an advantage in that it is possible to make the refractive index change as the whole liquid extremely small even when the alcohol components in water are evaporated and the content concentration thereof changes.

On the other hand, distilled water is preferable as the water to be used since deformation of the optical image which is projected on the resist is caused in cases where a substance which is opaque with respect to 193 nm light or impurities where the refractive index is greatly different from water are mixed in. Furthermore, pure water on which filtering is performed through an ion exchange filter or the like may also be used.

The electrical resistance of the water which is used as the immersion liquid is desirably 18.3 MΩcm or more, the total organic carbon (TOC) is desirably 20 ppb or less, and a degassing process is desirably carried out.

In addition, it is possible to increase the lithographic performance by increasing the refractive index of the immersion liquid. From this point of view, an additive agent which increases the refractive index may be added to the water, or heavy water (D₂O) may be used instead of water.

The receding contact angle of the resist film which is formed using the active light sensitive or radiation sensitive composition in the present invention is 70° or more at a temperature of 23±3° C. and a humidity of 45±5%, which is favorable in a case of carrying out exposure via the immersion liquid, preferably 75° or more, and more preferably 75° to 85°.

When the receding contact angle is excessively small, favorable use is not possible in a case of carrying out exposure via an immersion liquid and it is not possible to sufficiently exhibit the effect of reducing defects due to remaining water (water marks). In order to realize a favorable receding contact angle, the hydrophobic resin (HR) is preferably included in the active light sensitive or radiation sensitive resin composition. Alternatively, the receding contact angle may be improved by forming a coating layer (a so-called “top coat”) using a hydrophobic resin composition on an active light sensitive or radiation sensitive film.

In the liquid immersion exposure step, since it is necessary for the immersion liquid to move on a wafer following the movement of an exposure head scanning on the wafer at a high speed and forming exposure patterns, the contact angle of the immersion liquid with respect to the resist film in a dynamic state is important and there is a demand for the resist to have a performance which follows the high speed scanning of the exposure head without liquid droplets remaining thereon.

The substrate on which the film is formed in the present invention is not particularly limited, and it is possible to use a substrate such as inorganic substrates of silicon, SiN, SiO₂, TiN, or the like, and coated inorganic substrates of SOG or the like, which is generally used in steps of manufacturing a semiconductor such as IC, steps of manufacturing a circuit board such as liquid crystal or a thermal head, and moreover, lithography steps for other types of photofabrication. Furthermore, as necessary, an antireflection film may be formed between the resist film and the substrate. It is possible to appropriately use an organic or inorganic antireflection film which is known in the art as the antireflection film.

The developing step in the pattern forming method of the present invention is performed using a developer (also referred to below as an “organic solvent-based developer”) which contains an organic solvent. Due to this, a negative-type pattern is formed.

As described above, the pattern forming method of the present invention may include the developing step a plurality of times and, in this case, developing which uses an organic solvent-based developer and developing which uses an alkali developer may be combined.

In the present invention, a negative-type pattern is formed in a case of performing a step which carries out developing using an organic solvent-based developer and a positive-type pattern is formed in a case of performing a step which carries out developing using an alkali developer. In a case of performing both the developing which uses an organic solvent-based developer and the developing which uses an alkali developer, it is also possible to obtain a pattern with twice the resolution of the frequency of an optical space image as described in FIG. 1 to FIG. 11 and the like in U.S. Pat. No. 8,227,183B.

In the pattern forming method of the present invention, it is possible to use polar solvents and hydrocarbon-based solvents such as ketone-based solvents, ester-based solvents, alcohol-based solvents, amide-based solvents, and ether-based solvents as the organic-based developer in the step which carries out developing using an organic solvent-based developer.

Examples of the ketone-based solvent include 1-octanone, 2-octanone, 1-nonanone, 2-nonanone, acetone, 2-heptanone(methylamyl ketone), 4-heptanone, 1-hexanone, 2-hexanone, diisobutyl ketone, cyclohexanone, methylcyclohexanone, phenylacetone, methylethyl ketone, methylisobutyl ketone, acetylacetone, acetonylacetone, ionone, diacetonyl alcohol, acetylcarbinol, acetophenone, methylnaphthyl ketone, isophorone, propylene carbonate, and the like.

Examples of the ester-based solvent include methyl acetate, butyl acetate, ethyl acetate, isopropyl acetate, pentyl acetate, isopentyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate, propyl lactate, and the like.

Examples of the alcohol-based solvent include alcohols such as methyl alcohol, ethyl alcohol, n-propyl alcohol, isopropyl alcohol, n-butyl alcohol, sec-butyl alcohol, tert-butyl alcohol, isobutyl alcohol, n-hexyl alcohol, n-heptyl alcohol, n-octyl alcohol, and n-decanol, glycol-based solvents such as ethylene glycol, diethylene glycol, and triethylene glycol, glycol ether-based solvents such as ethylene glycol monomethyl ether, propylene glycol monomethyl ether, ethylene glycol monoethyl ether, propylene glycol monoethyl ether, diethylene glycol monomethyl ether, triethylene glycol monoethyl ether, and methoxymethyl butanol, and the like.

Examples of the ether-based solvent include dioxane, tetrahydrofuran, and the like other than the glycol ether-based solvents described above.

As the amide-based solvent, it is possible to use, for example, N-methyl-2-pyrrolidone, N,N-dimethyl acetamide, N,N-dimethyl formamide, hexamethylphosphoric triamide, 1,3-dimethyl-2-imidazolidinone, and the like.

Examples of the hydrocarbon-based solvent include aromatic hydrocarbon-based solvents such as toluene and xylene and aliphatic hydrocarbon-based solvents such as pentane, hexane, octane, and decane.

In particular, the organic-based developer is preferably a developer which contains at least one type of an organic solvent selected from a group formed of ketone-based solvents and ester-based solvents, and is particularly preferably a developer which includes butyl acetate as an ester-based solvent and methylamyl ketone (2-heptanone) as a ketone-based solvent.

A plurality of solvents may be mixed or the solvents may be used mixed with solvents other than the solvents described above or water. However, in order to sufficiently exhibit the effects of the present invention, the moisture content for the entirety of the developer is preferably less than 10 mass % and water is more preferably substantially not contained.

That is, the usage amount of the organic solvent with respect to the organic-based developer is preferably 90 mass % to 100 mass % with respect to the total amount of the developer and more preferably 95 mass % to 100 mass %.

The vapor pressure of the organic-based developer at 20° C. is preferably 5 kPa or less, more preferably 3 kPa or less, and particularly preferably 2 kPa or less. By setting the vapor pressure of the organic-based developer to 5 kPa or less, the evaporation of the developer on a substrate or in a developing cup is suppressed, the temperature uniformity in the wafer surface is improved, and, as a result, the uniformity of the dimensions in the wafer surface is improved.

It is possible to add an appropriate amount of a surfactant to the organic-based developer as necessary.

The surfactant is not particularly limited; however, it is possible to use, for example, ionic or non-ionic fluorine-based and/or silicon-based surfactants or the like. Examples of the fluorine-based and/or silicon-based surfactant include the surfactants described in JP 1987-36663A (JP-S62-36663A), JP 1986-226746A (JP-S61-226746A), JP 1986-226745A (JP-S61-226745A), JP1987-170950A (JP-S62-170950A), JP1988-34540A (JP-S63-34540A), JP1995-230165A (JP-H7-230165A), JP1996-62834A (JP-H8-62834A), JP1997-54432A (JP-H9-54432A), JP1997-5988A (JP-H9-5988A), U.S. Pat. No. 5,405,720A, U.S. Pat. No. 5,360,692A, U.S. Pat. No. 5,529,881A, U.S. Pat. No. 5,296,330A, U.S. Pat. No. 5,436,098A, U.S. Pat. No. 5,576,143A, U.S. Pat. No. 5,294,511A, and U.S. Pat. No. 5,824,451A and non-ionic surfactants are preferable. The non-ionic surfactant is not particularly limited; however, it is more preferable to use a fluorine-based surfactant or a silicon-based surfactant.

The usage amount of the surfactant is generally 0.001 mass % to 5 mass % with respect to the total amount of the developer, preferably 0.005 mass % to 2 mass %, and more preferably 0.01 mass % to 0.5 mass %.

In addition, a nitrogen-containing compound may be included in the organic-based developer as described particularly in paragraph “0032” to paragraph “0063” and the vicinity thereof in JP2013-11833A.

As the developing method, it is possible to apply, for example, a method for dipping a substrate in a tank which is filled with a developer for a certain time (a dipping method), a method for carrying out developing by raising the developer onto the substrate surface using surface tension and leaving the substrate to stand still for a certain time (a paddle method), a method for spraying the developer onto the substrate surface (a spraying method), a method for continuing to eject the developer onto a substrate which is rotating at a certain speed while scanning a developer ejecting nozzle at a certain speed (a dynamic dispensing method), and the like.

In a case where the various types of the developing methods described above include a step of ejecting the developer from the developing nozzle of the developing apparatus toward the resist film, the ejection pressure of the ejected developer (the flow rate of the ejected developer per unit area) is, as an example, preferably 2 mL/sec/mm² or less, more preferably 1.5 mL/sec/mm² or less, and even more preferably 1 mL/sec/mm² or less. There is no particular lower limit on the flow rate; however, when considering throughput, 0.2 mL/sec/mm² or more is preferable. Paragraph “0022” to paragraph “0029” and the like in JP2010-232550A disclose the details thereof.

In addition, after the step which carries out developing using a developer which includes an organic solvent, a step of stopping the developing may be carried out while the solvent is replaced with another solvent.

In a case where the pattern forming method of the present invention has a developing step using an alkali developer, the usable alkali developers are not particularly limited; however, an aqueous solution of 2.38 mass % tetramethyl ammonium hydroxide is generally used but it is also possible to use an aqueous solution with a concentration other than this (for example, a thinner concentration). In addition, it is also possible to use a solution in which an appropriate amount of alcohols and a surfactant are added to an alkali aqueous solution.

The alkali concentration of the alkali developer is generally 0.1 mass % to 20 mass %.

The pH of the alkali developer is generally 10.0 to 15.0.

Pure water is used as the rinsing liquid in the rinsing process which is performed after the alkali developing and it is also possible to use a liquid to which an appropriate amount of a surfactant is added.

In addition, it is possible to perform a process of removing the developer or the rinsing liquid which is attached on the pattern using a supercritical fluid after the developing process or the rinsing process.

After the step which carries out developing using an organic solvent-based developer, it is preferable to include a step of cleaning using a rinsing liquid. The rinsing liquid is not particularly limited as long as the rinsing liquid does not dissolve the resist pattern and it is possible to use a solution which includes a general organic solvent. As the rinsing liquid, it is preferable to use a rinsing liquid which contains at least one type of an organic solvent selected from a group formed of a hydrocarbon-based solvent, a ketone-based solvent, an ester-based solvent, an alcohol-based solvent, an amide-based solvent, and an ether-based solvent.

Specific examples of the hydrocarbon-based solvent, the ketone-based solvent, the ester-based solvent, the alcohol-based solvent, and the amide-based solvent, and the ether-based solvent include the same solvents as described in the developer which includes an organic solvent.

After the step which carries out developing using a developer which includes an organic solvent, a step of cleaning using a rinsing liquid which contains at least one type of an organic solvent selected from a group formed of a ketone-based solvent, an ester-based solvent, an alcohol-based solvent, and an amide-based solvent is more preferably performed, a step of cleaning using a rinsing liquid which contains an alcohol-based solvent or an ester-based solvent is even more preferably performed, a step of cleaning using a rinsing liquid which contains monovalent alcohol is particularly preferably performed, and a step of cleaning using a rinsing liquid which contains monovalent alcohol with 5 or more carbon atoms is most preferably performed.

Here, examples of the monovalent alcohol which is used in the rinsing step include a straight-chain, branched, or cyclic monovalent alcohol and specifically, it is possible to use 1-hexanol, 2-hexanol, 4-methyl-2-pentanol, 1-pentanol, 3-methyl-1-butanol, and the like.

A plurality of the components may be mixed or each of the components may be used in a mixture with an organic solvent other than the described above.

The moisture content in the rinsing liquid is preferably 10 mass % or less, more preferably 5 mass % or less, and particularly preferably 3 mass % or less. It is possible to obtain favorable developing characteristics by setting the moisture content to 10 mass % or less.

The vapor pressure of the rinsing liquid which is used after the step of carrying out developing using the developer which includes an organic solvent is preferably 0.05 kPa to 5 kPa at 20° C., more preferably 0.1 kPa to 5 kPa, and most preferably 0.12 kPa to 3 kPa. By setting the vapor pressure of the rinsing liquid to 0.05 kPa to 5 kPa, the temperature uniformity in the wafer surface is improved and, moreover, swelling which is caused by permeation of the rinsing liquid is suppressed and the uniformity of the dimensions in the wafer surface is improved.

It is also possible to use the rinsing liquid after adding an appropriate amount of a surfactant thereto.

In the rinsing step, the cleaning process is carried out using the rinsing liquid which includes the organic solvent on the wafer on which the developing was performed using the developer which includes an organic solvent. The cleaning method is not particularly limited; however, for example, it is possible to apply a method of continuously ejecting the rinsing liquid onto a substrate which is rotating at a certain speed (a rotary coating method), a method of dipping the substrate in a tank which is filled with the rinsing liquid for a certain time (a dipping method), a method of spraying the rinsing liquid onto the substrate surface (a spraying method), and the like, and it is preferable to perform the cleaning process using the rotary coating method among the above, to rotate the substrate at a rotation speed of 2000 rpm to 4000 rpm after the cleaning, and to remove the rinsing liquid from the substrate. In addition, it is also preferable to include a heating step (Post Bake) after the rinsing step. The developer and rinsing liquid which remain between the patterns and in the pattern by the baking are removed. The heating step after the rinsing step is normally performed at 40° C. to 160° C., preferably at 70° C. to 95° C., normally for 10 seconds to 3 minutes, and preferably for 30 seconds to 90 seconds.

The organic developer, the alkali developer, and/or the rinsing liquid which are used in the present invention preferably have few impurities such as various types of fine particles or metal elements. In order to obtain the liquid medicine with few impurities, it is preferable that the liquid medicine is produced in a clean room and, additionally, that impurity reduction is performed by performing filtration using various types of filters such as Teflon (registered trademark) filters, polyolefin-based filters, and ion exchange filters, and the like. With regard to metal elements, the metal element concentration of Na, K, Ca, Fe, Cu, Mg, Mn, Li, Al, Cr, Ni, and Zn is preferably each 10 ppm or less, and more preferably 5 ppm or less.

In addition, the storage container for the developer or the rinsing liquid is not particularly limited and it is possible to appropriately use a container of a polyethylene resin, polypropylene resin, polyethylene-polypropylene resin, and the like which is used for purposes involving electronic materials; however, it is also preferable to select a container in which there are few components which elute from an inner wall of the container to the liquid medicine in order to reduce impurities which elute from the container. Examples of the container include a container of which the inner wall is a perfluoro resin (for example, a Fluoro Pure PFA Compound Drum manufactured by Entegris Corp. (wetted inner surface; PFA resin lining) and a drum can made of steel manufactured by JFE Corp. (wetted inner surface; zinc phosphate film)) and the like.

A pattern which is obtained by the pattern forming method of the present invention is generally favorably used as an etching mask or the like of a semiconductor device; however, the pattern is also used for other purposes. Examples of the other purposes include uses for guide pattern forming in directed self-assembly (DSA) (for example, refer to ACS Nano Vol. 4 No. 8 Page 4815-4823), that is, as a core of a spacer process (for example, refer to JP1991-270227A (JP-H3-270227A), JP2013-164509A, and the like) and the like.

The present invention also relates to a method for manufacturing an electronic device which includes the negative-type pattern forming method of the present invention described above and an electronic device which is manufactured by the manufacturing method.

The electronic device of the present invention is favorably mounted on electrical and electronic devices (household electrical appliances, OA and media-related devices, optical apparatuses and instruments, telecommunication devices, and the like).

### EXAMPLES

Detailed description will be given below of the present invention using Examples; however, the content of the present invention is not limited thereby.

### Synthesizing Example

### Synthesizing Acid-Decomposable Resin (P-1)

24.2 g of cyclohexanone was placed in a three-neck flask in a nitrogen gas stream and heated to 85° C. In this manner, a solvent 1 was obtained. Next, a monomer solution was prepared by dissolving the monomer-1 (5.33 g), the monomer-2 (2.24 g), the monomer-3 (2.48 g), and the monomer-4 (20.19 g) described below in cyclohexanone (96.8 g). Furthermore, a polymerization initiator V-601 (produced by Wako Pure Chemical Industries, Ltd.) was added at 4.2 mol % with respect to the total amount of the monomers and the dissolved solution was dripped over 6 hours with respect to the solvent 1 described above. After finishing the dripping, a further reaction was carried out at 85° C. for 2 hours. After leaving the reaction liquid to cool, 25.2 g of the resin (P-1) which will be described below was obtained by dripping the reaction liquid into a mixed solvent of 953 g of methanol/106 g of water and filtering and drying the educted powder. With regard to the obtained resin (P-1), the weight average molecular weight (Mw: polystyrene conversion), the number average molecular weight (Mn: polystyrene conversion), and the dispersity (Mw/Mn) were calculated by GPC (Solvent: THF) measurement. In addition, the composition ratio (molar ratio) of the resin (P-1) was calculated by ¹³C-NMR. The weight average molecular weight of the obtained resin (P-1) was 6900, the dispersity (Mw/Mn) was 1.57, and the composition ratio was 20/21/9/60.

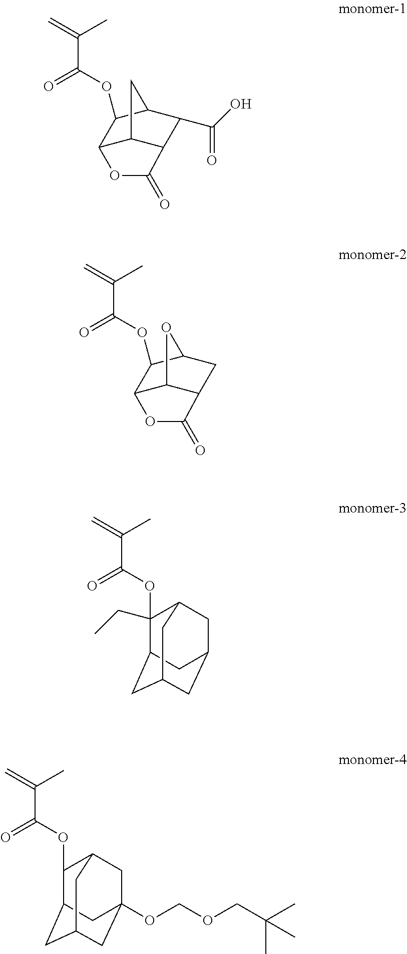 [SMILES: C=C(C)C(=O)OC1C2CC3C1OC(=O)C3C2C(=O)O ; C=C(C)C(=O)OC1C2CC3C(=O)OC1C3O2 ; C=C(C)C(=O)OC1(CC)C2CC3CC(C2)CC1C3 ; C=C(C)C(=O)OC1C2CC3CC1CC(OCOCC(C)(C)C)(C3)C2]

In the same manner as the resin (P-1), resins (P-2) to (P-7) and (PA-1) were synthesized. The weight average molecular weight, the dispersity (Mw/Mn), and the composition ratio of the resins were as in the table below.

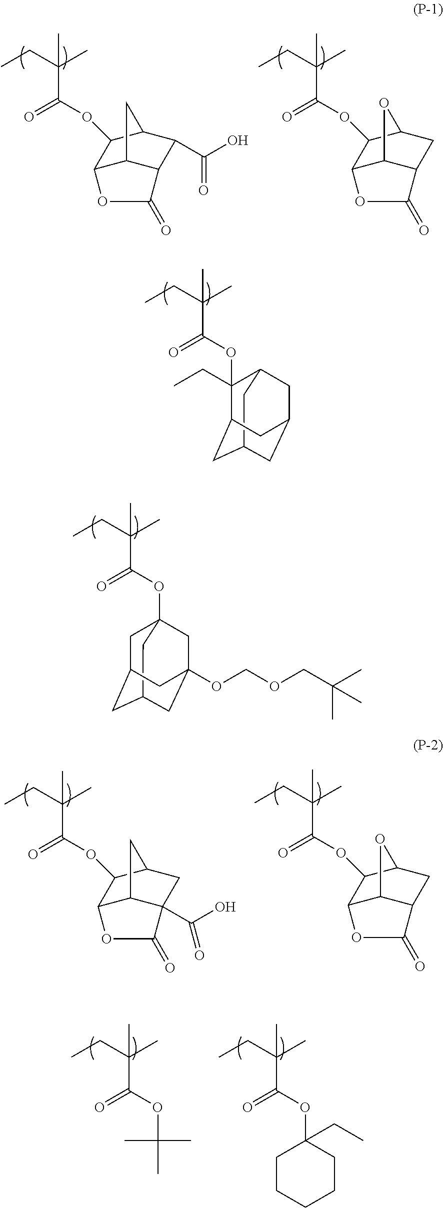

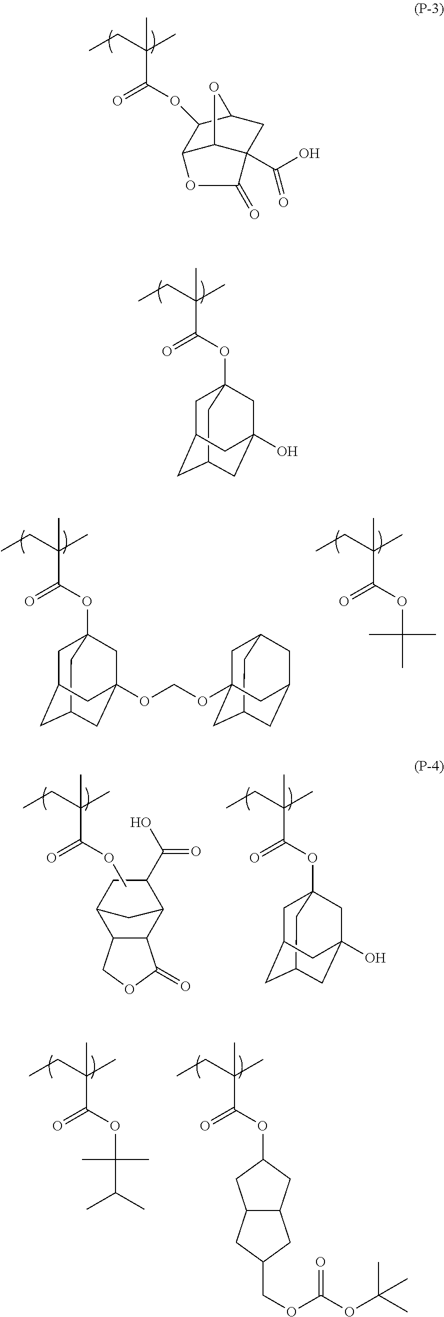

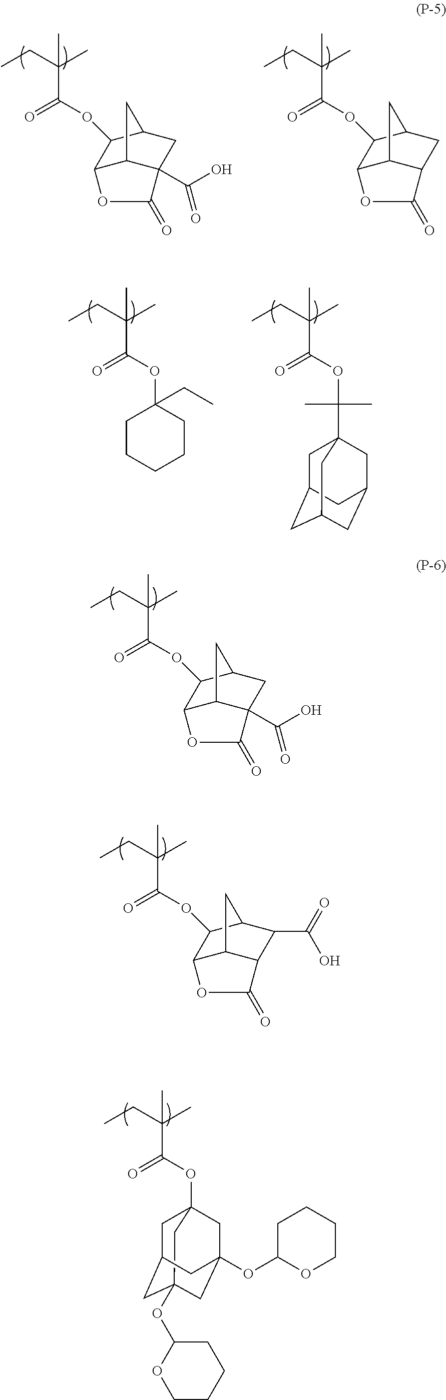

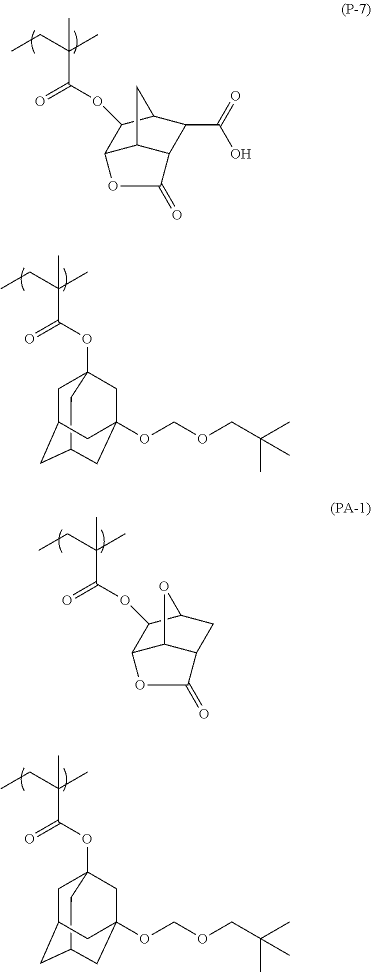

TABLE 3

| | | | |
|---|---|---|---|
| Compound | | | |
| number | Mw | Mw/Mn | Composition ratio |

| | | | | | | |
|---|---|---|---|---|---|---|
| P-1 | 6900 | 1.57 | 20 | 10 | 10 | 60 |
| P-2 | 13200 | 1.68 | 10 | 30 | 40 | 20 |
| P-3 | 11000 | 1.62 | 25 | 10 | 15 | 50 |
| P-4 | 17200 | 1.82 | 35 | 10 | 25 | 30 |
| P-5 | 8200 | 1.65 | 20 | 20 | 45 | 15 |
| P-6 | 9500 | 1.73 | 20 | 20 | 60 | |
| P-7 | 15200 | 1.67 | 50 | 50 | | |
| PA-1 | 12100 | 1.70 | 40 | 60 | | |

<Acid Generating Agent>

An acid generating agent was used after being appropriately selected from the acid generating agents z1 to z101 exemplified above.

<Basic Compound>

As basic compounds, the compounds (N-1) to (N-9) below were prepared.

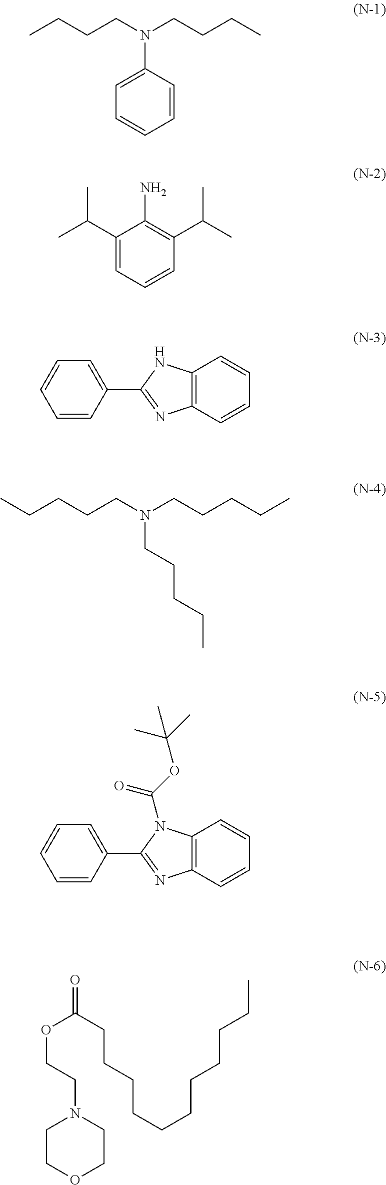

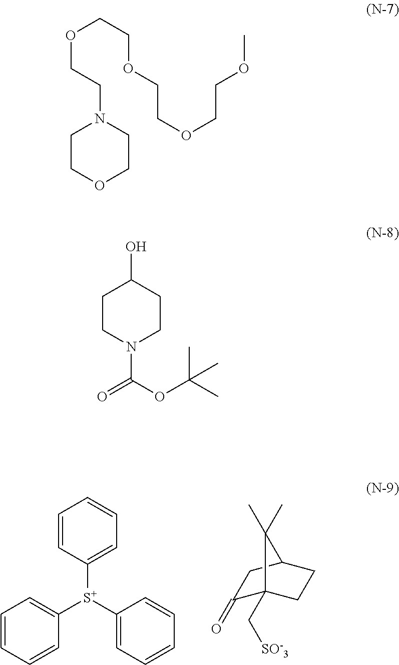

<Hydrophobic Resin>

A hydrophobic resin was used after being appropriately selected from the resins (HR-1) to (HR-66) and (C−1) to (C-28) exemplified above.

<Surfactant>

[0731]s a surfactant, the following were prepared.

W-1: Megafac F176 (produced by DIC Inc.; fluorine-based)

W-2: Megafac R08 (produced by DIC Inc.; fluorine and silicon-based)

W-3: Polysiloxane polymer KP-341 (produced by Shin-Etsu Chemical Co., Ltd.; silicon-based)

W-4: Troyzol S-366 (produced by Troy Chemical Industries, Inc.)

W-5: KH-20 (produced by Asahi Glass Co., Ltd.)

W-6: Poly Fox PF-6320 (produced by OMNOVA Solutions Inc.; fluorine-based)

<Solvent>

As a solvent, the following were prepared.

### (Group a)

SL-1: Propylene glycol monomethyl ether acetate (PGMEA)

SL-2: Propylene glycol monomethyl ether propionate

SL-3: 2-heptanone

### (Group b)

SL-4: Ethyl lactate

SL-5: Propylene glycol monomethyl ether (PGME)

SL-6: Cyclohexanone

### (Group c)

SL-7: γ-butyrolactone

SL-8: Propylene carbonate

<Developer>

As a developer, the following were prepared.

SG-1: Butyl acetate

SG-2: Methylamyl ketone

SG-3: Ethyl-3-ethoxypropionate

SG-4: Pentyl acetate

SG-5: Isopentyl acetate

SG-6: Propylene glycol monomethyl ether acetate (PGMEA)

SG-7: Cyclohexanone

<Rinsing Liquid>

As a rinsing liquid, the following were used.

SR-1: 4-methyl-2-pentanol

SR-2: 1-hexanol

SR-3: Butyl acetate

SR-4: Methylamyl ketone

SR-5: Ethyl-3-ethoxypropionate

<Resist Preparation>

An active light sensitive or radiation sensitive resin composition (a resist composition) was prepared by dissolving 3.8 mass % solid content of the components shown in Table 4 in the solvent shown in the same table and filtering each component using a polyethylene filter with a pore size of 0.03 μm.

<Pattern Forming>

A silicon wafer was coated with an organic antireflection film ARC29SR (produced by Nissan Chemical Industries, Ltd.), baking was performed at 205° C. for 60 seconds, and an antireflection film with a film thickness of 98 nm was formed. The result was coated with a prepared active light sensitive or radiation sensitive resin composition, baking (Prebake: PB) was performed at 100° C. for 60 seconds, and a resist film with a film thickness of 100 nm was formed.

Pattern exposure was performed with respect to the obtained resist film using an ArF excimer laser liquid immersion scanner (manufactured by ASML Corp.; XT1700i, NA1.20, C-Quad, outer sigma 0.900, inner sigma 0.812, XY deflection). Here, as a reticle, a 6% half tone mask with line size=45 nm and line:space=1:1 was used. In addition, ultra-pure water was used as the immersion liquid. After that, heating (Post Exposure Bake: PEB) was carried out at the temperature described in Table 5 for 60 seconds. Subsequently, the developing was carried out by paddling in the organic solvent-based developer described in Table 5 for 30 seconds and, while rotating the wafer at a rotation speed of 500 rpm, the rinsing was carried out by paddling for 2 seconds in the rinsing liquid described in Table 5. Subsequently, a resist pattern of a 1:1 line and space with a space width of 45 nm was obtained by completely drying the wafer by heating (Post Bake) at 90° C. for 60 seconds after spinning and drying at 2500 rpm.

<Evaluation Method>

According to the evaluation method below, the sensitivity, roughness characteristics (LWR), exposure latitude (EL), and a pattern shape were evaluated and the results are shown in Table 5 below.

[Sensitivity]

Irradiation energy when resolving a pattern of 1:1 line and space with a line width of 45 nm was set as the sensitivity (Eop). A smaller value indicates that the performance is more favorable.

[LWR]

The obtained pattern of 1:1 line and space with a line width of 45 nm was observed using a scanning microscope (S9380 manufactured by Hitachi Ltd.), the line width was measured at 50 points with regard to the range of edge 2 μm in the longitudinal direction of the line pattern, the standard deviation was obtained with regard to the measurement variations, and 3σ was calculated. A smaller value indicates that the roughness characteristic is more favorable.

[Exposure Latitude (EL)]

An exposure amount for reproducing a mask pattern of 1:1 line and space with a line width of 45 nm was set as the optimum exposure amount, an exposure amount width where a pattern size with a tolerance of 45 nm±10% when changing the exposure amount was obtained, and this value was divided by the optimum exposure amount and represented as a percentage. A larger value indicates that the changes in the performance due to the change in the exposure amount are smaller and that the exposure latitude is more favorable.

[Pattern Shape]

A cross-sectional shape of 1:1 line and space pattern with a line width of 45 nm in an irradiation amount which indicates the sensitivity described above was observed using a scanning electron microscope (S-4300 manufactured by Hitachi Ltd.) and rectangular, taper, and reversed taper evaluation was performed in three stages.

TABLE 4

| | Acid- | | Acid | | | | | | | | | |
|---|---|---|---|---|---|---|---|---|---|---|---|---|
| | decom- | | gener- | | Hydro- | | | | | | | |
| | posable | | ating | | phobic | | Basic | | | | | (Mass |
| | resin | (g) | agent | (g) | resin | (g) | compound | (g) | Surfactant | (g) | Solvent | ratio) |
| Example | | | | | | | | | | | | |
| 1 | P-1 | 10 | z95 | 0.9 | HR-7 | 0.06 | N-1 | 0.15 | W-2 | 0.003 | SL-1/SL-5 | 60/40 |
| 2 | P-2 | 10 | z101 | 1 | HR-10 | 0.06 | N-2 | 0.15 | W-3 | 0.003 | SL-1/SL-5 | 60/40 |
| 3 | P-3 | 10 | z32 | 1.2 | HR-66 | 0.06 | N-3 | 0.15 | W-1 | 0.003 | SL-1/SL-3 | 80/20 |
| 4 | P-4 | 10 | z80 | 0.8 | C-1 | 0.06 | N-4 | 0.15 | W-4 | 0.003 | SL-1/SL-5 | 80/20 |
| 5 | P-5 | 10 | z102 | 1 | C-9 | 0.06 | N-5 | 0.15 | W-5 | 0.003 | SL-1/SL-5/SL-7 | 60/30/10 |
| 6 | P-6 | 10 | z100 | 0.8 | C-3 | 0.06 | N-6 | 0.15 | W-6 | 0.003 | SL-1 | 100 |
| 7 | P-7 | 10 | z45 | 1 | C-14 | 0.06 | N-7 | 0.15 | W-2 | 0.003 | SL-6/SL-5 | 70/30 |
| 8 | P-1/P-2 | 5/5 | z93 | 1 | HR-7 | 0.06 | N-8 | 0.15 | W-6 | 0.003 | SL-1/SL-4 | 90/10 |
| 9 | P-1/PA-1 | 7/3 | z92 | 0.8 | HR-10 | 0.06 | N-9 | 0.3 | W-2 | 0.003 | SL-1/SL-8 | 90/10 |
| 10 | P-1 | 10 | z98/z100 | 0.7/0.3 | HR-66 | 0.06 | N-4 | 0.15 | W-3 | 0.003 | SL-1/SL-2 | 90/10 |
| 11 | P-1 | 10 | z99 | 1 | HR-66/C-1 | 0.05/0.01 | N-6 | 0.15 | W-1 | 0.003 | SL-1/SL-6 | 90/10 |
| 12 | P-1 | 10 | z78 | 1 | C-3 | 0.06 | N-3/N-7 | 0.08/0.07 | W-4 | 0.003 | SL-1 | 100 |
| 13 | P-1 | 10 | z72 | 0.9 | C-9 | 0.06 | N-4 | 0.15 | W-2/W-3 | 0.001/0.002 | SL-1/SL-5 | 70/30 |
| 14 | P-1 | 10 | z76 | 1 | C-14 | 0.06 | N-4 | 0.15 | — | — | SL-1/SL- 5 | 70/30 |
| Compar- | | | | | | | | | | | | |
| ative | | | | | | | | | | | | |
| Example | | | | | | | | | | | | |
| agent | | | | | | | | | | | | |
| 1 | PA-1 | 10 | z76 | 1 | HR-7 | 0.06 | N-1 | 0.15 | W-3 | 0.003 | SL-6/SL-5 | 80/20 |

TABLE 5

| | | | | | PEB | | | | |
|---|---|---|---|---|---|---|---|---|---|
| | | (Mass | Rinsing | (Mass | temperature | Sensitivity | | | |
| | Developer | ratio) | liquid | ratio) | (° C.) | [mJ/cm²] | LWR[nm] | EL[%] | Shape |
| Example | | | | | | | | | |
| 1 | SG-1 | 100 | SR-1 | 100 | 100 | 29.2 | 5.5 | 16 | Rectangular |
| 2 | SG-2 | 100 | SR-2 | 100 | 120 | 30.2 | 5.8 | 12 | Rectangular |
| 3 | SG-1 | 100 | SR-1/SR-3 | 80/20 | 100 | 29.3 | 5.2 | 16 | Rectangular |
| 4 | SG-3 | 100 | SR-5 | 100 | 110 | 30.2 | 5.5 | 14 | Rectangular |
| 5 | SG-5 | 100 | SR-1 | 100 | 90 | 33.1 | 5.9 | 12 | Rectangular |
| 6 | SG-6 | 100 | SR-2 | 100 | 100 | 27.7 | 5.6 | 14 | Rectangular |
| 7 | SG-2/SG-7 | 80/20 | SR-1 | 100 | 100 | 27.5 | 5.5 | 16 | Rectangular |
| 8 | SG-3/SG-7 | 70/30 | SR-4 | 100 | 120 | 29.8 | 5.4 | 14 | Rectangular |
| 9 | SG-4 | 100 | SR-2 | 100 | 100 | 30.9 | 5.6 | 15 | Rectangular |
| 10 | SG-1/SG-7 | 90/10 | SR-1 | 100 | 100 | 32.0 | 5.1 | 17 | Rectangular |
| 11 | SG-2/SG-3 | 50/50 | SR-1/SR-3 | 70/30 | 100 | 27.4 | 5.2 | 16 | Rectangular |
| 12 | SG-1 | 100 | SR-1 | 100 | 100 | 30.1 | 5.5 | 14 | Rectangular |
| 13 | SG-4 | 100 | SR-3 | 100 | 100 | 31.9 | 5.4 | 15 | Rectangular |
| 14 | SG-5 | 100 | SR-1 | 100 | 100 | 32.2 | 5.5 | 15 | Rectangular |
| Compar- | | | | | | | | | |
| ative | | | | | | | | | |
| Example | | | | | | | | | |
| 1 | SG-1 | 100 | SR-1 | 100 | 100 | 28.2 | 6.3 | 10 | Reversed |
| | | | | | | | | | taper |

As is clear from the results shown in the table above, the negative-type pattern which is obtained by the pattern forming method of the present invention is excellent in each performance relating to the sensitivity, LWR, EL, and pattern shape.

Furthermore, when evaluation was performed in the same manner in Example 1 apart from adding a small amount of tri n-octylamine to the developer (butyl acetate), it was also possible to obtain a favorable negative-type pattern therein.

In addition, when evaluation was performed in the same manner as the examples described above by performing a developing process using butyl acetate after forming a film on a substrate using the resist composition in Examples 15 and 16 shown in the table below and performing exposure using EUV light, it was also possible to perform favorable pattern forming with regard thereto.

TABLE 6

| | | | | | | | | | | | Total |
|---|---|---|---|---|---|---|---|---|---|---|---|
| | | | | | | | | | | | solid |
| | | | Acid | | | | Organic | | | | content |
| | Resin | Concen- | generating | Concen- | Basic | Concen- | solvent | Mass | | Concen- | concen- |
| | (P) | tration | agent | tration | compound | tration | (D) | ratio | Surfactant | tration | tration |
| Example | P-2-1 | 89.6 | z102 | 10 | N-5 | 0.3 | SL-1/SL-5/SL-7 | 60/30/10 | W-1 | 0.1 | 4.0 |
| 15 | | | | | | | | | | | |
| Example | P-2-2 | 99.4 | None | 0 | N-9 | 0.5 | SL-1/SL-5 | 40/60 | W-2 | 0.1 | 4.0 |
| 16 | | | | | | | | | | | |

The concentration of each component represents the concentration (mass %) in the total solid content concentration.

As the resin (P), the following were used.

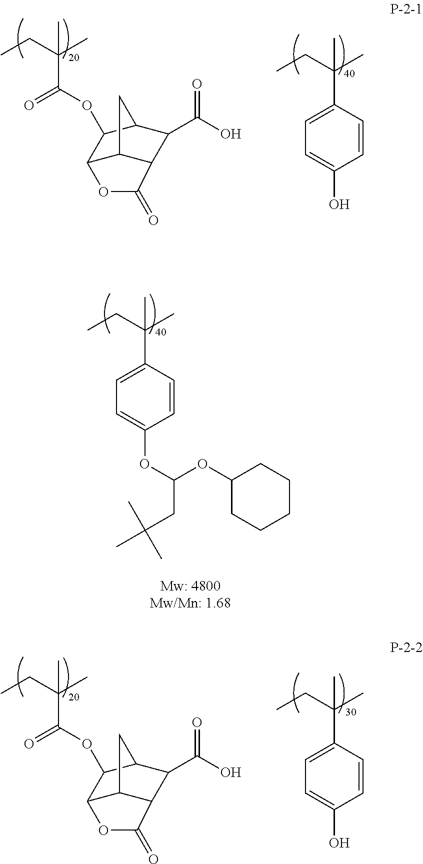

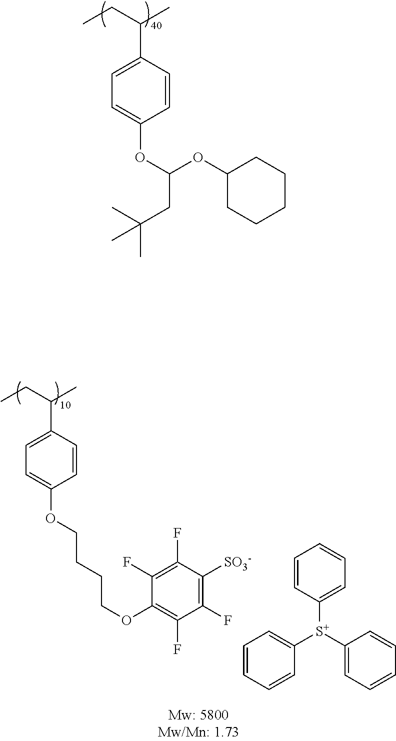

In addition, when butyl acetate developing and alkali developing were both performed after exposing a mask pattern of line and space using EUV light using the resist compositions of Example 1 with reference to Example 7 described in U.S. Pat. No. 8,227,183A, it was possible to form a pattern with a pitch of ½ of the mask pattern.

What is claimed is:

1. A pattern forming method comprising:
a step of forming an active light sensitive or radiation sensitive film by coating a substrate with an active light sensitive or radiation sensitive resin composition;
a step of exposing the active light sensitive or radiation sensitive film; and
a step of forming a negative-type pattern by developing the exposed active light sensitive or radiation sensitive film using a developer including an organic solvent,
wherein the active light sensitive or radiation sensitive resin composition contains a resin (A) which includes a repeating unit (a) having an acidic group and a lactone structure and of which, a polarity is increased by an action of an acid and thus a solubility with respect to the developer including an organic solvent is decreased.

2. The pattern forming method according to claim 1,
wherein the repeating unit (a) having an acidic group and a lactone structure includes a structure represented by General Formula (I-1) or (I-2) below, 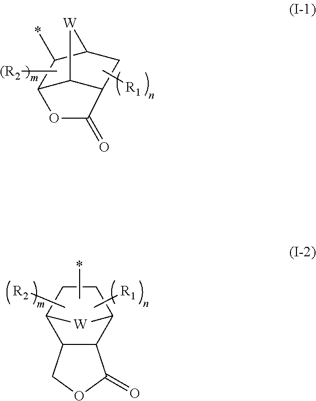
in General Formulas (I-1) and (I-2),
R₁ represents an acidic group and may be the same or may be different from each other in a case where a plurality thereof are present,
R₂ represents a monovalent organic group and may be the same or may be different from each other in a case where a plurality thereof are present,
n represents an integer of 1 or more, m represents an integer of 0 or more,
W represents a methylene group, an ethylene group, or an oxygen atom, and
* represents a linking site with a remainder of the repeating unit (a).

3. The pattern forming method according to claim 1,
wherein the acidic group of the repeating unit (a) is a carboxyl group.

4. The pattern forming method according to claim 1,
wherein the resin (A) further contains a repeating unit (b) having an acid-decomposable group which is decomposed by an action of an acid.

5. The pattern forming method according to claim 4,
wherein a content ratio of the repeating unit (b) is 55 mol % or more with respect to all of the repeating units included in the resin (A).

6. The pattern forming method according to claim 4,
wherein the acid-decomposable group of at least one type of the repeating unit (b) is a group which is decomposed by an action of an acid and generates an alcoholic hydroxy group.

7. The pattern forming method according to claim 4,
wherein the acid-decomposable group of at least one type of the repeating unit (b) includes a structure represented by General Formula (II) below, 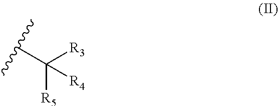
in the formula, R₃, R₄, and R₅ each independently represents an alkyl group, provided that one or more CH₂s in the alkyl group may be replaced by an ether bond.

8. An active light sensitive or radiation sensitive resin composition comprising:
a resin (A), which includes a repeating unit (a) having an acidic group and a lactone structure and a repeating unit (b) having an acid-decomposable group which is decomposed by an action of an acid, and of which, a polarity is increased by an action of an acid and a solubility with respect to a developer including an organic solvent is decreased,
wherein the repeating unit (a) includes a structure represented by General Formula (I-1) or (I-2) below, and
a content ratio of the repeating unit (b) is 55 mol % or more with respect to all of the repeating units included in the resin (A), 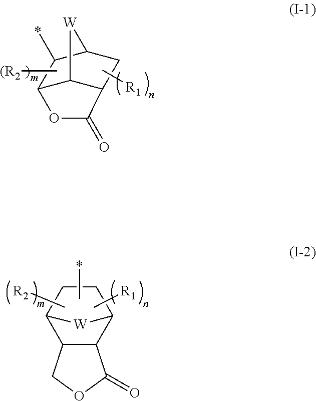
in General Formulas (I-1) and (I-2),
R₁ represents an acidic group and may be the same or may be different from each other in a case where a plurality thereof are present,
R₂ represents a monovalent organic group and may be the same or may be different from each other in a case where a plurality thereof are present,
n represents an integer of 1 or more and m represents an integer of 0 or more,
W represents a methylene group, an ethylene group, or an oxygen atom, and
* represents a linking site with a remainder of the repeating unit (a).

9. The active light sensitive or radiation sensitive resin composition according to claim 8,
wherein at least one R₁ in General Formulas (I-1) and (I-2) is a carboxyl group.

10. The active light sensitive or radiation sensitive resin composition according to claim 8,
wherein the acid-decomposable group of at least one type of the repeating unit (b) is a group which is decomposed by an action of an acid and generates an alcoholic hydroxy group.

11. The active light sensitive or radiation sensitive resin composition according to claim 8,
wherein the acid-decomposable group of at least one type of the repeating unit (b) includes a structure represented by General Formula (II) below, 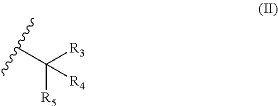
in the formula, R₃, R₄, and R₅ each independently represents an alkyl group, provided that one or more CH₂s in the alkyl group may be replaced by an ether bond.

12. An active light sensitive or radiation sensitive film which is formed using the active light sensitive or radiation sensitive resin composition according to claim 8.

13. A method for manufacturing an electronic device comprising:
the pattern forming method according to claim 1.

14. An electronic device which is manufactured by the method for manufacturing an electronic device according to claim 13.
